(19) United States
(12) Patent Application Publication
(10) Pub. No.: US 2023/0084574 A1
(43) Pub. Date: Mar. 16, 2023

(54) BIT SEQUENCE STORAGE METHOD AND SYSTEM

(71) Applicant: UncommonX Inc., Chicago, IL (US)

(72) Inventors: Raymond Hicks, Chicago, IL (US); Timothy W. Markison, Mesa, AZ (US)

(73) Assignee: UncommonX Inc., Chicago, IL (US)

(21) Appl. No.: 17/821,650

(22) Filed: Aug. 23, 2022

Related U.S. Application Data
(60) Provisional application No. 63/261,285, filed on Sep. 16, 2021.

(51) Int. Cl. G06F 16/13; G06F 16/14

(52) U.S. Cl. CPC G06F 16/13; G06F 16/148

(57) ABSTRACT

A method for execution by a computing entity includes receiving a file retrieval request for a file. The method further includes accessing an index table regarding the file. The method further includes interpreting the index table to identify a plurality of bit sequences. The index table includes a plurality of symbols, where a symbol is representative of a bit sequence. The method further includes sending one or more requests to a network device regarding at least some of the plurality of bit sequences. The method further includes receiving a requested bit sequence in response to the one or more requests. The method further includes reconstructing a portion of the file based on the requested bit sequence and the index table.

### CROSS-REFERENCE TO RELATED APPLICATIONS

The present U.S. Utility patent application claims priority pursuant to 35 U.S.C. § 119(e) to U.S. Provisional Application No. 63/261,285, entitled “BIT SEQUENCE STORAGE METHOD AND SYSTEM,” filed Sep. 16, 2021, which is hereby incorporated herein by reference in its entirety and made part of the present U.S. Utility patent application for all purposes.

### STATEMENT REGARDING FEDERALLY SPONSORED RESEARCH OR DEVELOPMENT

Not Applicable.

### INCORPORATION-BY-REFERENCE OF MATERIAL SUBMITTED ON A COMPACT DISC

Not Applicable.

### BACKGROUND OF THE INVENTION

### Technical Field of the Invention

This invention relates to data storage and/or retrieval and more particularly to bit sequence based data storage and/or retrieval.

### Description of Related Art

As is known, data storage involves partitioning a file into an ordered series of data blocks and/or an ordered series of data objects. The data blocks and/or data object may be stored locally in a user's computer memory and/or stored via the cloud.

Compression is a known technique to reduce the size of a file before it is stored. For example, MPEG video compression compresses a video file by about 10× to 20×. As such, the amount of memory needed to store a compressed video file is 10-20 times smaller than the uncompressed video file.

To protect against loss of data due to memory failure or other causes, stored data is replicated. One form of data replication is simply to make one or more copies of a file and store the copies in different memory devices. Another form of data replication is to use error encoding. Depending on the error encoding scheme, 1.2 to 1.8 times the file size is stored to allow recovery of the file if some memory devices fail.

Data deduplication is a known technique to reduce the amount of data being stored by eliminating duplicate copies of data. Data deduplication can become challenging to implement when copyright laws require unique copies to be maintained.

Even with the various techniques to reduce the amount of data to store for a file, a portion thereof, and/or duplicates thereof, it is estimated that the amount of data being stored is doubling every two to four years. As the amount of data stored increases, the risk of loss of data increases as does the risk of unauthorized access to it.

### BRIEF DESCRIPTION OF THE SEVERAL VIEWS OF THE DRAWING(S)

The patent or application file contains at least one drawing executed in color. Copies of this patent or patent application publication with color drawing(s) will be provided by the Office upon request and payment of the necessary fee.

FIG. 1A is a schematic block diagram of an example of a system using bit-sequence-storage;

FIG. 1B is a schematic block diagram of another example of a system using bit-sequence-storage;

FIG. 1C is a schematic block diagram of another example of a system using bit-sequence-storage;

FIG. 1D is a schematic block diagram of an example of files being created from a collection of bit sequences;

FIGS. 2A-2E are schematic block diagrams of example embodiments of a computing entity;

FIGS. 3A-3D are schematic block diagrams of example embodiments of a computing device;

FIG. 4 is a schematic block diagram of an example of a system having circulating bit-sequence-storage;

FIG. 5 is a schematic block diagram of an example of a system having non-circulating bit-sequence-storage;

FIG. 6 is a schematic block diagram of an example embodiment of an infrastructure device;

FIG. 7 is a schematic block diagram of another example embodiment of an infrastructure device;

FIG. 8 is a schematic block diagram of an example of computing entities recovering a data file and/or an application file from respective index tables;

FIG. 9A is a schematic block diagram of an example of an index table and corresponding bit sequences of a file;

FIG. 9B is a schematic block diagram of another example of an index table and corresponding bit sequences of a file;

FIGS. 10A-10M are diagrams of various examples of symbols;

FIG. 11 is a schematic block diagram of an example of obtaining index tables as images of symbols to retrieve bit sequences and reconstruct therefrom a data file, a user application file, an operating system, and/or a driver;

FIG. 12 is a schematic block diagram of an example of converting a file into bit sequences and corresponding symbols, which are used to produce an index table;

FIG. 13 is a schematic block diagram of an example of symbols of an index table being used to identify packets that contain at least a portion of a bit sequence;

FIG. 14A is a schematic block diagram of an example of a packet for use in a circulating bit-sequence-storage system;

FIG. 14B is a schematic block diagram of an example of a circulating packet for use in a circulating bit-sequence-storage system;

FIG. 14C is a schematic block diagram of an example of a header of a request packet for a packet of a circulating bit-sequence-storage system;

FIG. 14D is a schematic block diagram of an example of a header of a response packet for a packet of a circulating bit-sequence-storage system;

FIG. 15 is a logic diagram of an example of a method for an infrastructure device processing packets in a circulating bit-sequence-storage system;

FIG. 16 is a logic diagram of another example of a method for an infrastructure device processing packets in a circulating bit-sequence-storage system;

FIGS. 17A and 17B are a logic diagram of an example of a method for computing entity to retrieve in a file in a bit-sequence-storage system;

FIG. 18A is a schematic block diagram of an example of a packet for use in a non-circulating bit-sequence-storage system;

FIG. 18B is a schematic block diagram of an example of a packet for a packet for use in a non-circulating bit-sequence-storage system;

FIG. 18C is a schematic block diagram of an example of a header of a request packet for a packet of a non-circulating bit-sequence-storage system;

FIG. 18D is a schematic block diagram of an example of a header of a response packet for a packet of a non-circulating bit-sequence-storage system;

FIG. 19 is a logic diagram of an example of a method for an infrastructure device processing packets in a non-circulating bit-sequence-storage system;

FIG. 20A is a schematic block diagram of an example of a bit sequence and corresponding cyclic redundancy check (CRC) value;

FIG. 20B is a schematic block diagram of an example of dividing the bit sequence of FIG. 20A into a plurality of bit sequence segments;

FIG. 20C is a schematic block diagram of an example of a packet format for a bit sequence segment;

FIG. 20D is a schematic block diagram of an example of copies of the packets of segments of the bit sequence;

FIG. 21 is a logic diagram of an example of a method for detecting corruption of a packet in a bit-sequence-storage system;

FIG. 22 is a schematic block diagram of an example of various categorizations for organizing bit sequences;

FIG. 23 is a schematic block diagram of an example of partitioning a file into data words, metadata for the data words, and meta data for the file;

FIG. 24 is a schematic block diagram of an example of partitioning a word processing file into data words, metadata for the data words, and metadata for the file;

FIG. 25 is a schematic block diagram of an example of various applications and the data files created therefrom, each may use one or more bit sequence categories;

FIG. 26 is a logic diagram of an example of a method for identifying bit sequences in files;

FIG. 27 is a schematic block diagram of an example of grouping data words of a file for analysis per the method of FIG. 26;

FIG. 28 is a schematic block diagram of another example of grouping data words of a file for analysis per the method of FIG. 26;

FIG. 29A is a schematic block diagram of another example of grouping data words of a file for analysis per the method of FIG. 26;

FIG. 29B is a schematic block diagram of another example of grouping data words of a file for analysis per the method of FIG. 26;

FIG. 30 is a schematic block diagram of another example of corresponding grouping data words of various files;

FIG. 31A is a schematic block diagram of a bit sequence including a plurality of data word groups, the bit sequence is represented by a symbol;

FIG. 31B is a schematic block diagram of an example of the data word groups of FIG. 31A with a different ordering, which is represented by the same symbol shape with a different color;

FIG. 31C is a schematic block diagram of another example of the data word groups of FIG. 31A with a different ordering, which is represented by the same symbol shape with a different color;

FIG. 32 is a schematic block diagram of an example of a stored index table have colored symbols, where color is used to indicate an order of the data word groups of the corresponding bit sequence, and where the bit sequences are in the system based on one color for the corresponding symbols;

FIG. 33 is a logic diagram of an example of a method for a computing entity to convert a file into bit sequences and create an index table therefrom;

FIG. 34 is a logic diagram of another example of a method for a computing entity to convert a file into bit sequences and create an index table therefrom;

FIG. 35 is a schematic block diagram of an example of identifying a symbol for a group of hexadecimal words;

FIG. 36 is a schematic block diagram of an example of a file system for a bit-sequence-storage system;

FIG. 37 is a schematic block diagram of an example of an embodiment of a symbol generator;

FIG. 38A is a schematic block diagram of an example of a symbol created by a symbol generator;

FIG. 38B is a schematic block diagram of an example of another symbol created by a symbol generator;

FIG. 38C is a schematic block diagram of an example of another symbol created by a symbol generator;

FIG. 39 is a schematic block diagram of another example of an embodiment of a symbol generator;

FIG. 40A is a schematic block diagram of an example of a symbol created by a symbol generator;

FIG. 40B is a schematic block diagram of an example of another symbol created by a symbol generator;

FIG. 40C is a schematic block diagram of an example of another symbol created by a symbol generator;

FIG. 41A is a schematic block diagram of an example of a 16-bit data word and it's corresponding 4-hexadecimal data word;

FIG. 41B is a schematic block diagram of an example of a symbol created by a symbol generator;

FIG. 41C is a schematic block diagram of an example of another symbol created by a symbol generator using color to add information to the symbol;

FIG. 42 is a schematic block diagram of an example of a symbol cell array of a symbol generator;

FIG. 43A is a schematic block diagram of an example of a symbol cell;

FIG. 43B is a schematic block diagram of an example of another symbol cell;

FIG. 43C is a schematic block diagram of an example of another symbol cell;

FIG. 43D is a schematic block diagram of an example of another symbol cell;

FIG. 43E is a schematic block diagram of an example of another symbol cell;

FIG. 43F is a schematic block diagram of an example of another symbol cell;

FIG. 43G is a schematic block diagram of an example of another symbol cell;

FIG. 43H is a schematic block diagram of an example of another symbol cell;

FIG. 43I is a schematic block diagram of an example of another symbol cell;

FIG. 44 is a schematic block diagram of an example of an index scrambler for use by a computing entity;

FIG. 45 is a schematic block diagram of another example of an index scrambler for use by a computing entity;

FIG. 46 is a schematic block diagram of an example of symbol scrambling;

FIG. 47 is a schematic block diagram of an example of an index descrambler for use by a computing entity;

FIG. 48 is a schematic block diagram of an example of on-demand access to files using a scrambled index table;

FIG. 49 is a schematic block diagram of an example of data communication using a scrambled index table;

FIG. 50 is a schematic block diagram of an example of secure bit sequence retrieval based on unique file key;

FIG. 51 is a schematic block diagram of an example of a user device sending packets of symbol requests to the network;

FIG. 52 is a logic diagram of an example of a method for execution by an infrastructure computing entity to verify username, destination address, and/or unique file key for a file;

FIG. 53 is a schematic block diagram of an example of layers of symbols and/or bit sequence groups of a file;

FIG. 54 is a schematic block diagram of an example of layers of symbols groups for a file;

FIG. 55 is a schematic block diagram of another example of layers of symbols and/or bit sequence groups of a file;

FIG. 56 is a schematic block diagram of another example of layers of symbols and/or bit sequence groups of a file;

FIG. 57 is a schematic block diagram of another example of layers of symbols;

FIG. 58 is a schematic block diagram of another example of a symbol being used for multiple layers;

FIG. 59 is a schematic block diagram of another example of a bit sequence arranged in data words;

FIG. 60 is a schematic block diagram of an example of symbol representing a word-based bit sequence;

FIG. 61 is a schematic block diagram of an example of color information of a symbol being used to identified selected data of a word-based bit sequence;

FIG. 62 is a schematic block diagram of another example of color information of a symbol being used to identified selected data of a word-based bit sequence;

FIG. 63 is a schematic block diagram of another example of color information of a symbol being used to identify selected data of a word-based bit sequence;

FIG. 64 is a schematic block diagram of another example of color information of a symbol being used to identify selected data of a word-based bit sequence;

FIG. 65 is a schematic block diagram of an example of a symbol representing a bit sequence that includes a plurality of data words;

FIG. 66 is a schematic block diagram of another example of color information of a symbol being used to identify selected data of a bit sequence for change;

FIG. 67 is a schematic block diagram of an example of a symbol representing a bit sequence that includes a plurality of data words; and

FIG. 68 is a schematic block diagram of another example of color information of a symbol being used to identify selected data of a bit sequence for change.

### DETAILED DESCRIPTION OF THE INVENTION

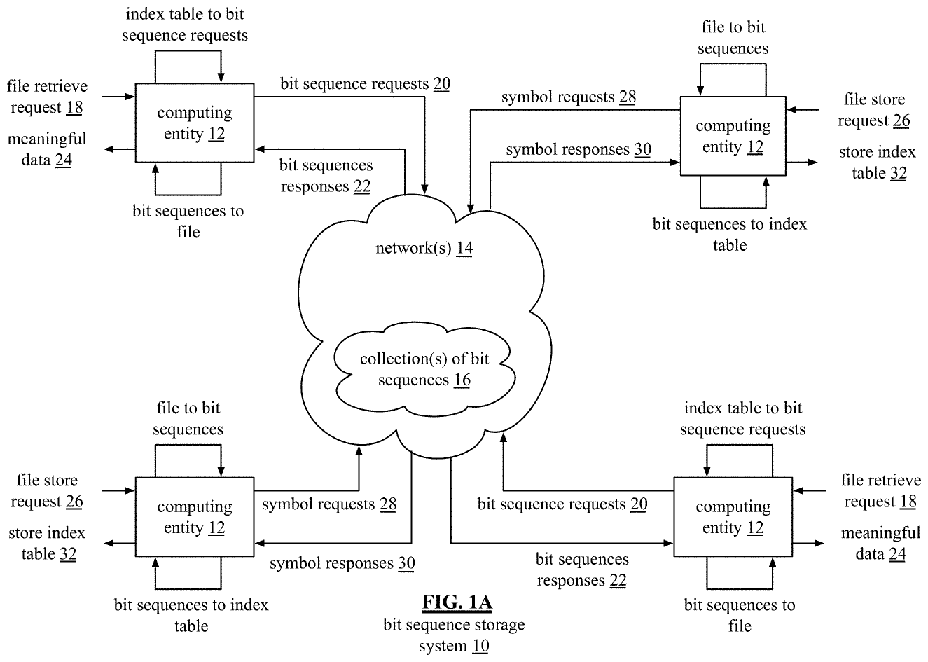

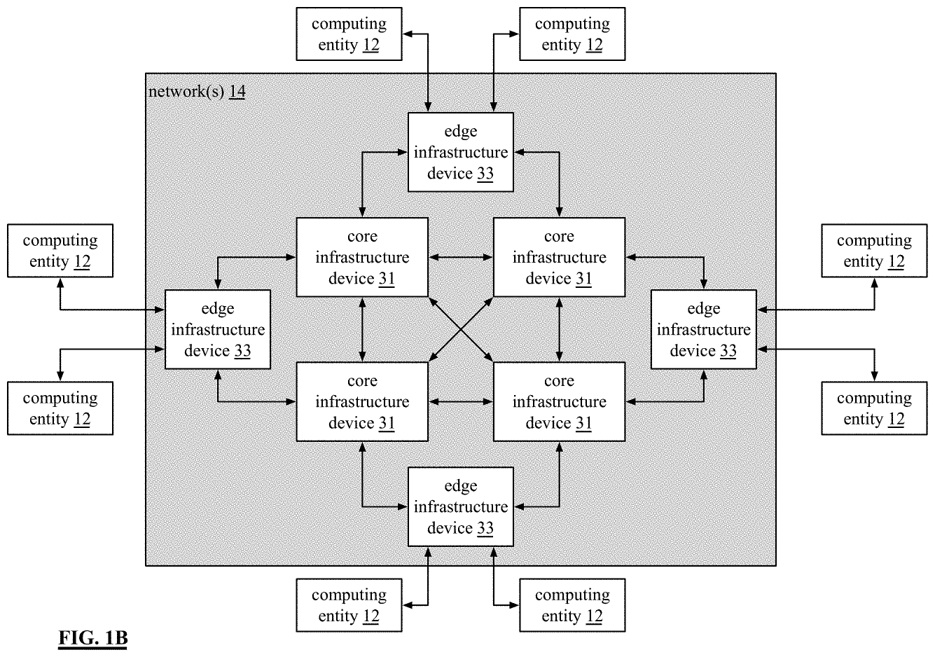

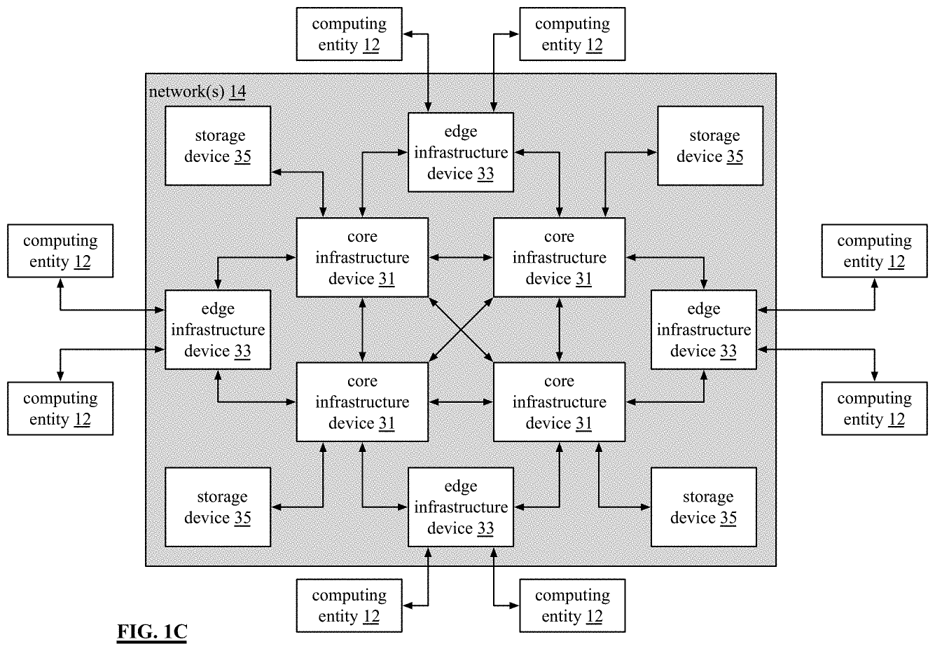

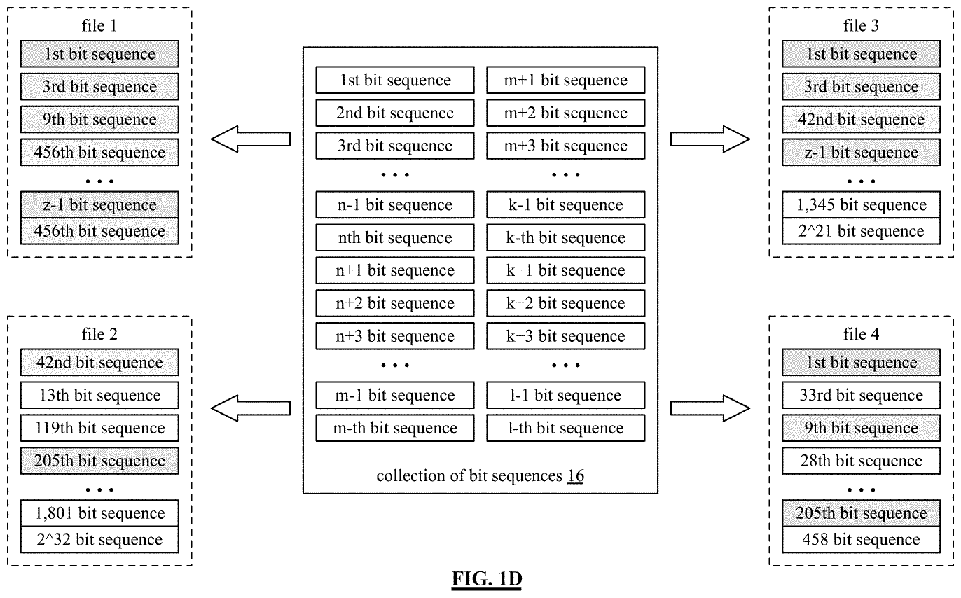

FIG. 1 is a schematic block diagram of an embodiment of a bit-sequence-storage system 10 that includes a plurality of computing entities 12 and one or more networks 14. The network(s) 14 include infrastructure devices (as will be discussed in greater detail with reference to FIGS. 1B, 1C, and 4-7) that support one or more collections of bit sequences 16. In an example, a bit sequence is a string of bits that corresponds to a portion of a file. A file includes a data file, an application file, an operating system, a video file, an image file, an audio file, a driver, a software tool, digital date that readable by a computing entity 12, and/or a set of operational instructions executable by a computing entity 12.

As an example, an application file is a word processing application, and a data file is a document produced using the word processing application. As another example, an application file is an image capture application, and a data file is an image produced using the image capture application.

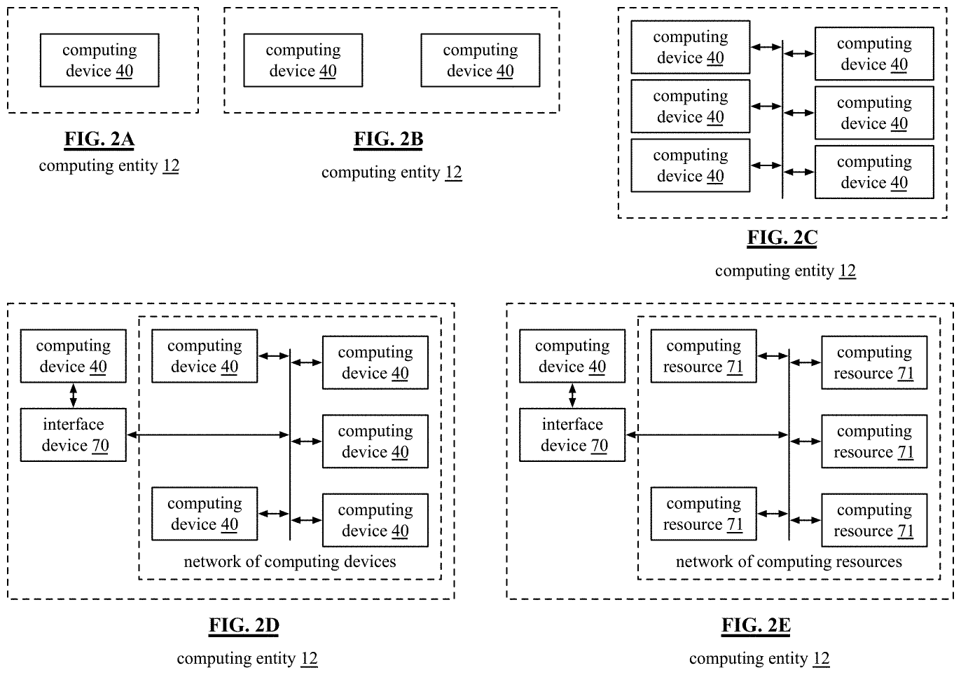

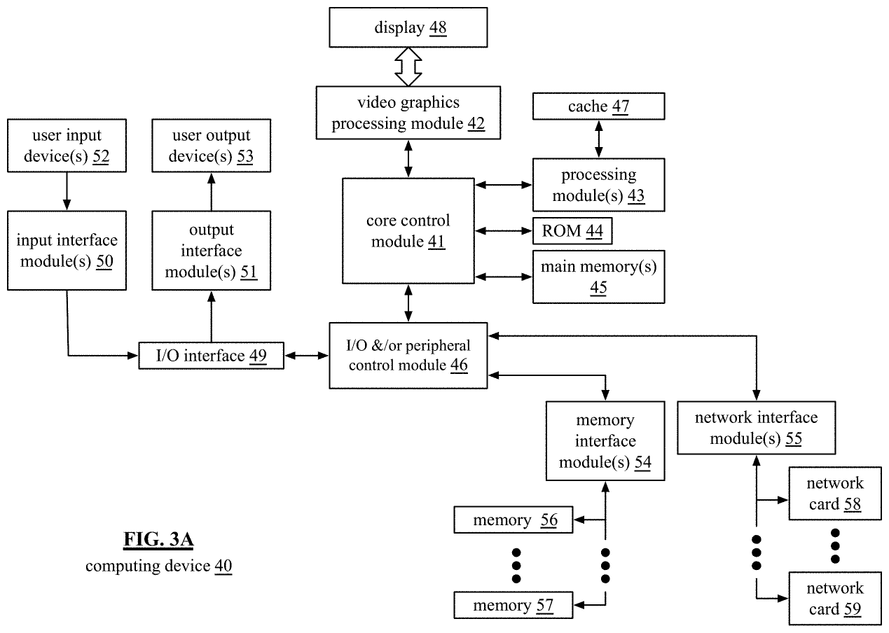

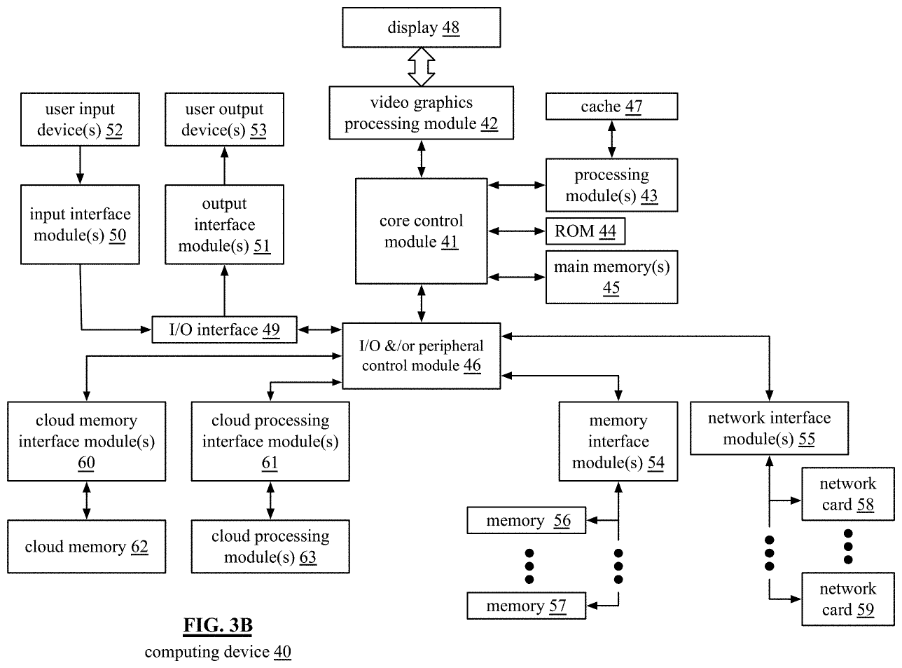

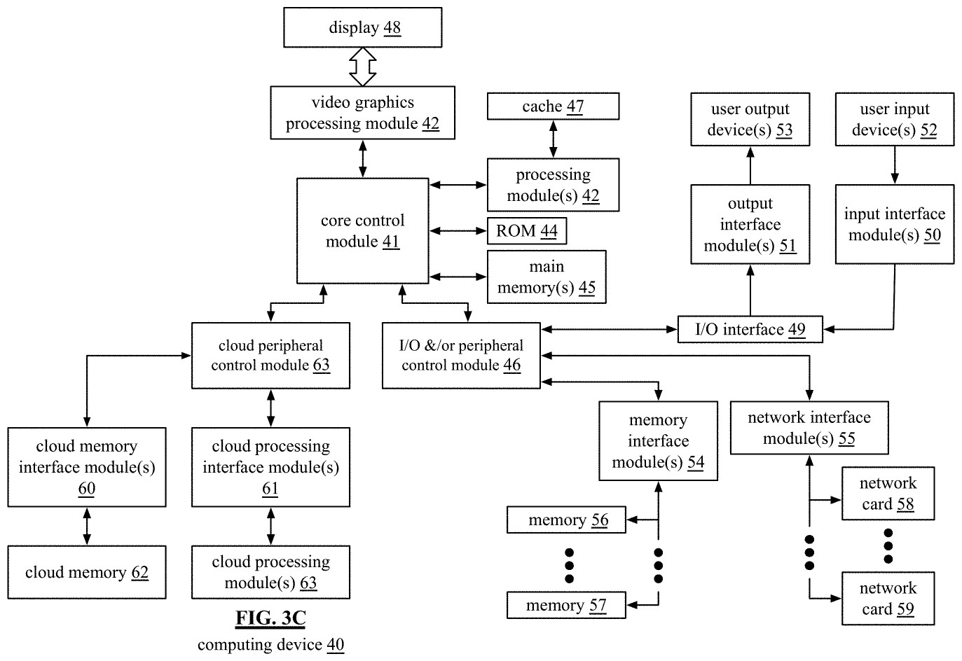

A computing entity 12, which will be described in greater detail with reference to FIGS. 2A-2E and FIGS. 3A-3D, is capable of reading a file that is a compilation of bit sequences from the collection(s) of bit sequences and/or capable of storing a file, or edits thereto, as a compilation of bit sequences from the collection(s) of bit sequences. In this manner, virtually every file could be comprised of bit sequences of the collection(s) of bit sequences.

To read a file (e.g., data file, application file, operating system, driver, other software and/or digital data), a computing entity 12 issues a file retrieval request 18. In an example, a file retrieval request corresponds to a request to open the file. In another example, a file retrieval request corresponds to a download request.

In response to the file retrieval request, the computing entity 12 obtains an index table for the file. An index table includes a plurality of symbols; each symbol representing one or more bit sequences, or a portion of a bit sequence. Note that an index table may include multiple copies of the same symbol, which corresponds to a file including multiple uses of the corresponding bit sequence. Further note that an index table is considerably smaller than the file, from a data size perspective. As an example, the index table is 4 times to 64 times, or more, smaller than the file it represents for a first order index table (e.g., symbols correlate to bit sequences). As another example, the index table is 4*n times to 64*n times smaller than the file it represents for a n^{th} order index table (e.g., symbols correlate to one or more layers of symbols and then to bit sequences).

The computing entity 12 may retrieve the index table in a variety of ways. For example, the computing entity 12 retrieves the index table from its local memory. As another example, the computing entity 12 retrieves the index table from its cloud memory. As yet another example, the computing entity 12 receives the index table from another computing entity or server coupled to the network 14.

Upon obtaining the index table, the computing entity 12 selects a symbol from the index table (e.g., the first symbol in the table). From the symbol, the computing entity 12 generates a bit sequence request 20, which is a request for the bit sequence represented by the symbol. The bit sequence request 20 is sent to the network 14 in one or more packets. The computing entity 12 does the same process for each symbol of the index table.

If a bit sequence request 20 is valid, the network 14 responds with a bit sequence response 22. A bit sequence request is valid if it is sent by a valid computing entity 12, a valid user, is for a valid bit sequence, and/or other security measures.

A bit sequence response 22 is sent to the requesting computing entity 12 as one or more packets. Each packet identifies the requesting computing entity, the bit sequence ID (e.g., a numerical representation of the symbol), and a segment of the bit sequence. This repeats for remaining bit sequence requests and corresponding bit sequence responses.

As the computing entity 12 receives the bit sequences, it assembles the file. For a data file, the computing entity utilizes an application, the operating system, and/or one or more drives to convert the data file into meaningful data.

To store a file as a series of bit sequences, a computing entity 12 receives a file store request 26. For example, the file store request 26 is a save command. In response to the file store request 26, the computing entity 12 convers the file in a series of bit sequences.

For a bit sequence, the computing entity 12 sends a symbol request 28 to the network. The symbol request 28 includes the bit sequence and a request to identify the corresponding symbol. If the symbol request 28 is valid, the computing entity 12 receives a symbol response 30. A symbol request 28 is valid when it includes a valid bit sequence, is from a valid computing entity, is associated with a valid user, and/or passes other validation criteria. Alternatively, the computing entity 12 determines an appropriate symbol for the bit sequence from a library of symbol to bit sequence combinations that are supported by the network 14.

Upon receiving a symbol response 30, the computing entity 12 extracts a symbol (e.g., a glyph, an alpha-numeric, an image, etc.) and adds it to an index table for the file. The computing entity 12 does this for the remaining bit sequences of the file. As the index table is being created, the computing entity 12 stores it in local memory and/or cloud memory.

In bit-sequence-storage system 10, the amount of data being stored is substantially reduced in comparison to conventional storage systems due to the combination of data compression via the use of symbols to represent bit sequences and data deduplication (e.g., every file in the system is a combination of bit sequences, which are available via the network in a limited quantity). In some embodiments, the reduction is storage is from 4*n to 64*n depending on the symbols used and the size of the corresponding bit sequences. In addition, security of data is enhanced since a majority of data being transmitted via the network is bit sequences, which have no meaning until reassembled into a file. Other benefits, with respect to conventional storage systems, include easier compliance with copyright laws, easier digital rights management, improved data security, reduced opportunity for bad actors to corrupt data, reduced opportunity for sensitive data to be compromised, and/or reduced memory requirements.

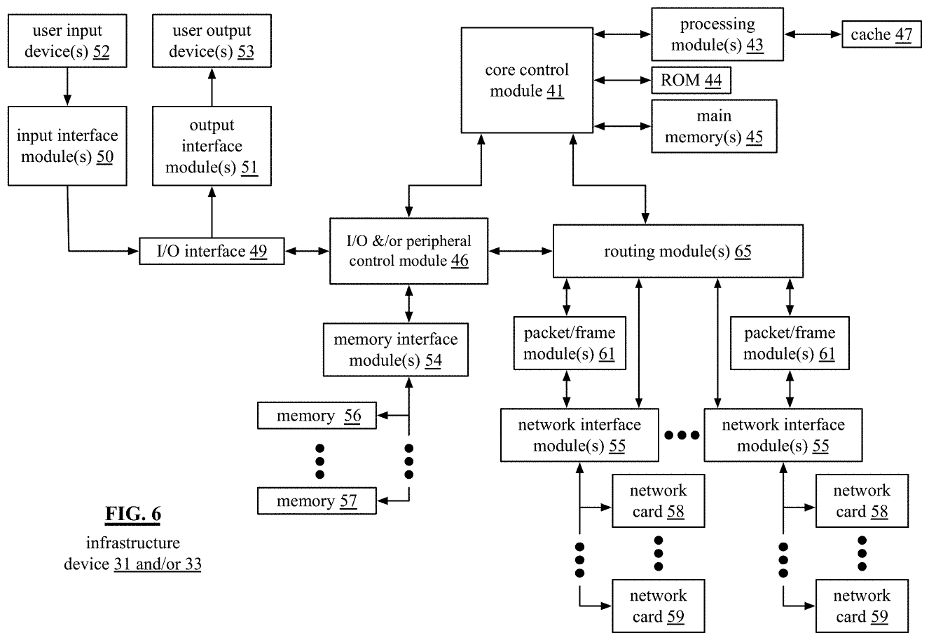

FIG. 1B is a schematic block diagram of an example of a system using bit-sequence-storage. In this example, the network 14 includes a plurality of edge infrastructure devices 33 and a plurality of core infrastructure devices 31. The architecture of an edge infrastructure device and of a core infrastructure device are similar. Examples of edge and core infrastructure device architectures are provided in FIGS. 6 and 7.

An edge infrastructure device 33 is a network device that functions essentially as a network entry point or network exits point and provides data flow between networks and/or between an external device and a network. An edge infrastructure device 33 may further perform functions such as transmission, routing, processing, monitoring, filtering, translation, security, Dynamic Host Configuration Protocol (DHCP) services, and/or storage of data entering and/or exiting a network. Examples of edge devices include an edge router, a firewall, routing switch, or a wireless access point.

A core infrastructure device 31 is one or more of a switch, a router, a bridge, and/or a repeater. A switch is a multi-port device that generally functions to route packets from one device to another within a network and typically operates at the data link OSI layer and/or at the network OSI layer. A router essentially charts a path through the plurality of core infrastructure devices for packet and/or frame transmission. A router may include, or work in conjunction with, a channel service unit/data service unit (CDU/DAU), which translates LAN framing to WAN framing and vice versa.

A bridge connects two or more hosts or network segments together and generally functions to store and forward frames and/or packets between different segments of the network. To facilitate the forwarding of frames, a bridge typically includes a Media Access Control (MAC) addresses, which, when interpreted, indicates whether a frame or packet should be transmission to a segment or whether it should be blocked.

A repeater operates at the physical OSI layer and functions to extend the distance a data transmission signal can travel. It does so by amplifying magnitude, or power, of data transmission signals (i.e., signals representing frames or packets) it receives and forward them to a next destination within a network.

In this example network, the collection of bit sequences 16 is circulating within the network(s) 14. For example, an infrastructure device (core or edge) 31 or 33 receives a frame or packet containing at least a portion of a bit sequence and forwards it to another infrastructure device. When the other infrastructure device receives the frame or packet, it forwards the packet or frame to yet another infrastructure device. As such, the frame or packet is in continual motion. Note that an infrastructure device may temporarily store the frame or packet for a period of time (e.g., a few milliseconds to tens of minutes) before forwarding the frame or packet to the next infrastructure device.

In this example system, a majority of the data traffic of the network is the circulating of the bit sequences and responding to bit sequence requests. For this example, infrastructure devices could be modified or built in accordance with the concepts disclosed herein to support a bit-sequence storage system. This shifts the function of the internet from a data transport structure to a data storage and data request response structure. In this regard, a majority of data flowing through the internet is no longer file specific, its file generic (e.g., files are comprised of various combinations of bit sequences from the same set of bit sequences). As such, the data flowing through the internet is generic and has no meaning until selected generic bit sequences are properly combined to produce files.

Note that, in 2018, it was estimated that 2.5×10¹⁸ bytes (i.e., 2.5 exa-bytes) of data was being transmitted within the internet at a given time. Further note that, in 2020, it was estimated that 6.8×10²¹ bytes (i.e., 6.8 zettabytes) of data was stored. From these data points and assuming that the compression ratio from symbol to bit sequence is 64× (e.g., 2⁶) then the 6.8 zettabytes of data can be represented by 1.06×10²⁰ bytes of symbols, which is 106 exabytes. Also, if a bit sequence is 16 Kbytes of data (16×10³), there are 1.54×10¹¹ different bit sequences (154 billion different bit sequences), and there are 1,000 copies of each bit sequence, then there would be 2.5×10¹⁸ bytes of bits sequences circulating the internet. Note that the more bits a symbol can represent, the higher data compression rate. For example, a symbol, which can be represented as an image of about 2 KB, represents a bit sequence of at least 8 KB up to 128 KB or more.

FIG. 1C is a schematic block diagram of another example of a system using bit-sequence-storage. In this example, the network 14 includes edge infrastructure devices 33, core infrastructure devices 33, and storage devices 35. The storage devices 35 stored the bit sequences for a period of time. Thus, the bit sequences are not continually circulating the network, they are stored until a copy is requested by a user computing entity 12.

A storage device 35 may store a collection of bit sequences or a portion thereof. For example, a first storage device 35 stores a first copy of the collection of bit sequences, a second storage device 35 stores a second copy of the collection of bit sequences, and so on. As another example, a storage device 35 stores a copy of a collection of bit sequences, but the bit sequences are of random copies (e.g., copy 1 for bit sequence 1, copy 3 for bit sequence 2, etc.).

The storage devices 35 may periodically exchange copies of one or more bit sequences to aid in security of the bit sequences. For example, every thirty minutes, storage devices 35 exchange 100 bit sequence copies. As subsequently discussed, a copy number is included in the header of the packet or frame and is part of the addressing. Thus, by exchanging bit sequences, the addresses of the bit sequences being stored by a storage device is changing making more difficult for a bad actor to damage a bit sequence.

FIG. 1D is a schematic block diagram of an example of files being created from a collection of bit sequences. As shown, a collection of bit sequences includes a large number of bit sequences. The bit sequences by themselves have no meaning, thus provide no information regarding files that they represent once properly reconstructed. Color is used in this figure to aid in the understanding that files are formed from the same collection of bit sequences.

Each of the four files includes a plurality of bit sequences. Each plurality of bit sequences is a sub-set of the collection of bit sequences and may include multiple instances of a bit sequence. From file to file, a bit sequence can be used multiple times. As color coordinated, bit sequence 1 is included in files 1, 3, and 4; bit sequence 3 is included in files 1 and 3; bit sequence 9 is included in files 1 and 4; bit sequence z−1 is used in files 1 and 3; bit sequence 42 is used in files 2 and 3; and bit sequence 205 is used in files 2 and 4. Note that bit sequence 456 is used twice in file 1.

FIGS. 2A-2E are schematic block diagrams of example embodiments of a computing entity. FIG. 2A is schematic block diagram of an embodiment of a computing entity 16 that includes a computing device 40 (e.g., one of the embodiments of FIGS. 3A-3D). A computing device may function as a user computing device, a server, a system computing device, a data storage device, a data security device, a networking device, a user access device, a cell phone, a tablet, a laptop, a printer, a game console, a satellite control box, a cable box, etc.

FIG. 2B is schematic block diagram of an embodiment of a computing entity 16 that includes two or more computing devices 40 (e.g., two or more from any combination of the embodiments of FIGS. 3A-3D). The computing devices 40 perform the functions of a computing entity in a peer processing manner (e.g., coordinate together to perform the functions), in a master-slave manner (e.g., one computing device coordinates and the other support it), and/or in another manner.

FIG. 2C is schematic block diagram of an embodiment of a computing entity 16 that includes a network of computing devices 40 (e.g., two or more from any combination of the embodiments of FIGS. 3A-3D). The computing devices are coupled together via one or more network connections (e.g., WAN, LAN, cellular data, WLAN, etc.) and preform the functions of the computing entity.

FIG. 2D is schematic block diagram of an embodiment of a computing entity 16 that includes a primary computing device (e.g., any one of the computing devices of FIGS. 3A-3D), an interface device (e.g., a network connection), and a network of computing devices 40 (e.g., one or more from any combination of the embodiments of FIGS. 3A-3D). The primary computing device utilizes the other computing devices as co-processors to execute one or more the functions of the computing entity, as storage for data, for other data processing functions, and/or storage purposes.

FIG. 2E is schematic block diagram of an embodiment of a computing entity 16 that includes a primary computing device (e.g., any one of the computing devices of FIGS. 3A-3D), an interface device (e.g., a network connection) 70, and a network of computing resources 71 (e.g., two or more resources from any combination of the embodiments of FIGS. 3A-3D). The primary computing device utilizes the computing resources as co-processors to execute one or more the functions of the computing entity, as storage for data, for other data processing functions, and/or storage purposes.

FIGS. 3A-3D are schematic block diagrams of example embodiments of a computing device. FIG. 3A is a schematic block diagram of an embodiment of a computing device 40 that includes a plurality of computing resources. The computing resource include a core control module 41, one or more processing modules 43, one or more main memories 45, a read only memory (ROM) 44 for a boot up sequence, cache memory 47, a video graphics processing module 42, a display 48 (optional), an Input-Output (I/O) peripheral control module 46, an I/O interface module 49 (which could be omitted), one or more input interface modules 50, one or more output interface modules 51, one or more network interface modules 55, and one or more memory interface modules 54. A processing module 43 is described in greater detail at the end of the detailed description of the invention section and, in an alternative embodiment, has a direction connection to the main memory 45. In an alternate embodiment, the core control module 41 and the I/O and/or peripheral control module 46 are one module, such as a chipset, a quick path interconnect (QPI), and/or an ultra-path interconnect (UPI).

Each of the main memories 45 includes one or more Random Access Memory (RAM) integrated circuits, or chips. For example, a main memory 45 includes four DDR4 (4^{th} generation of double data rate) RAM chips, each running at a rate of 2,400 MHz. In general, the main memory 45 stores data and operational instructions most relevant for the processing module 43. For example, the core control module 41 coordinates the transfer of data and/or operational instructions between the main memory 45 and the memory 56-57. The data and/or operational instructions retrieve from memory 56-57 are the data and/or operational instructions requested by the processing module or will most likely be needed by the processing module. When the processing module is done with the data and/or operational instructions in main memory, the core control module 41 coordinates sending updated data to the memory 56-57 for storage.

The memory 56-57 includes one or more hard drives, one or more solid state memory chips, and/or one or more other large capacity storage devices that, in comparison to cache memory and main memory devices, is/are relatively inexpensive with respect to cost per amount of data stored. The memory 56-57 is coupled to the core control module 41 via the I/O and/or peripheral control module 46 and via one or more memory interface modules 54. In an embodiment, the I/O and/or peripheral control module 46 includes one or more Peripheral Component Interface (PCI) buses to which peripheral components connect to the core control module 41. A memory interface module 54 includes a software driver and a hardware connector for coupling a memory device to the I/O and/or peripheral control module 46. For example, a memory interface 54 is in accordance with a Serial Advanced Technology Attachment (SATA) port.

The core control module 41 coordinates data communications between the processing module(s) 43 and the network(s) 14 via the I/O and/or peripheral control module 46, the network interface module(s) 55, and a network card 58 or 59. A network card 58 or 59 includes a wireless communication unit or a wired communication unit. A wireless communication unit includes a wireless local area network (WLAN) communication device, a cellular communication device, a Bluetooth device, and/or a ZigBee communication device. A wired communication unit includes a Gigabit LAN connection, a Firewire connection, and/or a proprietary computer wired connection. A network interface module 55 includes a software driver and a hardware connector for coupling the network card to the I/O and/or peripheral control module 46. For example, the network interface module 55 is in accordance with one or more versions of IEEE 802.11, cellular telephone protocols, 10/100/1000 Gigabit LAN protocols, etc.

The core control module 41 coordinates data communications between the processing module(s) 43 and input device(s) 52 via the input interface module(s) 50, the I/O interface 49, and the I/O and/or peripheral control module 46. An input device 52 includes a keypad, a keyboard, control switches, a touchpad, a microphone, a camera, etc. An input interface module 50 includes a software driver and a hardware connector for coupling an input device to the I/O and/or peripheral control module 46. In an embodiment, an input interface module 50 is in accordance with one or more Universal Serial Bus (USB) protocols.

The core control module 41 coordinates data communications between the processing module(s) 43 and output device(s) 53 via the output interface module(s) 51 and the I/O and/or peripheral control module 46. An output device 53 includes a speaker, auxiliary memory, headphones, etc. An output interface module 51 includes a software driver and a hardware connector for coupling an output device to the I/O and/or peripheral control module 46. In an embodiment, an output interface module 46 is in accordance with one or more audio codec protocols.

The processing module 43 communicates directly with a video graphics processing module 42 to display data on the display 48. The display 48 includes an LED (light emitting diode) display, an LCD (liquid crystal display), and/or other type of display technology. The display has a resolution, an aspect ratio, and other features that affect the quality of the display. The video graphics processing module 42 receives data from the processing module 43, processes the data to produce rendered data in accordance with the characteristics of the display, and provides the rendered data to the display 48.

FIG. 3B is a schematic block diagram of an embodiment of a computing device 40 that includes a plurality of computing resources similar to the computing resources of FIG. 3A with the addition of one or more cloud memory interface modules 60, one or more cloud processing interface modules 61, cloud memory 62, and one or more cloud processing modules 63. The cloud memory 62 includes one or more tiers of memory (e.g., ROM, volatile (RAM, main, etc.), non-volatile (hard drive, solid-state, etc.) and/or backup (hard drive, tape, etc.)) that is remoted from the core control module and is accessed via a network (WAN and/or LAN). The cloud processing module 63 is similar to processing module 43 but is remoted from the core control module and is accessed via a network.

FIG. 3C is a schematic block diagram of an embodiment of a computing device 40 that includes a plurality of computing resources similar to the computing resources of FIG. 3B with a change in how the cloud memory interface module(s) 60 and the cloud processing interface module(s) 61 are coupled to the core control module 41. In this embodiment, the interface modules 60 and 61 are coupled to a cloud peripheral control module 63 that directly couples to the core control module 41.

FIG. 3D is a schematic block diagram of an embodiment of a computing device 40 that includes a plurality of computing resources, which includes include a core control module 41, a boot up processing module 66, boot up RAM 67, a read only memory (ROM) 45, a video graphics processing module 42, a display 48 (optional), an Input-Output (I/O) peripheral control module 46, one or more input interface modules 50, one or more output interface modules 51, one or more cloud memory interface modules 60, one or more cloud processing interface modules 61, cloud memory 62, and cloud processing module(s) 63.

In this embodiment, the computing device 40 includes enough processing resources (e.g., module 66, ROM 44, and RAM 67) to boot up. Once booted up, the cloud memory 62 and the cloud processing module(s) 63 function as the computing device's memory (e.g., main and hard drive) and processing module.

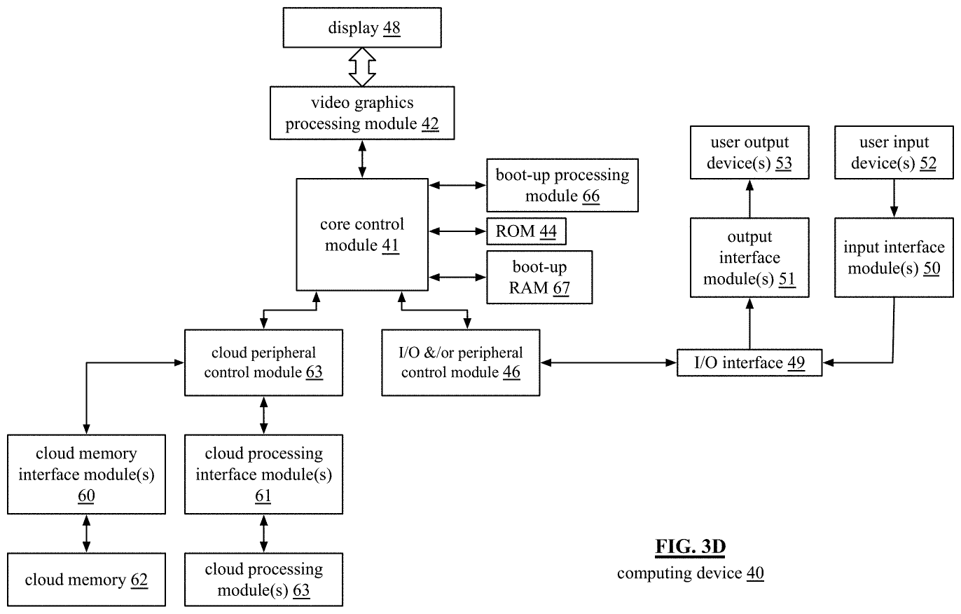

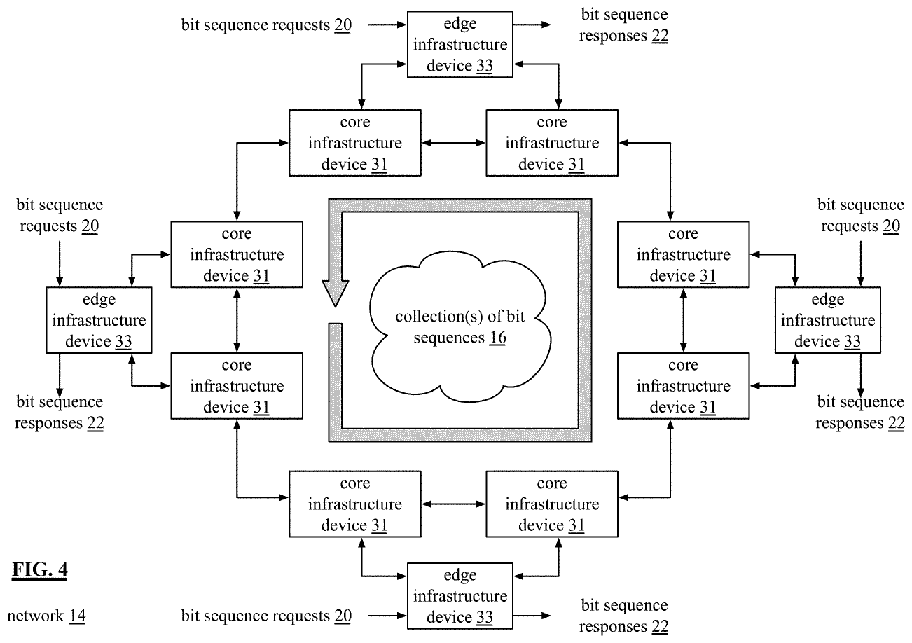

FIG. 4 is a schematic block diagram of an example of a system having circulating bit-sequence-storage. The network(s) 14 of the system includes a plurality of core infrastructure devices 31 and a plurality of edge infrastructure devices 33. In this example, the collection(s) of bit sequences 16 are circulated within the network(s) 14 as discussed with reference to FIG. 1B.

In this example, the edge infrastructure devices 33 receive bit sequence requests from computing entities 12. An edge infrastructure device 33 interprets a bit sequence request 20 to determine whether to process the request and/or forward it to another infrastructure device (edge or core). For example, the edge infrastructure device 33 determines whether it is in possession of a packet or frame that includes at least a portion of the requested bit sequence. If not, the edge infrastructure device forwards the bit sequence request to another infrastructure device.

If edge infrastructure device has the packet or frame, the edge infrastructure device creates a bit sequence response 22, which includes the packet or frame. If the bit sequence response 22 fulfils the bit sequence request (i.e., the packet or frame includes the requested bit sequence or the packet or frame includes the last segment of the bit sequence), the response is complete. If not, the edge infrastructure device 33 updates the bit sequence request to indicate what segment of the bit sequence has been fulfilled and sends the updated bit sequence request to another infrastructure device.

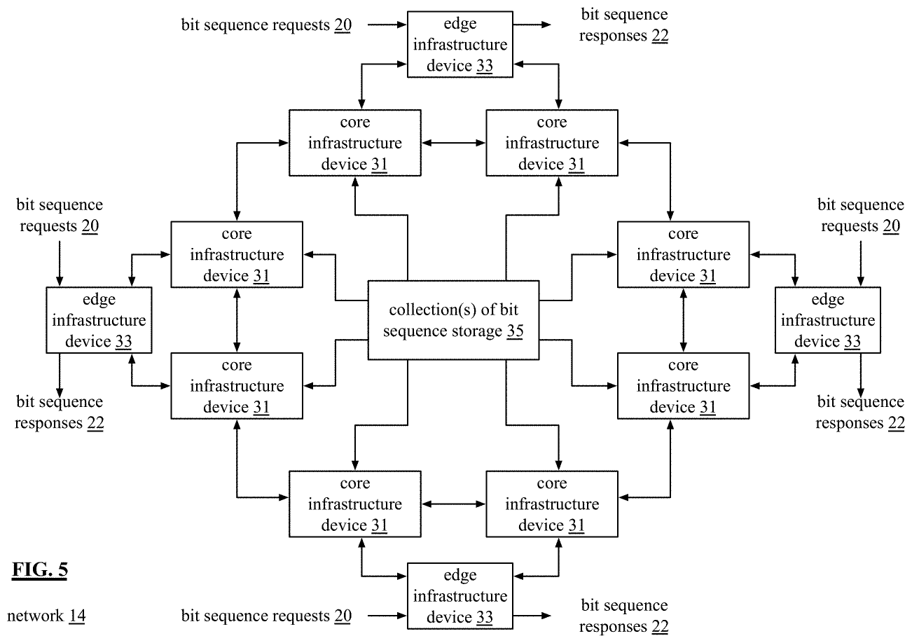

FIG. 5 is a schematic block diagram of an example of a system having non-circulating bit-sequence-storage. The network(s) 14 of the system includes a plurality of core infrastructure devices 31 and a plurality of edge infrastructure devices 33. In this example, the collection(s) of bit sequences 16 are not continually circulated within the network(s) 14 as discussed with reference to FIG. 1C.

In this example, the edge infrastructure devices 33 receive bit sequence requests 20 from computing entities 12. An edge infrastructure device 33 interprets a bit sequence request to determine which bit sequence storage device 35 to forward the request. Note that, in an embodiment of a bit sequence storage device, it is part of an infrastructure device and, in another embodiment of a bit sequence storage device, it is a stand-alone device.

If the edge infrastructure device 33 is the identified bit sequence storage unit, it generates a bit sequence response 22, which includes at least a portion of the requested bit sequence. If the bit sequence response 22 fulfils the bit sequence request (i.e., the packet or frame includes the requested bit sequence or the packet or frame includes the last segment of the bit sequence), the response is complete. If not, the edge infrastructure updates the bit sequence request to indicate what segment of the bit sequence it fulfilled and sends the updated bit sequence request to an infrastructure device for routing to the bit sequence storage device.

If the edge infrastructure device is not the identified bit sequence storage unit, it forwards the bit sequence request to an infrastructure device 31 for routing to the bit sequence storage device. At some later point in time (e.g., microseconds to seconds), the edge infrastructure device 33 receives one or more packets or frames regarding the requested bit sequence. The edge infrastructure device provides the one or more packets of frames as a bit sequence response to the requesting computing entity 12.

FIG. 6 is a schematic block diagram of an example embodiment of an infrastructure device 31 and/or 33 that includes a plurality of computing resources. The computing resource include one or more of a core control module 41, one or more processing modules 43, one or more main memories 45, a read only memory (ROM) 44 for a boot up sequence, cache memory 47, an Input-Output (I/O) peripheral control module 46, an I/O interface module 49 (which could be omitted), one or more input interface modules 50, one or more output interface modules 51, one or more memory interface modules 54, one or more routing modules 65, a plurality of packet/frame modules 61, and a plurality of network modules 55. A processing module 43 is described in greater detail at the end of the detailed description of the invention section and, in an alternative embodiment, has a direction connection to the main memory 45. In an alternate embodiment, the core control module 41 and the I/O and/or peripheral control module 46 are one module, such as a chipset, a quick path interconnect (QPI), and/or an ultra-path interconnect (UPI).

Each of the main memories 45 includes one or more Random Access Memory (RAM) integrated circuits, or chips. For example, a main memory 45 includes four DDR4 (4^{th} generation of double data rate) RAM chips, each running at a rate of 2,400 MHz. In general, the main memory 45 stores data and operational instructions most relevant for the processing module 43. For example, the core control module 41 coordinates the transfer of data and/or operational instructions between the main memory 45 and the memory 56-57. The data and/or operational instructions retrieve from memory 56-57 are the data and/or operational instructions requested by the processing module or will most likely be needed by the processing module. When the processing module is done with the data and/or operational instructions in main memory, the core control module 41 coordinates sending updated data to the memory 56-57 for storage.

The memory 56-57 includes one or more hard drives, one or more solid state memory chips, and/or one or more other large capacity storage devices that, in comparison to cache memory and main memory devices, is/are relatively inexpensive with respect to cost per amount of data stored. The memory 56-57 is coupled to the core control module 41 via the I/O and/or peripheral control module 46 and via one or more memory interface modules 54. In an embodiment, the I/O and/or peripheral control module 46 includes one or more Peripheral Component Interface (PCI) buses to which peripheral components connect to the core control module 41. A memory interface module 54 includes a software driver and a hardware connector for coupling a memory device to the I/O and/or peripheral control module 46. For example, a memory interface 54 is in accordance with a Serial Advanced Technology Attachment (SATA) port.

The core control module 41 coordinates data communications between the processing module(s) 43 and the network(s) via the I/O and/or peripheral control module 46, the network interface module(s) 55, and a network card 58 or 59. A network card 58 or 59 includes a wired communication unit. A wired communication unit includes a Gigabit LAN connection, a Firewire connection, and/or a proprietary computer wired connection. A network interface module 55 includes a software driver and a hardware connector for coupling the network card to the I/O and/or peripheral control module 46. For example, the network interface module 55 is in accordance with one or more versions of IEEE 802.11, cellular telephone protocols, 10/100/1000 Gigabit LAN protocols, etc.

The core control module 41 coordinates data communications between the processing module(s) 43 and input device(s) 52 via the input interface module(s) 50, the I/O interface 49, and the I/O and/or peripheral control module 46. An input device 52 includes a keypad, a keyboard, control switches, a touchpad, a microphone, a camera, etc. An input interface module 50 includes a software driver and a hardware connector for coupling an input device to the I/O and/or peripheral control module 46. In an embodiment, an input interface module 50 is in accordance with one or more Universal Serial Bus (USB) protocols.

The core control module 41 coordinates data communications between the processing module(s) 43 and output device(s) 53 via the output interface module(s) 51 and the I/O and/or peripheral control module 46. An output device 53 includes a speaker, auxiliary memory, headphones, etc. An output interface module 51 includes a software driver and a hardware connector for coupling an output device to the I/O and/or peripheral control module 46. In an embodiment, an output interface module 46 is in accordance with one or more audio codec protocols.

The core control module 41 coordinates processing of circulating packets and/or frames of bit sequences and/or bit sequence segments. For example, a circulating packet or frame of a bit sequence is received via a network card. The network card sends the circulating packet or frame to the packet/frame module 61 via the network interface module 55.

The packet/frame module 61 temporarily stores the packet or frame before sending it to the routing module 65. The routing module determines the next infrastructure device to receive the packet or frame and sends the packet or frame to the next infrastructure device via the network interface module 55 and a network card. Alternatively, the packet/frame module determines the next infrastructure device.

The core control module 41 also coordinates processing of bit sequence requests and bit sequence responses. For example, a bit sequence response is received via a network card, which functions as one or more network ports of the infrastructure device. The bit sequence response is routed to the routing module 65. The routing module is a co-processing module of the infrastructure device and determines what to do with the bit sequence request.

For example, if the routing module 65 determines that the bit sequence request is to be forwarded to another infrastructure device (i.e., the infrastructure device does not current possess the bit sequence or a segment thereof), the routing module sends the bit sequence request to a network interface module 55. The network interface module 55 provides the bit sequence request to a network card, which sends the bit sequence request to another infrastructure device.

If, however, the routing module determines (alone or in combination with the processing module) that the infrastructure device can fulfill at least a portion of the bit sequence request, the routing module 65 accesses one of the packet/frame modules that is temporarily storing the packet or frame of the requested bit sequence, or segment thereof. In one instance, the routing module retrieves the packet or frame from the packet/frame module and generates a bit sequence response therefrom. The bit sequence response is provided to a network card via the network interface module for routing to the requesting computing entity.

In an alternative instance, the routing module instructs the packet/frame module to generate a bit sequence response from the packet or frame. The packet/frame module provides the bit sequence response to a network card via the network interface module for routing to the requesting computing entity.

FIG. 7 is a schematic block diagram of another example embodiment of an infrastructure device 31 and/or 33 that includes a plurality of computing resources similar to the infrastructure device of FIG. 6. In comparison to the embodiment of FIG. 6, this embodiment does not include the plurality of packet/frame modules 61 and it does include a collection of bit sequences being stored in its memory 56-57.

The core control module 41 coordinates processing of bit sequence requests and bit sequence responses. For example, a bit sequence response is received via a network card, which functions as one or more network ports of the infrastructure device. The bit sequence response is routed to the routing module 65. The routing module is a co-processing module of the infrastructure device and determines what to do with the bit sequence request.

For example, if the routing module 65 determines that the bit sequence request is to be forwarded to another infrastructure device (i.e., the infrastructure device is not currently storing the bit sequence or a segment thereof), the routing module sends the bit sequence request to a network interface module 55. The network interface module 55 provides the bit sequence request to a network card, which sends the bit sequence request to another infrastructure device.

If, however, the routing module determines (alone or in combination with the processing module) that the infrastructure device can fulfill at least a portion of the bit sequence request, the routing module 65 accesses one of the memories 56-57 to retrieve the packet or frame of the requested bit sequence, or segment thereof. The routing module then provides the packet or frame to a network card via the network interface module for routing to the requesting computing entity.

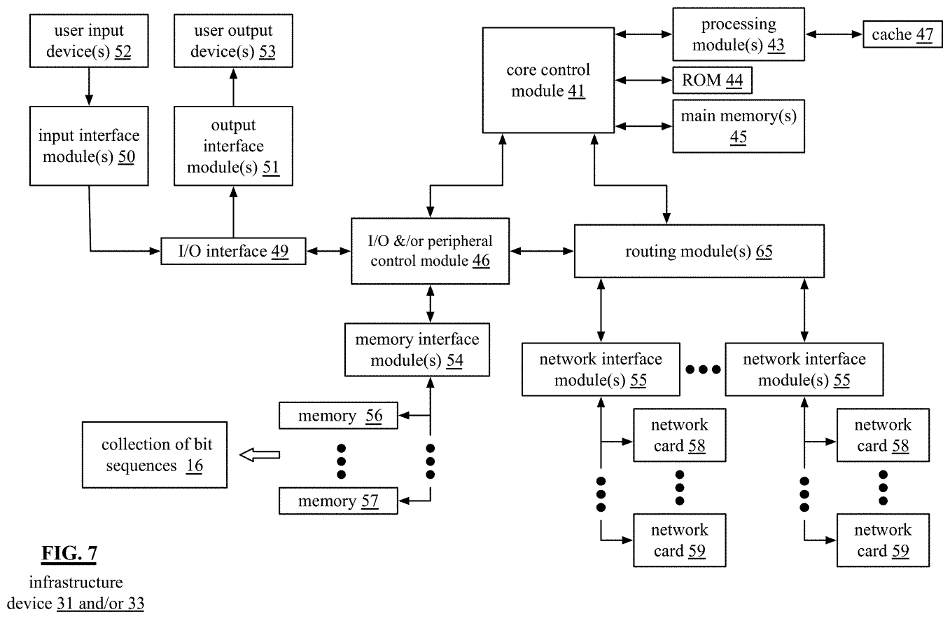

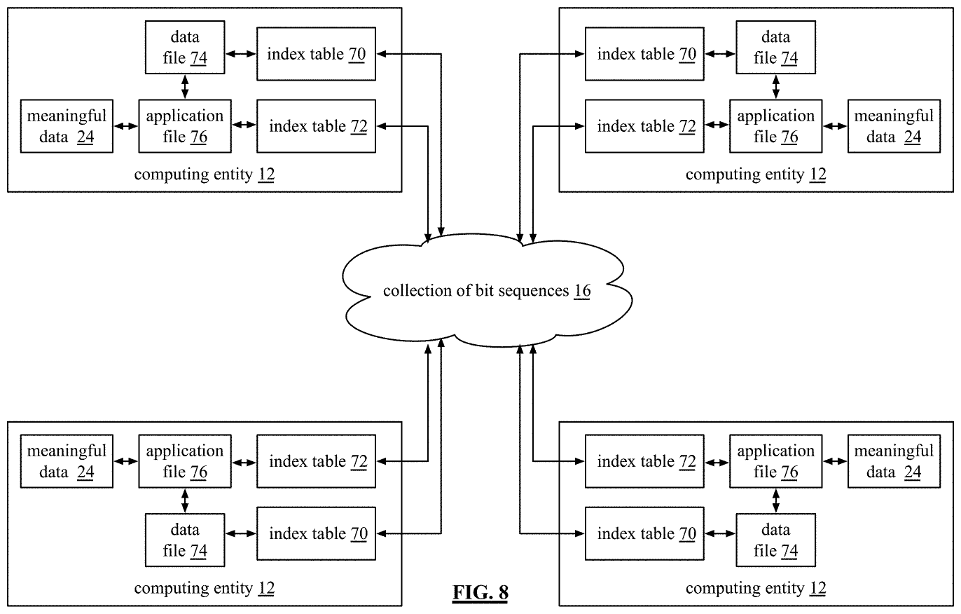

FIG. 8 is a schematic block diagram of an example of computing entities 12 recovering a data file 74 and/or an application file 76 from respective index tables 70 and/or 72. Within a computing entity 12, it includes an index table 70 for a data file 74 and another index 72 table for an application file 76 (e.g., user application, system application, operating system, driver, etc.). For example, the application file 76 is a word processing software program, and the data file 74 is a document created using the word processing software program.

Each of the index tables 70 and/or 72 includes a plurality of symbols, each symbol corresponding to a bit sequence, multiple bit sequences, a portion of a bit sequence, or a set of symbols that corresponds to bit sequences. The computing entity 12 utilizes the index table to retrieve the bit sequences from the collection of bit sequences circulating and/or stored in the network(s). As the bit sequences are recovered, the computing entity 12 reconstructs the data file 74 and the application file 76. When the files are sufficiently reconstructed, the computing entity 12 creates meaningful data 24 (e.g., a graphical representation of a portion of the document).

Note that the data file 74 and/or the application file 76 may be encrypted such that the retrieved bit sequences correspond to encrypted data of the respective file. Thus, the encrypted data would be decrypted by the computing entity 12 prior to rendering the meaningful data.

Also note that the data file 74 and/or application file 76 may be compressed such that the retrieved bit sequences correspond to compressed data of a respective file. Thus, the compressed data would be decompressed by the computing entity prior to rendering the meaningful data.

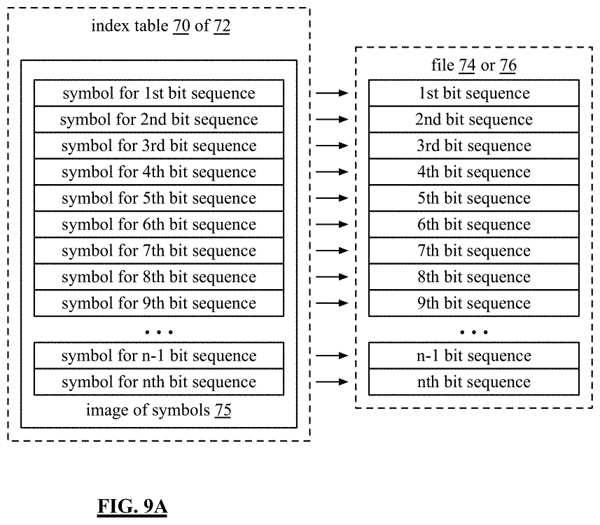

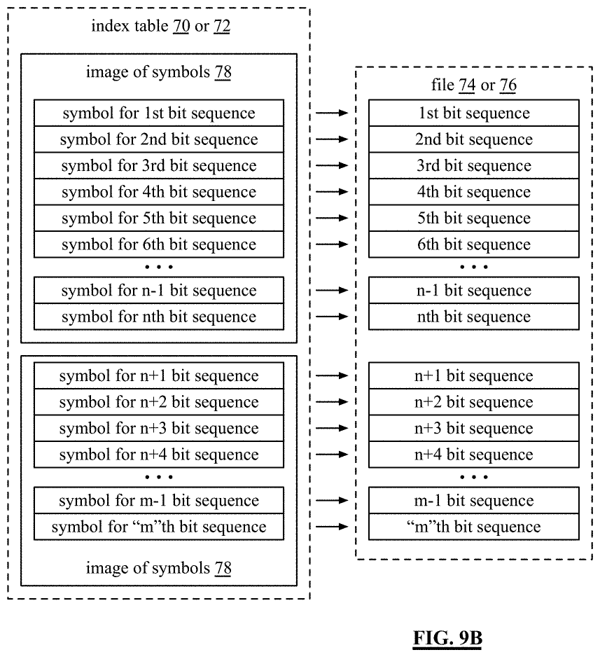

FIG. 9A is a schematic block diagram of an example of an index table 70 and/or 72 and corresponding bit sequences of a file (e.g., data file 74 or application file 76). The file includes a plurality of bit sequences and may include multiple instances of one or more bit sequences. A bit sequence may include a few Kilobytes (KB) of data to tens of Megabytes (MB) of data, or more. In an example, a bit sequence includes a plurality of data words, where a data word is 1 byte to 8 bytes or more in size. The data words of a bit sequence are often repeated in data files and/or in application files.

For each bit sequence, multiple bit sequences, a portion of a bit sequence, or collection of symbols, the index table includes a symbol. The data size of a symbol is much less than its corresponding bit sequence (e.g., 4× to 64× smaller for a direct symbol to bit sequence relationship). An image of the symbols is stored as the index table. An image 75 may be taken in accordance with one of a variety of image protocols. Such image protocols include, but are not limited to, PDF (portable document format), EPS (encapsulated post-script), JPG (joint photographic expert group), TIFF (tagged image file format), GIF (graphics interchange format), PNG (portable network graphics), ZIP, HEIC (high efficiency image file format), SVG (scalable vector graphics), WebP (web picture format), AVIF (AV1 image file format), BMP (bitmap file), PSD (photoshop document), AI (Adobe illustrator artwork), XCF (experimental computing facility), and/or other image format. The data size of image of index table is much less than the size of the data file (e.g., 64×).

FIG. 9B is a schematic block diagram of another example of an index table 70 and/or 72 and corresponding bit sequences of a file 74 and/or 76. The file includes a plurality of bit sequences, and the index table includes a corresponding plurality of symbols. In this example, the index table includes multiple images 78 of the symbols. For instance, symbols for the 1^{st} through n^{th} bit sequences are included in a first image of symbols and the symbols for the n^{th}+1 through the m^{th} bit sequences are included in a second image of symbols. This allows for more efficient parallel retrieval of bit sequences.

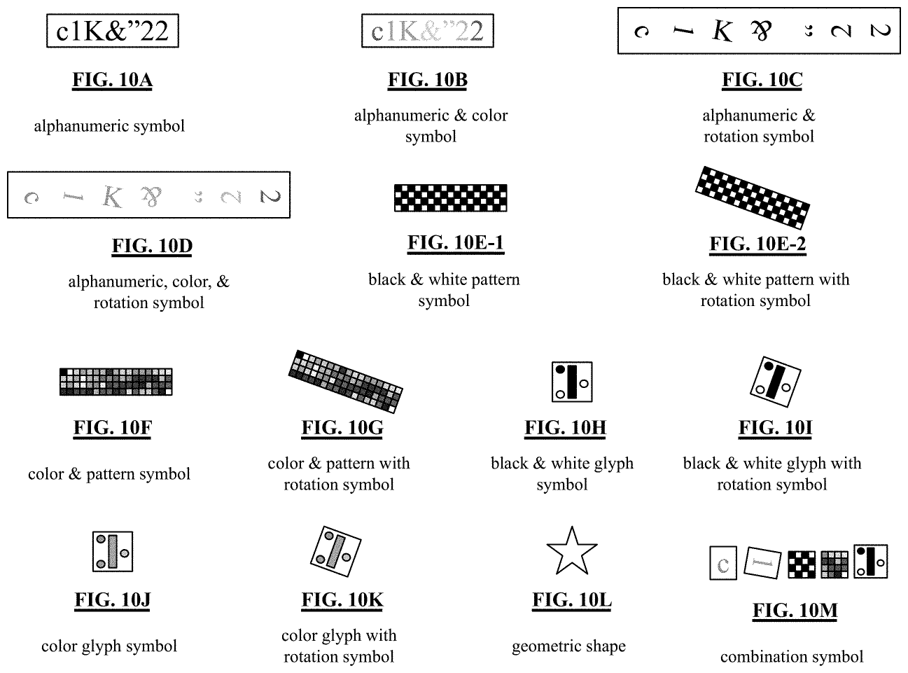

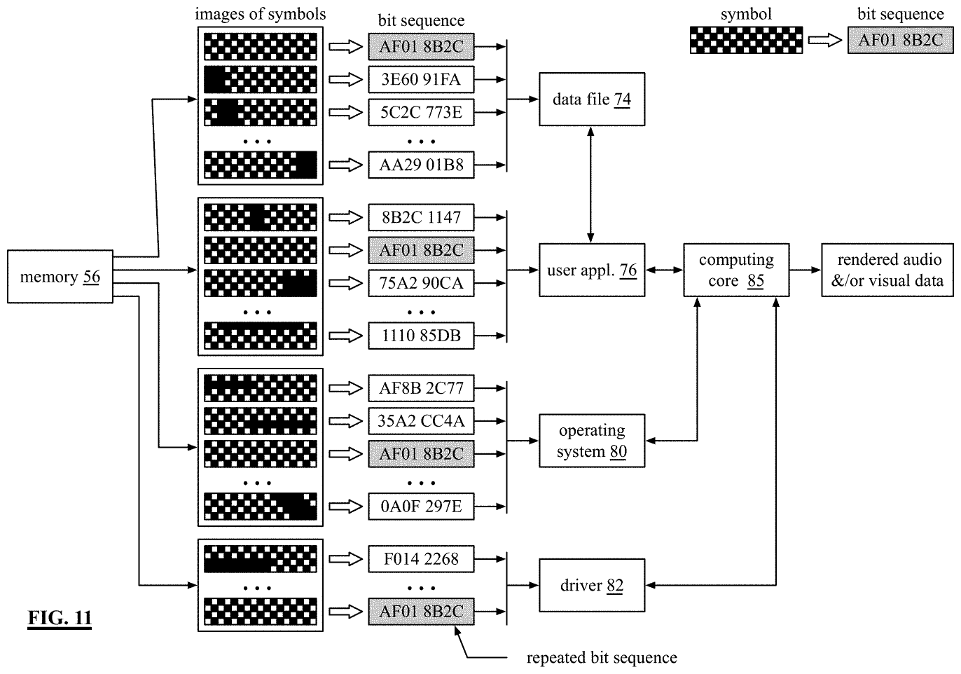

FIGS. 10A-10M are diagrams of various examples of symbols. These are but a few of the billions and billions of options for symbols. FIG. 10A illustrates a symbol that includes one or more alphanumeric values in black & white. In this example, the symbol includes 7 alphanumeric values. Further levels of information may be achieved by using different fonts for the alphanumeric values. For example, if there are 128 different alphanumeric values and a symbol includes 2 alphanumeric values, then there are 128², which is 16,384 options. If four different font are used, then there are 16,384*4=65,536 options.

FIG. 10B illustrates a symbol that includes one or more alphanumeric values in color. In this example, the symbol includes 7 alphanumeric values; each having an associated color. For example, if there are 128 different alphanumeric values, 16 different colors per value, and a symbol includes 2 alphanumeric values, then there are (128*16)², which is 4,194,304 options. If four different fonts are also used, then there are 4,194,304*4=16,777,216 options.

FIG. 10C illustrates a symbol that includes one or more alphanumeric values with rotation. In this example, the symbol includes 7 alphanumeric values; each having an associated rotation. For example, if there are 128 different alphanumeric values, 16 different rotations for each value, and a symbol includes 2 alphanumeric values, then there are (128*16)², which is 4,194,304 options. If four different fonts are also used, then there are 4,194,304*4=16,777,216 options.

FIG. 10D illustrates a symbol that includes one or more alphanumeric values with rotation and color. In this example, the symbol includes 7 alphanumeric values; each having an associated rotation and an associated color. For example, if there are 128 different alphanumeric values, 16 different rotations for each value, 16 different colors for each value, and a symbol includes 2 alphanumeric values, then there are (128*16*16)², which is 1,073,741,824 options. If four different fonts are also used, then there are 1,073,741,824*4=4,294,967,296 options.

FIG. 10E-1 illustrates a symbol that includes a black & white pattern comprised of blocks. If there are 16 blocks per row and there are 4 rows, then there are 64 blocks in the symbol. With each block being black or white, then there are 2⁶⁴ options, which is 18.4×10¹⁸ options.

FIG. 10E-2 illustrates a symbol that includes a black & white pattern comprised of blocks and the pattern can be rotated. If there are 16 blocks per row and there are 4 rows, then there are 64 blocks in the symbol. If the symbol can be rotated in one of 32 portions, then there are 2⁶⁴*2⁵ options, which is 590.3×10¹⁸ options.

FIG. 10F illustrates a symbol that includes a color pattern comprised of blocks. If there are 16 blocks per row and there are 4 rows, then there are 64 blocks in the symbol. If each block can be one of eight colors, then there are 8⁶⁴ options, which is 6.27×10⁵⁷ options.

FIG. 10G illustrates a symbol that includes a color pattern comprised of blocks and the pattern can be rotated. If there are 16 blocks per row and there are 4 rows, then there are 64 blocks in the symbol. If each block can be one of eight colors, and if the pattern can be rotated into one of 32 positions, then there are 200.6×10⁵⁷ options.

FIG. 10H illustrates a symbol that includes a black & white glyph. The glyph may be of any shape, object, and/or combination thereof. As such, there is an almost number of glyphs that could be used for symbols.

FIG. 10I illustrates a symbol that includes a black & white glyph with rotation of the glyph.

FIG. 10J illustrates a symbol that includes a color glyph.

FIG. 10K illustrates a symbol that includes a color glyph with rotation of the glyph.

FIG. 10L illustrates a symbol that includes a black & white geometric shape.

FIG. 10M illustrates a symbol that includes a combination of alphanumeric values, patterns, colors, rotations, and/or glyphs to produce symbols.

FIG. 11 is a schematic block diagram of an example of a computing entity obtaining index tables as images of symbols to retrieve bit sequences and reconstruct therefrom a data file, a user application file, an operating system, and/or a driver. In this example, a symbol is comprised of a plurality of blocks that produces a black & white pattern; each black & white pattern represents a different bit sequence.

A bit sequence is a pattern of data words, where a data word is 1 byte to 16 bytes in size (or other sizes). In this simplified example, a bit sequence includes 8 hexadecimal charters, each pair representing a 1-byte data word. The data file includes its set of bit sequences; the application file includes its set of bit sequences; the operating system includes its set of bit sequences; and the driver includes its set of bit sequences.

Each set of bit sequences for the various files is represented in an index table that includes an image of a plurality of symbols. For example, the bit sequences of the data file are represented by symbols of a first image of symbols; the bit sequences of the application file are represented by symbols of a second image of symbols; the bit sequences of the operating system are represented by symbols of a third image of symbols; and the bit sequences of the driver are represented by symbols of a fourth image of symbols.

The images of symbols are stored in memory 56 readily accessible to the computing entity. For example, the images of symbols are stored in local memory of the computing entity. As another example, the images of symbols are stored in cloud memory of the computing entity. As another example, some of the images of symbols are stored in local memory and other images of symbols are stored in cloud memory. The data size of an image of symbols is significantly less that the data of its corresponding file (e.g., 4× to 64× or more less in size).

In this example, bit sequence AF01 8B2C is present in each of the files, which is highlighted using a grey background. When a bit sequence is used multiple times, it is retrieved once from the network, stored in local memory, and inserted into the reconstructed file as needed.

When a file is at least partially recovered, the computing core 85 (e.g., one or more computing resources) of the computing entity executes the user application 76, operating system 80, and/or the driver 82 with respect to the data file 74 to produce rendered audio and/or visual data. For example, if the user application is a spreadsheet program, then the data file a spreadsheet document and the rendered visual data is graphics representing the spreadsheet document as executed by the spreadsheet program. As another example, if the user application is an audio playback program (e.g., MP3), then the data file is an audio file and the rendered audio data is the encoded audio of the data file processed by the audio playback program.

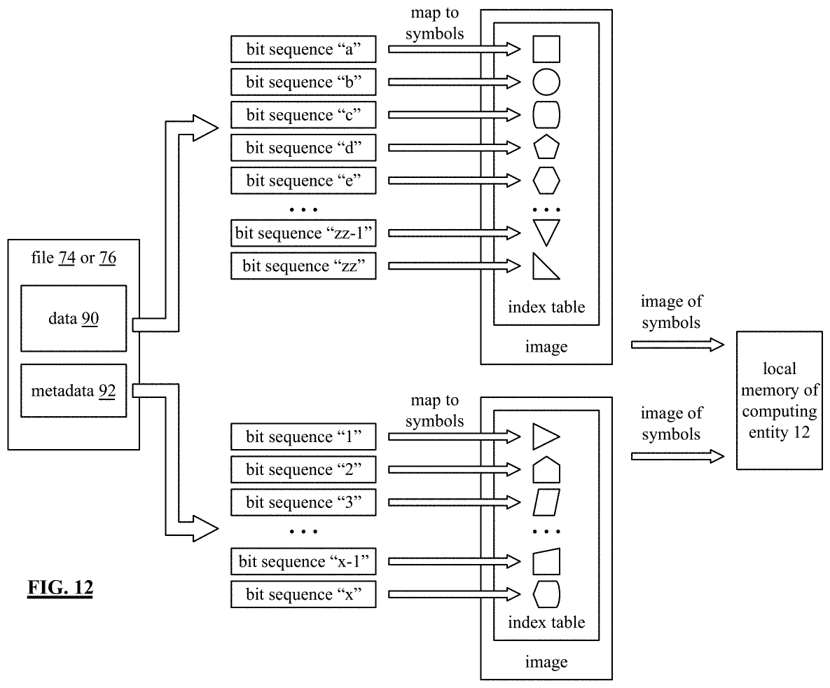

FIG. 12 is a schematic block diagram of an example of converting a file 74 and/or 76 into bit sequences and corresponding symbols, which are used to produce an index table. The file (e.g., data file, user application, system application, operating system, driver, etc.) includes a data section 90 and a metadata section 92. The data section includes the data of the file (e.g., program instructions for an application, words of in a paragraph of a word processing document, etc.) and the metadata section includes information about the file and about the data section.

For example, if the file is a word processing document, then the data section 90 is regarding the characters of the document. The metadata section 92 is regarding information such as font type, size, color, underlining, etc., for the characters. The metadata may still further be regarding information such as margins, paragraph spacing, line spacing, etc. The metadata may still further be regarding a file name and/or file path.

The data section 90 is broken down into a series of bit sequences. There may be tens of bit sequences to billions of bit sequences in the data section. Each bit sequence is mapped to a symbol and the symbol is added to an index table. An image of the index table is stored in local memory.

Similarly, the metadata section 92 is broken down into a series of bit sequences. Each bit sequence is mapped to a symbol and the symbol is added to an index table. An image of the index table is stored in local memory. The image of the index table for the data section is linked to the index table for the metadata section such that the file can be accurately reconstructed.

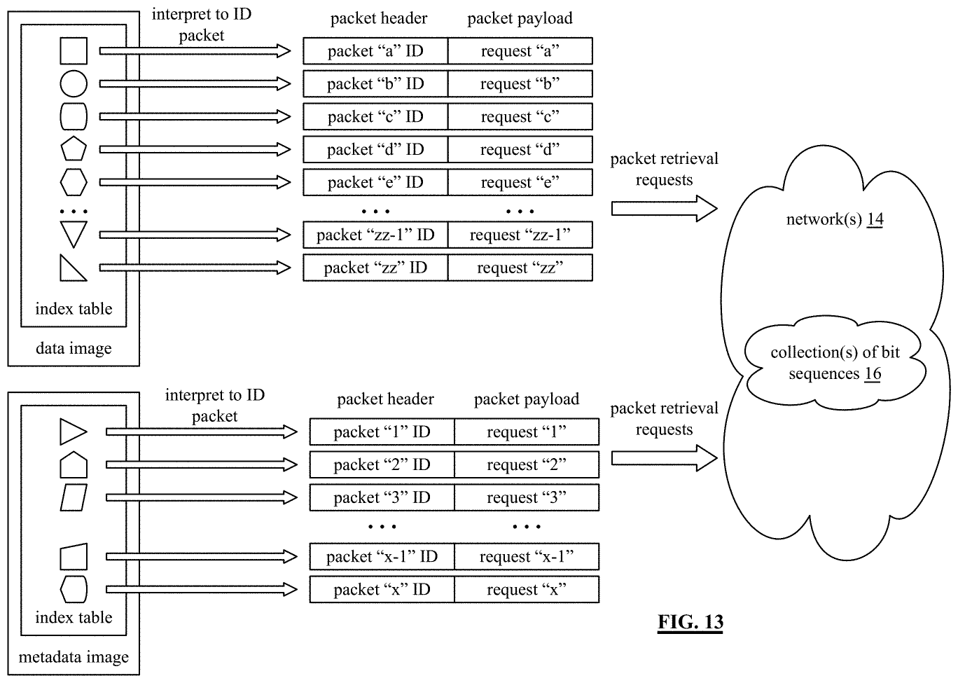

FIG. 13 is a schematic block diagram of an example of symbols of an index table being used to identify packets (or frames) that contain at least a portion of a bit sequence. To reconstruct a file, a computing entity retrieves an index table for the data section of the file and an index table for the metadata of the file. The symbols of each are interpreted to identify the appropriate packets (or frames).

As the packets are identified, the computing entity creates bit sequence requests, which includes a packet (or frame) header and a packet (or frame) payload. The packet header includes a packet ID that is based on a particular bit sequence. The payload section includes a request for a corresponding bit sequence or segment thereof. The bit sequence requests are sent to the network as packet retrieval requests.

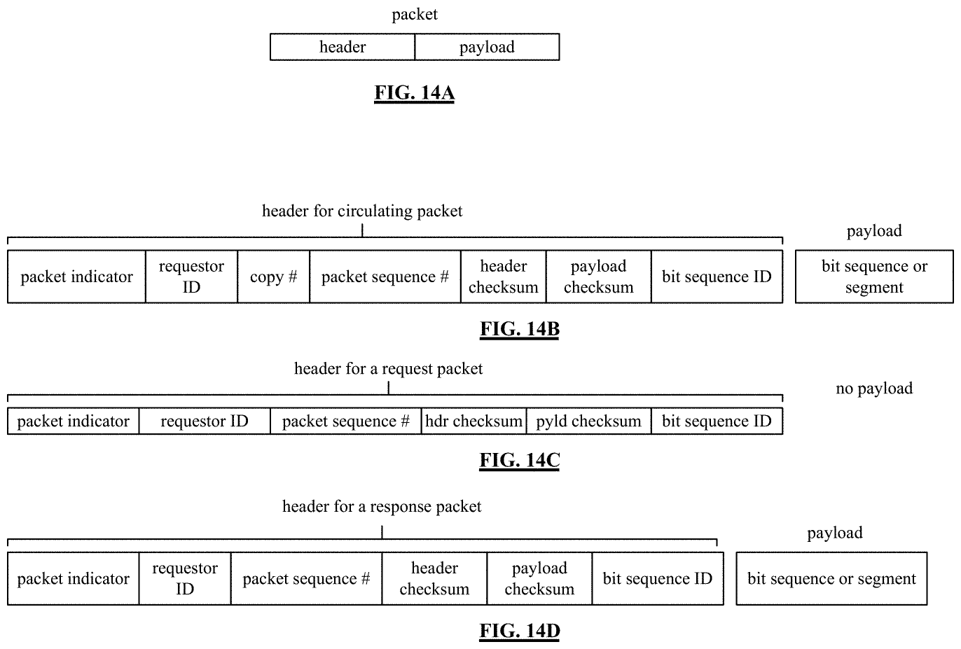

FIG. 14A is a schematic block diagram of an example of a packet or frame for use in a circulating bit-sequence-storage system. The packet (or frame) includes a header section and a payload. The header section includes information to identify a bit sequence, or segment thereof, and a copy number for the bit sequence, or segment thereof. The payload varies depending on whether the packet is for a bit sequence request, a bit sequence response, or circulating the packet (or frame) within the system.

The packet or frame may be used at the transport layer of the OSI and/or TCP/IP model; used as the network layer as packets in the OSI and/or TCP/IP model; and/or as a data link layer as frames in the OSI and/or TCP/IP model. The physical layer of the OSI model, which is at the bit level, may be implemented in a variety of ways using one or more wired and/or wireless communication protocols. Note that, unless specifically stated otherwise herein, packet and frame are used interchangeable keeping in mind the different layers they are used in.

FIG. 14B is a schematic block diagram of an example of a circulating packet for use in a circulating bit-sequence-storage system. The payload section includes the bit sequence or a segment thereof. The header for a circulating packet (i.e., one that infrastructure devices route through the network) includes a packet indicator field, a requestor ID field, a copy number field, a packet sequence number field, a header checksum, a payload checksum, and/or a bit sequence ID. Since this is a circulating packet, the requester ID field includes a default value to indicate no requestor.

The packet indicator field is a small field (e.g., 2-16 bits) to indicate the type of packet (circulating, request, response, non-circulating). When the packet indicator is set for a circulating packet (e.g., 00 for 2-bits), the packet is passed from infrastructure device to infrastructure device without a destination. As such, it continues to circulate through the network. If more than two bits are included in the packet indicator field, at least some of the remaining bits provide information regarding routing within the network and/or how long to hold the packet (or frame) before forwarding it.

The copy number field stores a value indicating the copy number of the bit sequence or segment thereof. In an embodiment, there will be hundreds or more copies of each bit sequence or segments thereof. The copies allow for each of fulfilling bit sequence requests and provide enhanced security for the system and users thereof.

The packet sequence number field includes a value indicating the sequence of the segment of the bit sequence contained in this packet (or frame). For example, if a bit sequence is divided into 6 segments, then a packet for each segment will be created. The packet for the first segment will have a packet sequence number of 1, the packet for the second segment will have a packet sequence number of 2, and so on. If the bit sequence is not segmented, then the packet sequence number field include a value of 0.

The header checksum, which is optional, includes a checksum value for the header section, less the header checksum. The checksum may be calculated in a variety of ways. For example, the checksum is calculated as a checksum function (e.g., parity byte or parity word, sum complement, position-dependent, fuzzy checksum, etc.). As another example, the checksum is calculated using a CRC (cyclic redundancy check). As yet another example, the checksum is calculated using a hash function such as a universal hash function, a non-cryptographic hash function, a keyed cryptographic hash function, an unkeyed cryptographic has function, or other deterministic function.

The payload checksum includes a checksum value for the payload section (i.e., the bit sequence or the segment thereof). The checksum may be calculated in using one or more of the techniques used to calculate the header checksum.

The bit sequence ID is a value that uniquely identifies a bit sequence. In an example, the bit sequence ID is an image of at least a portion of the bit sequence. In another example, the bit sequence ID is a mathematical representation of the bit sequence (e.g., compression, CRC, etc.).

FIG. 14C is a schematic block diagram of an example of a header of a request packet for a packet of a circulating bit-sequence-storage system. The header section includes the same fields: a packet indicator field, a requestor ID field, a copy number field, a packet sequence number field, a header checksum, a payload checksum, and/or a bit sequence ID.

In this example, the packet indicator field is set to request packet (e.g., 01 for two-bits) and the request ID includes the IP address of the requestor or some other network addressable identifier. The packet sequence field is set to a desired packet sequence number and the bit sequence ID field includes the identifier of the requested bit sequence. The header checksum is calculated, if included, based on the foregoing. The payload checksum is set to a default value in accordance with this a bit sequence request packet or is filled with a stored payload checksum for bit sequence or segment thereof being requested.

FIG. 14D is a schematic block diagram of an example of a header of a response packet for a packet of a circulating bit-sequence-storage system. The header section includes the same fields: a packet indicator field, a requestor ID field, a copy number field, a packet sequence number field, a header checksum, a payload checksum, and/or a bit sequence ID. The payload includes the requested bit sequence or the segment thereof.

In this example, the packet indicator field is set to response packet (e.g., 10 for two-bits) and the request ID includes the IP address of the requestor or some other network addressable identifier. The packet sequence field is set to match the desired packet sequence number of the request. The bit sequence ID field includes the identifier of the requested bit sequence. The payload checksum is calculated from the payload. The header checksum is calculated, if included, based on the foregoing.

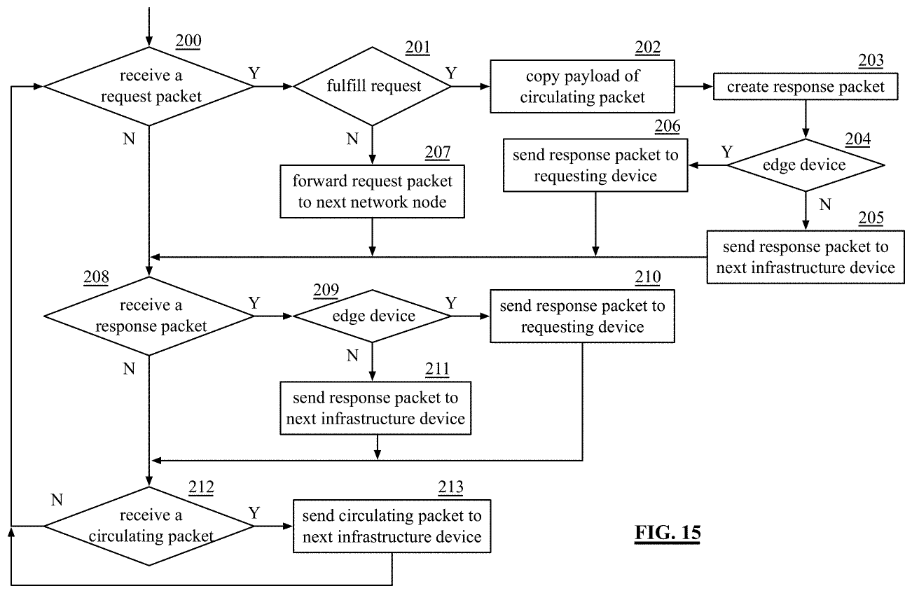

FIG. 15 is a logic diagram of an example of a method for an infrastructure device processing packets in a circulating bit-sequence-storage system. The method begins at step 200 where the infrastructure device determines whether it's receiving a bit sequence request packet. If yes, the method proceeds to step 201 where the infrastructure device determines whether it can fulfill the request. For example, does the infrastructure device currently possess the requested bit sequence or segment thereof. Note that, in a circulating-bit-sequence-storage system, an infrastructure device receives packets of bit sequences or segments thereof, temporarily stores them, and then forwards them to another infrastructure device.

If the infrastructure device cannot fulfill the request, the method continues at step 207 where the infrastructure device forwards the packet to another infrastructure device. If, at step 201, the infrastructure device can fulfill the request, the method continues at step 202 where the infrastructure device copies the payload of the appropriate circulating packet. The method continues at step 203 where the infrastructure device creates a response packet that includes the copied payload.

The method branches at step 204 depending on whether the infrastructure device is an edge device or a core device. If the infrastructure device is a core device, the method continues at step 205 where the infrastructure device sends the response packet to another infrastructure device of the network. If the infrastructure device is an edge device, the method continues at step 206 where the infrastructure device sends the response packet to the requesting device.

If, at step 200, the infrastructure device did not receive a request packet or after steps 205-207, the method continues at step 208 where the infrastructure device determines whether it's receiving a response packet. The method branches at step 209 depending on whether the infrastructure device is an edge device or a core device. If the infrastructure device is a core device, the method continues at step 211 where the infrastructure device sends the response packet to another infrastructure device of the network. If the infrastructure device is an edge device, the method continues at step 210 where the infrastructure device sends the response packet to the requesting device.

If, at step 208, the infrastructure device did not receive a response packet or after steps 210-211, the method continues at step 212 where the infrastructure device determines whether it's receiving a circulating packet. If yes, the method continues at step 213 where the infrastructure device sends the circulating packet to another infrastructure device of the network in accordance with a routing protocol to balance the load on the network with respect to the circulating packets. If the infrastructure device is not receiving a circulating packet or after step 213, the method repeats at step 200.

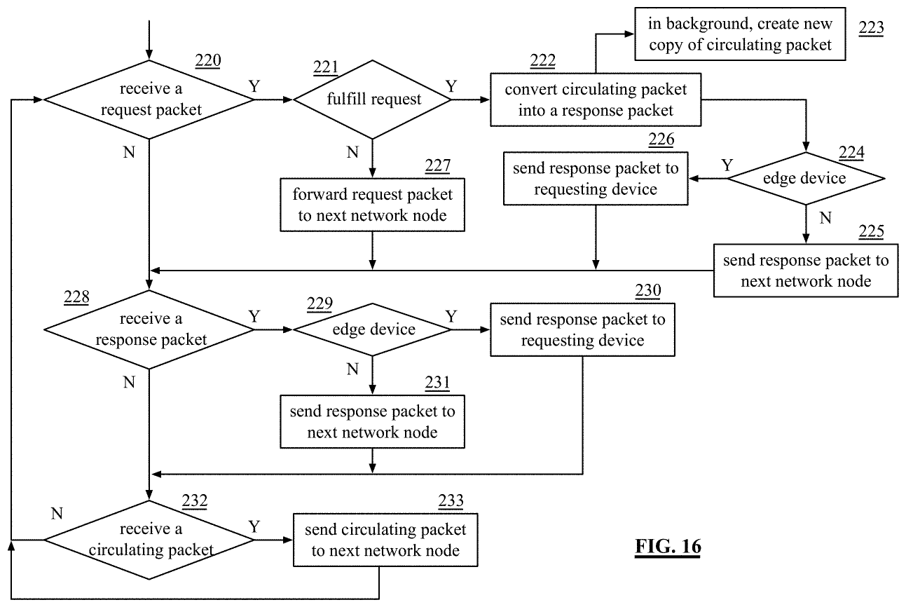

FIG. 16 is a logic diagram of another example of a method for an infrastructure device processing packets in a circulating bit-sequence-storage system. The method begins at step 220 where the infrastructure device determines whether it's receiving a bit sequence request packet. If yes, the method proceeds to step 221 where the infrastructure device determines whether it can fulfill the request. For example, does the infrastructure device currently possess the requested bit sequence or segment thereof. Note that, in a circulating-bit-sequence-storage system, an infrastructure device receives packets of bit sequences or segments thereof, temporarily stores them, and then forwards them to another infrastructure device.

If the infrastructure device cannot fulfill the request, the method continues at step 227 where the infrastructure device forwards the packet to another infrastructure device. If, at step 221, the infrastructure device can fulfill the request, the method continues at step 222 where the infrastructure device converts the circulating packet into a response packet. The method continues at steps 223 and 224. At step 223, the infrastructure device or another infrastructure device creates a new circulating copy of the packet.

The method branches at step 224 depending on whether the infrastructure device is an edge device or a core device. If the infrastructure device is a core device, the method continues at step 225 where the infrastructure device sends the response packet to another infrastructure device of the network. If the infrastructure device is an edge device, the method continues at step 226 where the infrastructure device sends the response packet to the requesting device.

If, at step 220, the infrastructure device did not receive a request packet or after steps 225-227, the method continues at step 228 where the infrastructure device determines whether it's receiving a response packet. The method branches at step 229 depending on whether the infrastructure device is an edge device or a core device. If the infrastructure device is a core device, the method continues at step 231 where the infrastructure device sends the response packet to another infrastructure device of the network. If the infrastructure device is an edge device, the method continues at step 230 where the infrastructure device sends the response packet to the requesting device.

If, at step 228, the infrastructure device did not receive a response packet or after steps 230-231, the method continues at step 232 where the infrastructure device determines whether it's receiving a circulating packet. If yes, the method continues at step 233 where the infrastructure device sends the circulating packet to another infrastructure device of the network in accordance with a routing protocol to balance the load on the network with respect to the circulating packets. If the infrastructure device is not receiving a circulating packet or after step 233, the method repeats at step 220.

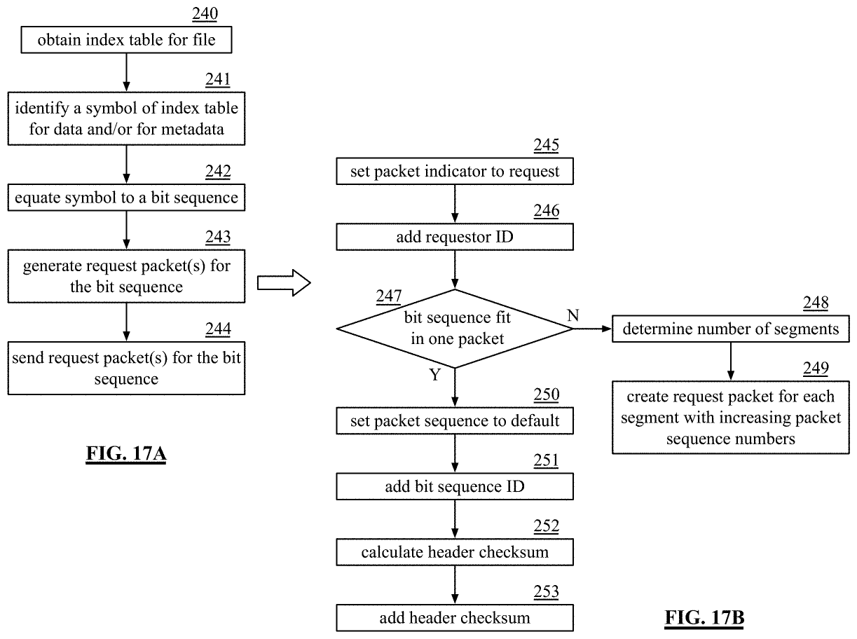

FIGS. 17A and 17B are a logic diagram of an example of a method for computing entity to retrieve in a file in a bit-sequence-storage system. The method of FIG. 17A begins at step 240 where the computing entity obtains an index table for a file. For example, the computing entity retrieves the index table from local memory and/or cloud memory of the computing entity.

The method continues at step 241 where the computing entity identifies a symbol from the index table regarding a data sector or a metadata section of the file. The computing entity may identify the symbol in a variety of ways. For example, the computing entity scans the index table to identify a symbol. As another example, the computing entity performs an image recognition function to identify the symbol. As another example, the computing entity comes a symbol of the index table with known symbols.

The method continues at step 242 where the computing entity equates the symbol to a bit sequence. This may be done in a variety of ways. For example, the computing entity performs a lookup function. As another example, the computing entity performs a deterministic function.

The method continues at step 243 where the computing entity creates a request packet or packets for the bit sequence. The method continues at step 244 where the computing entity sends the request packet(s) to the network(s).

The method of FIG. 17B is regarding the generation of a request packet and begins at step 245 where the computing entity sets the packet indicator field of the header to request. The method continues at step 246 where the computing entity adds its ID to the requestor ID field of the header.

The method continues at step 247 where the computing entity determines whether the bit sequence fits in a single packet. This can be done by a look up function, by knowledge of the size of bit sequences and the size of packet's payload, and/or by a deterministic function. If the bit sequence does fit into one packet payload, the method continues at step 250 where the computing entity sets the packet sequence number to a default value indicating that the entire bit sequence is contained in the packet's payload.

The method continues at step 251 where the computing entity adds the bit sequence ID to the header section of the packet. The method continues at step 252 where the computing entity generates a header checksum and, at step 253, adds the header checksum to the header of the packet.

If, at step 247, the bit sequence does not fit into a single packet payload, the method continues at step 248 where the computing entity determines a number of segments for the bit sequence based on the size of the bit sequence and the size of a packet's payload. The method continues at step 249 where the computing entity creates a request packet for each segment, each packet with an increasing packet sequence number. For each of the packets, the computing entity performs steps 251-253.

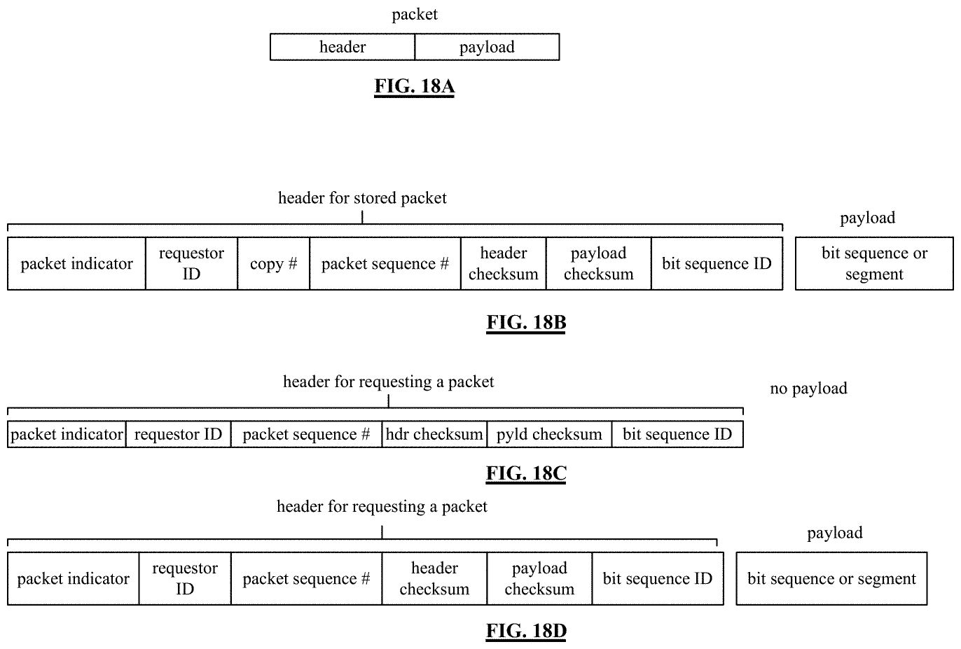

FIG. 18A is a schematic block diagram of an example of a packet or frame for use in a non-circulating bit-sequence-storage system. The packet (or frame) includes a header section and a payload. The header section includes information to identify a bit sequence, or segment thereof, and a copy number for the bit sequence, or segment thereof. The payload varies depending on whether the packet is for a bit sequence request, a bit sequence response, or non-circulating (i.e., stored) packet (or frame) within the system.

The packet or frame may be used at the transport layer of the OSI and/or TCP/IP model; used as the network layer as packets in the OSI and/or TCP/IP model; and/or as a data link layer as frames in the OSI and/or TCP/IP model. The physical layer of the OSI model, which is at the bit level, may be implemented in a variety of ways using one or more wired and/or wireless communication protocols. Note that, unless specifically stated otherwise herein, packet and frame are used interchangeable keeping in mind the different layers they are used in.

FIG. 18B is a schematic block diagram of an example of a non-circulating packet for use in a non-circulating bit-sequence-storage system. The payload section includes the bit sequence or a segment thereof. The header for a non-circulating packet (i.e., one that an infrastructure device stores) includes a packet indicator field, a requestor ID field, a copy number field, a packet sequence number field, a header checksum, a payload checksum, and/or a bit sequence ID. Since this is a non-circulating packet, the requester ID field includes a default value to indicate no requestor.

The packet indicator field is a small field (e.g., 2-16 bits) to indicate the type of packet (circulating, request, response, non-circulating). When the packet indicator is set for a non-circulating packet (e.g., 11 for 2-bits), the packet is stored by an infrastructure device.

The copy number field stores a value indicating the copy number of the bit sequence or segment thereof. In an embodiment, there will be hundreds or more copies of each bit sequence or segments thereof. The copies allow for each of fulfilling bit sequence requests and provide enhanced security for the system and users thereof.

The packet sequence number field includes a value indicating the sequence of the segment of the bit sequence contained in this packet (or frame). For example, if a bit sequence is divided into 6 segments, then a packet for each segment will be created. The packet for the first segment will have a packet sequence number of 1, the packet for the second segment will have a packet sequence number of 2, and so on. If the bit sequence is not segmented, then the packet sequence number field include a value of 0.

The header checksum, which is optional, includes a checksum value for the header section, less the header checksum. The checksum may be calculated in a variety of ways. For example, the checksum is calculated as a checksum function (e.g., parity byte or parity word, sum complement, position-dependent, fuzzy checksum, etc.). As another example, the checksum is calculated using a CRC (cyclic redundancy check). As yet another example, the checksum is calculated using a hash function such as a universal hash function, a non-cryptographic hash function, a keyed cryptographic hash function, an unkeyed cryptographic has function, or other deterministic function.

The payload checksum includes a checksum value for the payload section (i.e., the bit sequence or the segment thereof). The checksum may be calculated in using one or more of the techniques used to calculate the header checksum.

The bit sequence ID is a value that uniquely identifies a bit sequence. In an example, the bit sequence ID is an image of at least a portion of the bit sequence. In another example, the bit sequence ID is a mathematical representation of the bit sequence (e.g., compression, CRC, etc.).

FIG. 18C is a schematic block diagram of an example of a header of a request packet for a packet of a non-circulating bit-sequence-storage system. The header section includes the same fields: a packet indicator field, a requestor ID field, a copy number field, a packet sequence number field, a header checksum, a payload checksum, and/or a bit sequence ID.

In this example, the packet indicator field is set to request packet (e.g., 01 for two-bits) and the request ID includes the IP address of the requestor or some other network addressable identifier. The packet sequence field is set to a desired packet sequence number and the bit sequence ID field includes the identifier of the requested bit sequence. The header checksum is calculated, if included, based on the foregoing. The payload checksum is set to a default value in accordance with this a bit sequence request packet or is filled with a stored payload checksum for bit sequence or segment thereof being requested.

FIG. 18D is a schematic block diagram of an example of a header of a response packet for a packet of a circulating bit-sequence-storage system. The header section includes the same fields: a packet indicator field, a requestor ID field, a copy number field, a packet sequence number field, a header checksum, a payload checksum, and/or a bit sequence ID. The payload includes the requested bit sequence or the segment thereof.

In this example, the packet indicator field is set to response packet (e.g., 10 for two-bits) and the request ID includes the IP address of the requestor or some other network addressable identifier. The packet sequence field is set to match the desired packet sequence number of the request. The bit sequence ID field includes the identifier of the requested bit sequence. The payload checksum is calculated from the payload. The header checksum is calculated, if included, based on the foregoing.

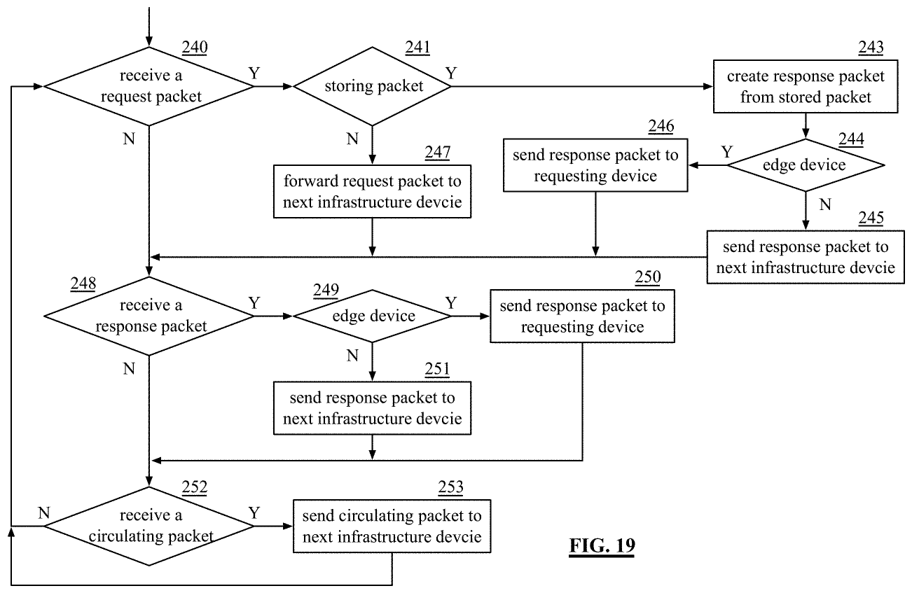

FIG. 19 is a logic diagram of an example of a method for an infrastructure device processing packets in a non-circulating bit-sequence-storage system. The method begins at step 240 where the infrastructure device determines whether it's receiving a bit sequence request packet. If yes, the method proceeds to step 221 where the infrastructure device determines whether it is storing the request bit sequence or segment thereof.

If the infrastructure device is not storing the bit sequence or segment thereof, the method continues at step 247 where the infrastructure device forwards the packet to another infrastructure device. If, at step 241, the infrastructure device is storing the bit sequence or segment thereof, the method continues at step 243 where the infrastructure device creates a response packet that includes a copy of the bit sequence or segment thereof.

The method branches at step 244 depending on whether the infrastructure device is an edge device or a core device. If the infrastructure device is a core device, the method continues at step 245 where the infrastructure device sends the response packet to another infrastructure device of the network. If the infrastructure device is an edge device, the method continues at step 246 where the infrastructure device sends the response packet to the requesting device.

If, at step 240, the infrastructure device did not receive a request packet or after steps 245-247, the method continues at step 248 where the infrastructure device determines whether it's receiving a response packet. The method branches at step 249 depending on whether the infrastructure device is an edge device or a core device. If the infrastructure device is a core device, the method continues at step 251 where the infrastructure device sends the response packet to another infrastructure device of the network. If the infrastructure device is an edge device, the method continues at step 250 where the infrastructure device sends the response packet to the requesting device.

If, at step 248, the infrastructure device did not receive a response packet or after steps 250-251, the method continues at step 252 where the infrastructure device determines whether it's receiving a circulating packet. If yes, the method continues at step 253 where the infrastructure device sends the circulating packet to another infrastructure device of the network in accordance with a routing protocol to balance the load on the network with respect to the circulating packets. If the infrastructure device is not receiving a circulating packet or after step 253, the method repeats at step 240.

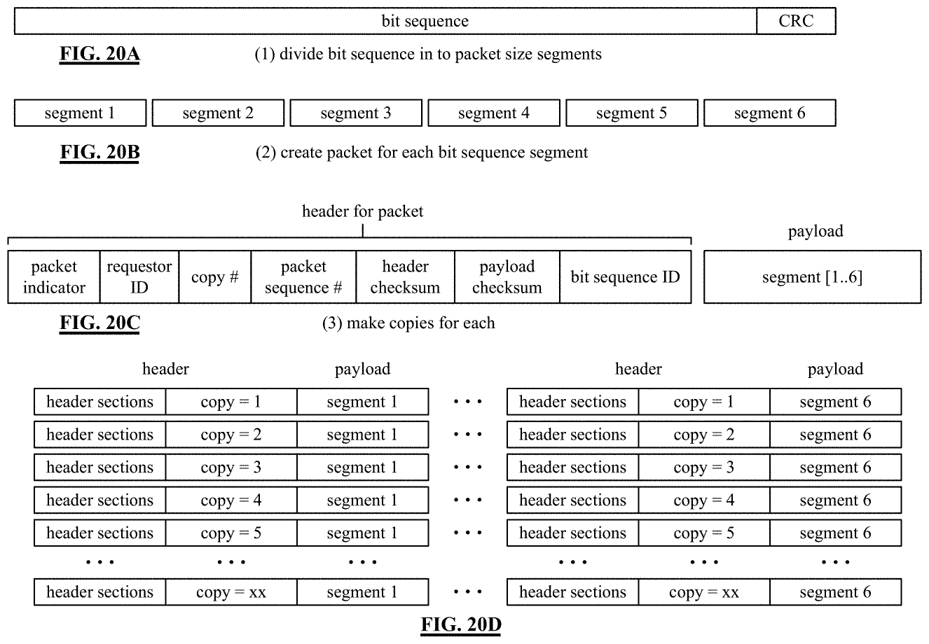

FIG. 20A is a schematic block diagram of an example of a bit sequence and corresponding cyclic redundancy check (CRC) value or other data integrity function. In this example a bit sequence with its CRC value appended thereto. As such, the CRC value is part of the overall bit sequence.

FIG. 20B is a schematic block diagram of an example of dividing the bit sequence of FIG. 20A into a plurality of bit sequence segments. In this example, the bit sequence (including the CRC) is divided into six segments (e.g., segments 1-6).

FIG. 20C is a schematic block diagram of an example of a packet format for a segment. The packet includes a header section and a payload. The payload includes one of the segments (e.g., 1-6). The header includes the packet indicator field, the copy number field, the packet sequence number field, the header checksum field, the payload checksum field, and the bit sequence ID. The fields of a header were previously discussed with reference to FIGS. 14A-14D and 18A-18D.

FIG. 20D is a schematic block diagram of an example of copies of the packets of segments of the bit sequence. In this example, a plurality of copies (e.g., xx, which is any integer greater than 2) is generated for each segment. The packets for each copy are identical but for the copy number field. This field includes a unique number correspond to which copy of the segment is included in the packet.

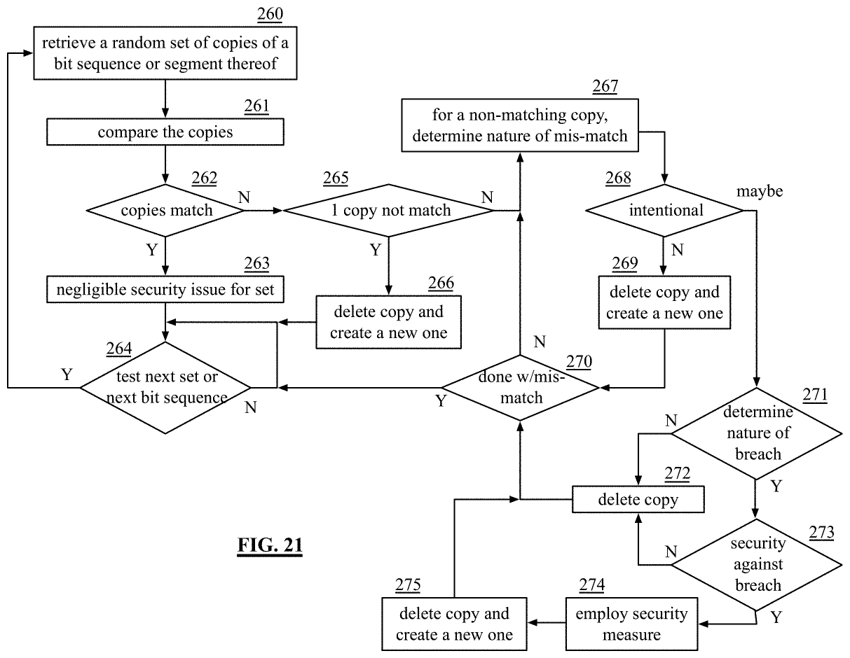

FIG. 21 is a logic diagram of an example of a method for an infrastructure device and/or a computing entity (hereinafter for this figure called a “device”) detecting corruption of a packet in a bit-sequence-storage system. The method begins at step 260 where the device retrieves a random set of copies of a bit sequence or a segment thereof. For example, the device retrieves 10's to 100's of copies of the bit sequence or a segment. As another example, the device retrieves 1% to 50% of the copies of a bit sequence or a segment.

The device randomly determines the copy numbers of the copies to retrieve using a modulo pseudo random number generation process. For example, if there are 1,000 copies, then there are 1,000 pseudo random numbers that the modulo pseudo random number generation process can produce. If the number of copies to analyze is 100, then the modulo pseudo random number generation processing will produce 100 random numbers in the range of 1 to 1,000.

The method continues at step 261 where the device compares the copies with each other at the bit level. For example, copy 1 includes the bit sequence segment of 0011 1010 0010 1110 1101 and copy 2 includes the bit sequence segment of 0011 1010 0010 1110 1101. In this example, the device compares the bits sequence segments and the header sections less the copy number field to determine if they match. In this example, they do. As another example, copy 2 includes the bit sequence of “1”011 1010 0010 1110 1101. The first bit is included in quotes to emphasize that it does not match the first bits of copies 1 and 2. Thus, in this example, copy 3 does not match copies 1 and 2.

The method continues at step 262 where the device determines if the copies match. If yes, the method continues at step 263 where the device determines that there is negligible security issues with the copies analyzed thus far. Note that a significant concern for any storage system is data corruption whether through equipment failure or through malicious acts. With this method, if a copy of a bit sequence or segment is altered, it will be detected and can be dealt with accordingly (e.g., deleted, corrected, increased security measures, etc.).

The method continues at step 264 where the device determines whether to test another set of copies of a bit sequence or a segment. If so, the method repeats at step 260. If not, the method is paused until the device tests another set. Note the device may periodically (e.g., once every minute, hour, etc.) test a set of copies), it may be prompted by a system administrator, or it may continually test copies (i.e., as soon as done testing one set, start testing another).

If at step 262, one or more copies do not match, the method continues at step 265 where the device determines whether there is only one copy that does not match. If so, the method continues at step 266 where the device deletes the non-matching copy and creates a new matching copy. Since only one copy was not matching, it can be relatively safe to assume that the data corruption of the copy was due to equipment failure and not a malicious act. Hence, deleting the non-matching copy and creating a new one. The method then continues at step 264.

If, at step 265, more than 1 copy did not match, the method continues at step 267 where the device attempts to determine the nature of the cause for the mismatch of each non-matching copy. For example, the device determines how many copies are mismatching. If the number of mismatching copies exceeds a threshold, there is a likelihood of malicious acts. As another example, the device determines the number of bits in each copy that are mismatching and the bit location of each mismatching bit. The device then analyzes the mismatches to determine if there is a pattern or commonality to the mismatches. If there is no discernable pattern or commonality of mismatches, then it is likely the mismatches are due to equipment failure. As another example, the device may employ one or more security algorithms and/or protocols to detect a malicious act.

The method continues at step 268 where the device determines whether the mismatch of a copy was likely intentional. If not, the method continues at step 269 where the device deletes the mismatching copy and creates a new matching copy. The method continues at step 270 where the device determines whether there are more mismatching copies to address. If yes, the method continues at step 267. If not, the method continues at step 264.

If it is possible that the mismatching copy was intentionally corrupted, the method continues at step 271 where the device determines the nature of the breach. For example, the device attempts to determine the source of the malicious act (e.g., an inside user, a hacker, a bot, etc.). If the nature of the breach cannot be determined, the method continues at step 272 where the mismatching copy is deleted, and a new copy is not created.

If the nature of the breach can be determined, the method continues at step 273 where the device determines whether there are available security measures to prevent future breaches of a like nature. If not, the method continues at step 272. If yes, the method continues at step 274 where the device employs the security measure. The method continues at step 275 where the device deletes the mismatching copy and creates a new copy.

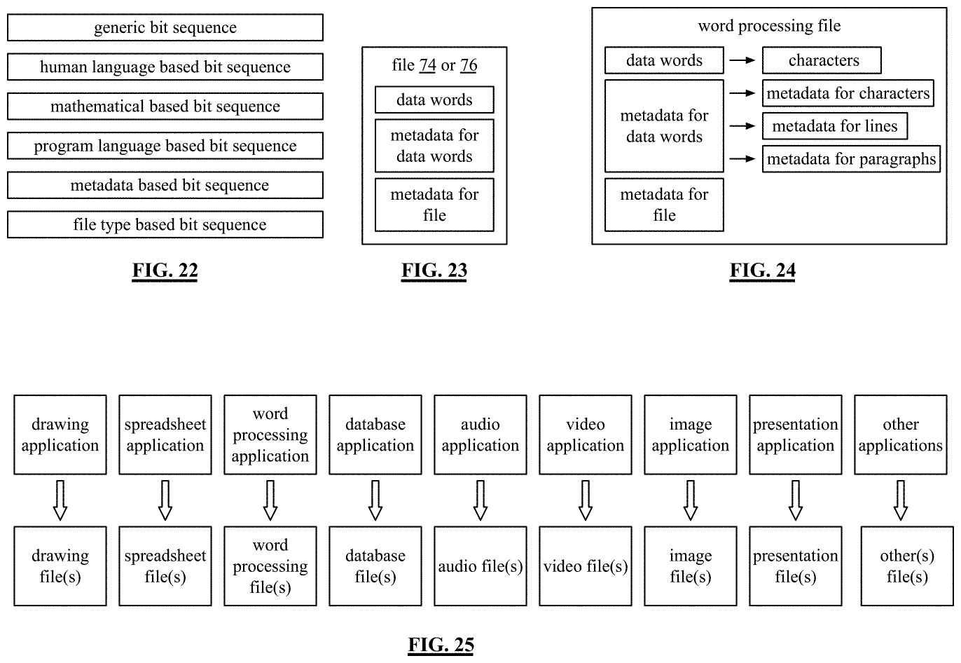

FIG. 22 is a schematic block diagram of an example of various categorizations for organizing bit sequences. As mentioned, a collection of bit sequences includes bit sequences that are used in files (e.g., data files, application files, operating systems, drivers, software programs, etc.). In this example, there are a plurality of collections of bits; each collection directed towards a particular type of file, sections of a file, or other type of categorization.

The first collection of bit sequences is generic, meaning it is usable for all types of files (i.e., no one type of file is favored over another). The second collection of bit sequences is human language based bit sequences. In this collection, the bit sequences correspond to human language by language (e.g., English, Chinese, German, etc.). For instance, phrases converted to binary form one or more bit streams. This collection may be more suitable for data files such as word processing documents, spreadsheets, etc.

A third collection of bit sequences is mathematical based. In this collection, results of mathematical equations with input sets form bit sequences. In addition, mathematical equations form other bit sequences. This collection may be suitable for use with audio and/or video recording and/or playback application files and/or with audio files and/or with video files.

A fourth collection of bit sequences is programming language based. In this collection, operational instruction sets form bit sequences. In addition, sub-routines form other bit sequences. This collection may be more suitable for use with applications and/or software programs.

A fifth collection of bit sequences is metadata based. In this collection, the commonalities of metadata form the bit sequences.

A sixth collection of bit sequences is file type based. For example, common bit patterns of a word processing application and corresponding documents form a collection of bit sequences. As another example, common bit patterns of a database application and resulting database documents form another collection of bit sequences. Note that other categorizations of bit sequences may be created. Further note that a file may draw from one or more collection of bit sequences.

FIG. 23 is a schematic block diagram of an example of partitioning a file 74 and/or 76 into data words, metadata for the data words, and meta data for the file. The data words of the file correspond to the meaningful data of the file (e.g., the words and punctuation of a word processing document). The metadata for the data words corresponds to how the characters of the data words are to appear in the meaningful data. The metadata of the file includes information regarding margins, paragraph formatting, and/or file system storage information.

FIG. 24 is a schematic block diagram of an example of partitioning a word processing file into data words, metadata for the data words, and metadata for the file. In this example, the data words are the characters and punctuation of the document. The metadata for the data words includes metadata for the characters (e.g., size, font, underlining, etc.), metadata for the lines (e.g., line numbering, word spacing, etc.), and metadata for paragraphs (line spacing, right justified, etc.).

FIG. 25 is a schematic block diagram of an example of various applications and the data files created therefrom, each may use one or more bit sequence categories. In this example, which is not an exhaustive list of applications, or the data files created therefrom, a drawing application produces drawing files; each of which may use the collection of generic bit and/or the collection of file type based bit sequences.

A spreadsheet application produces spreadsheet files, a database application produces database files, and a word processing application produces word processing files. Such applications and files may use the collection of generic bit, the collection of language based bit sequences, and/or the collection of file type based bit sequences.

An audio record/playback application processes audio files, a video record/playback application processes video files, and an image record/playback application processes image files. Such applications and files may use the collection of generic bit, the collection of mathematical based bit sequences, and/or the collection of file type based bit sequences.

Note that the application files may also use the collection of programming language based bit sequences. Also note that other applications can use one or more of the collection of bit sequences and the resulting files of another application can use one or more of the collection of bit sequences.

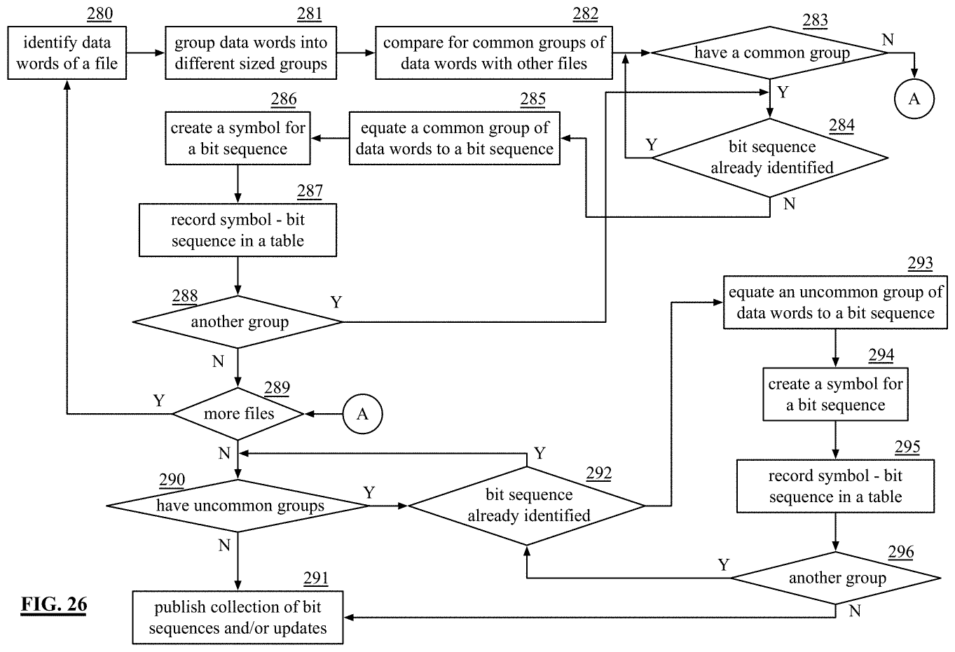

FIG. 26 is a logic diagram of an example of a method for an infrastructure device and/or a computing entity (hereinafter for this figure called a “device”) to identify bit sequences in files. The method begins at step 280 where the device identifies data words of a data file. A data word may be 1 byte to 128 bytes in size and/or may corresponds to data word size of applications, microprocessors, memory devices, and/or mechanism for establishing a data word size.

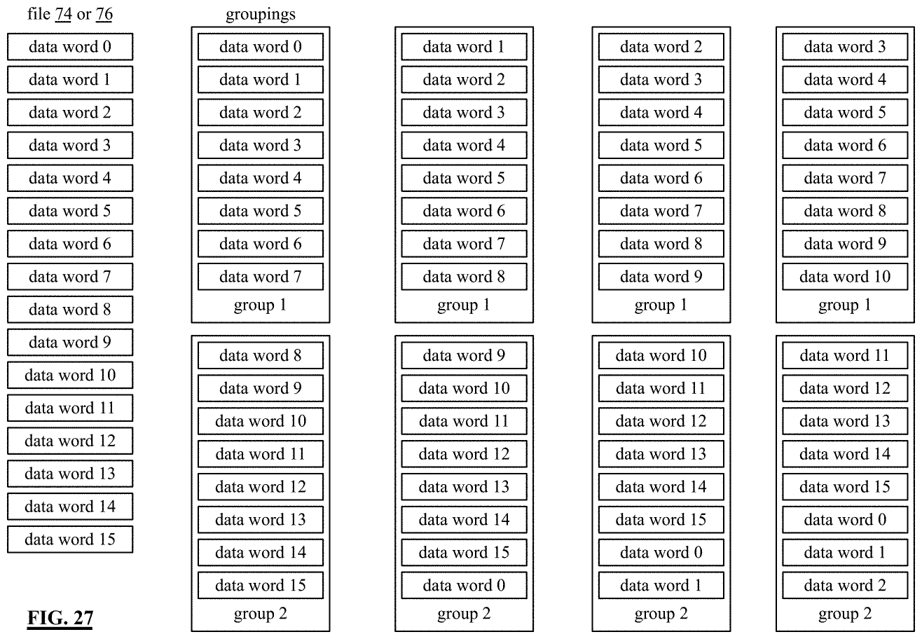

The method continues at step 281 where the device groups data words into different sized groups. Various examples of grouping data words are discussed with reference to FIGS. 27-29B. Note that the examples of FIGS. 27-29B have a small number of data words and groupings thereof in a file for illustrative purposes; in practice there would likely tens to thousands, or more, of grouping of data words.

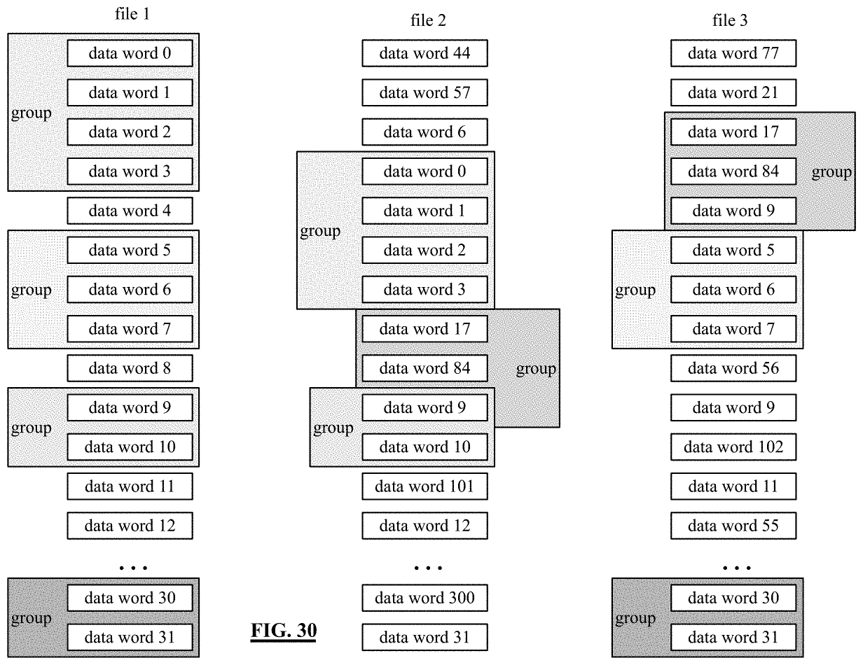

The method continues at step 282 where the device compares grouping of files and/or groupings within files for commonality (e.g., the same data words in the group, the same ordering of data words in the group, and/or a certain percentage of data words in common between the groups). An example is provided with reference to FIG. 30. The method continues at step 283 where the device determines whether there are any common groups.

If yes, the method continues at step 284 where the device determines whether a bit sequence already exists for the identified group. If yes, the method repeats at step 283. If not, the method continues at step 285 where the device equates a common group of data words to a bit sequence (e.g., string the data words together to form a bit sequence). The method continues at step 286 where the device creates a symbol for the bit sequence. The method continues at step 287 where the device records the assignment of a symbol to the bit sequence in a collection of bit sequences.

The method continues at step 288 where the device determines whether there is another group to process. If yes, the method repeats at step 283. If not, the method continues at step 289 where the device determines whether there are more files to analyze. If yes, the method repeats at step 280.

If not, the method continues at step 290 where the device determines whether there are uncommon groups (i.e., a group of data words from one file but does not appear in any other file that has been analyzed). If not, the method continues at step 291 where the device publishes a collection of bit sequences or updates to it.

If there are uncommon groups at step 290, the method continues to step 292 where the device determines whether a bit sequence already exists for an uncommon group. If yes, the method continues at step 290.

If not, the method continues at step 293 where the device equates an uncommon group of data words to a bit sequence. The method continues at step 294 where the device creates a symbol for the bit sequence. The method continues at step 295 where the device records the assignment of the symbol to the bit sequence in a collection of bit sequences. The method continues at step 296 where the device determines whether there is another uncommon group to process. If yes, the method continues at step 292. If not, the method continues at step 291.

FIG. 27 is a schematic block diagram of an example of grouping data words of a file for analysis per the method of FIG. 26. In this example, the file includes 16 data words (0-15). For a first pass of grouping, the file is grouped into 8 data words per group in a rolling manner. As shown, from group to group, there is some commonality and some differences. Note that the entire file could be one group. Further note that, in practice, the number of data words in a group would be in the range of dozens to thousands.

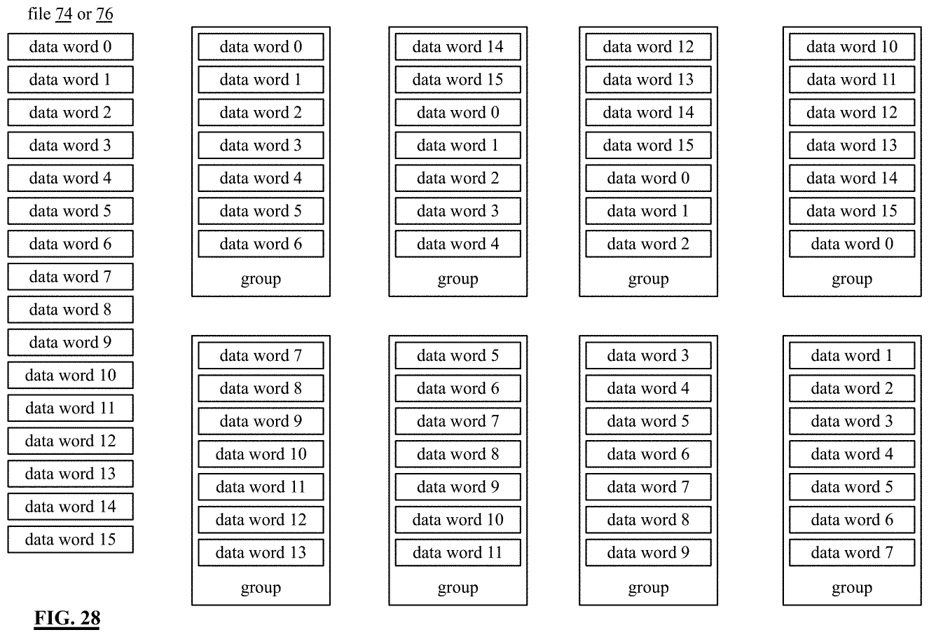

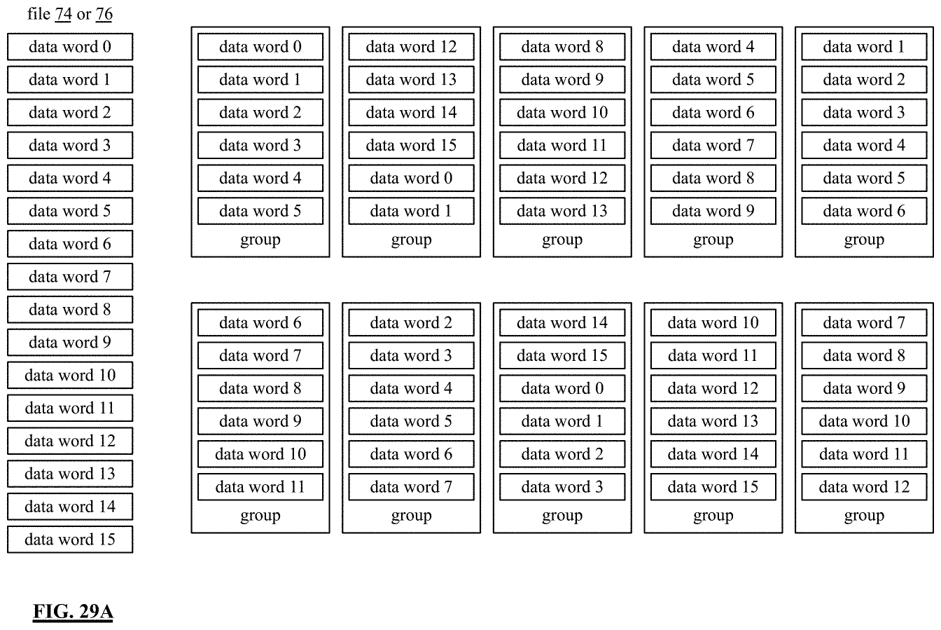

FIG. 28 is a schematic block diagram of another example of grouping data words of a file for analysis per the method of FIG. 26. In this example, the 16 data words of the file are arranged into groups of 7 data words per group. Each group having a different combination of 7 data words.

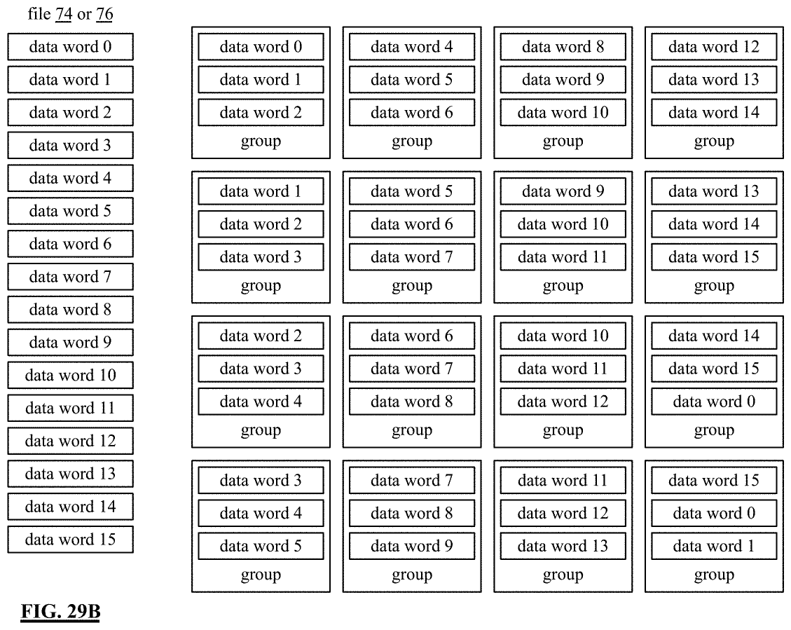

FIG. 29A is a schematic block diagram of another example of grouping data words of a file for analysis per the method of FIG. 26. In this example, the 16 data words of the file are arranged into groups of 6 data words per group. Each group having a different combination of 6 data words.

FIG. 29B is a schematic block diagram of another example of grouping data words of a file for analysis per the method of FIG. 26. In this example, the 16 data words of the file are arranged into groups of 3 data words per group. Each group having a different combination of 3 data words.

FIG. 30 is a schematic block diagram of another example of corresponding grouping data words of various files. In this example, three files have been analyzed for common groupings of data words. Color is used to highlight the particular groups of common sets of data words between the files. Data words not in a color group are in uncommon groups (i.e., only used in a particular grouping in one file).

As shown, data words 0-3 form a group (pink) of data words, which is common to file 1 and file 2. The group of data words may be converted into a bit sequence; for which a symbol would be created. Data words 5-7 are in a common group (yellow) between files 1 and 3. Data words 9 and 10 are in a common group (light blue) to files 1 and 2. Data words 30 and 31 are in a common group (darker blue) to files 1 and 3. Data words 17, 84, and 9 are in a common group (purple) to files 2 and 3. Note that data word 9 is included in two common groupings (light blue and purple) of data words.

Uncommon data word groupings include data words 11 and 12 of file 1; data words 44, 57, and 6 of file 2; data words 101, 12, . . . 300, and 31; data words 77 and 21 of file 3, and data words 56, 9, 102, 11, and 55 of file 3. If these are the only files analyzes, then bit sequences would be created from the common groups and from the uncommon groups. Each bit sequence would have a unique symbol created for it.

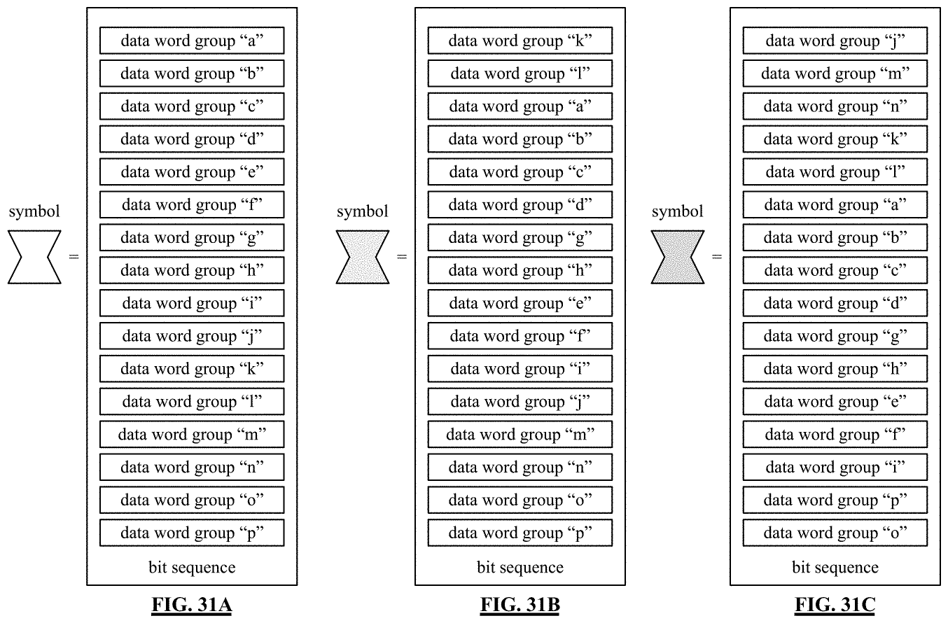

FIG. 31A is a schematic block diagram of a bit sequence including a plurality of data word groups, the bit sequence is represented by a symbol. The symbol is a black and white shape. Note that the symbol could be any type of symbol that is black and white. The symbol represents a bit sequence that includes a plurality of data word groups in a particular order (e.g., a through p). Note that a data word group includes one or more data words, and a data word is 1 byte to 128 kilobytes, or more, in size.

FIG. 31B is a schematic block diagram of an example of the data word groups of FIG. 31A with a different ordering to form a different bit sequence. The symbol is of the same shape as the symbol for the bit sequence of FIG. 31A but has a fill color of light blue. The light blue color indicates a different ordering of the data words of FIG. 31A to produce a different bit sequence.

FIG. 31C is a schematic block diagram of another example of the data word groups of FIGS. 31A and 31B with a different ordering to form a different bit sequence. The symbol is of the same shape as the symbol for the bit sequence of FIGS. 31A and 31B but has a different color (purple). The purple color indicates another different ordering of the data words of FIG. 31A to produce another different bit sequence.

For the example FIG. 31A-31C, the symbol shape is associated with a group of data word and the color indicates the ordering of the data words to produce different bit sequences. If true color is used, which includes 24 bits, there are 2²⁴ unique orderings of the same data word groups. Note that not every combination of data word group ordering needs to be represented, just the ones that are used in files.

In an embodiment, the bit sequence represented by the black & white symbol is circulating or stored in the network. The index table includes the symbol shape and color but communicates with the network using the black and white symbol. Thus, until the color is added by the index table, the bit sequence has no meaning (with the exception that the index table includes the black & white symbol). Note that each computing entity can use its own color scheme to represent data word ordering. As such, even if a bad actor obtained a computing entities index table, without the color order scheme, the index table has little value regarding the file it represents.

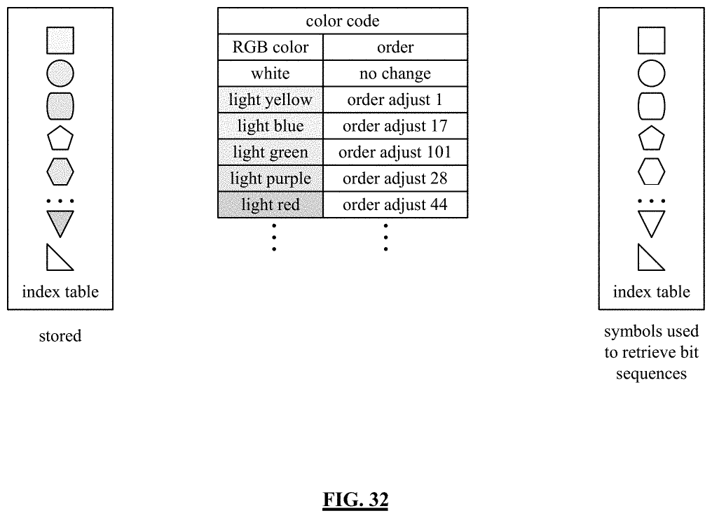

FIG. 32 is a schematic block diagram of an example of a stored index table have colored symbols and a color code table. The index table stored by the computing entity includes a plurality of colored symbols. The color represents a different ordering of a group of data words to produce different bit sequences. The particular ordering of the data words is based on color as indicated in the color code table.

The table lists the colors (as an RGB bit code, an image of the color, or other descriptor) and a corresponding ordering. As shown, the color white has no change to the ordering. The light yellow has order adjust 1 change to the ordering. For example, order adjust 1 indicates that data word groups 3 and 7 are to switch positions in the order of the bit sequence represented by the white symbol. The other colors represent different ordering changes. Note that each computing entity may have its own color code table or include multiple color code tables to add further security to its data files.

When the computing entity communicates with the network regarding the index table, it does so using only the white symbols (or other default colored symbols). In this manner, the white symbolled index table has no real meaning without the color. As such, the transmission of white symbolled index tables provides no meaningful information regarding the files they represent.

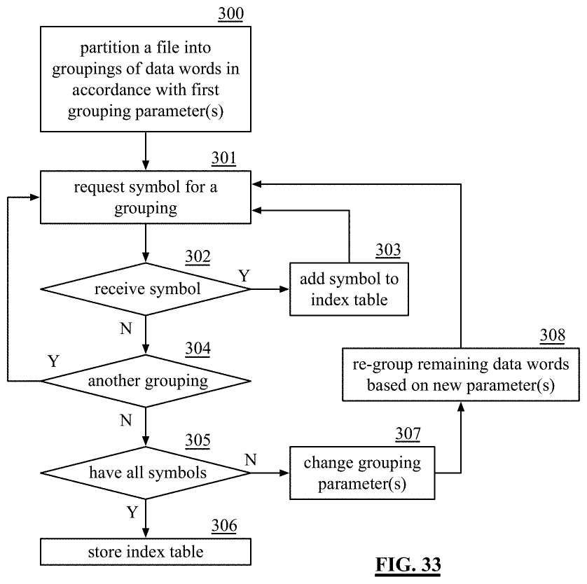

FIG. 33 is a logic diagram of an example of a method for a computing entity to convert a file into bit sequences and create an index table therefrom. The method begins at step 300 where the computing entity partitions a file into groups of data words in accordance with a first grouping parameter (e.g., a number of data words to include in a group, which ranges from a few data words to thousands of data words). The partitioning may be done in accordance with a logical partitioning of the file. For example, a word processing document is partitioned by paragraphs, pages, section, etc. As another example, a software application is partition based on sub-routines, instruction descriptors, etc.

The computing entity may normalize a file into a normalized data word format. For example, if a file uses 4-byte data words and the bit sequences are based on 8-byte data words, the computing entity converts the 4-byte data words into 8-byte data words (e.g., concatenates them).

The method continues at step 301 where the computing entity requests a symbol for a group of data words. This may be done in a variety of ways. For example, the computing entity performs a deterministic function (e.g., a hash, CRC, checksum, etc.) on the group of data words to produce reference value. The computing entity then accesses a local copy, or remote copy, of reference value table to determine if the reference value is included in the table. The table includes the reference value field and a symbol field.

If the reference value is in the table, the computing entity obtains the symbol and uses it to request the bit sequence associated with the symbol. Upon receiving the bit sequence, the computing entity compares it to the grouping of data words. If the comparison reveals that the data word groups of the bit sequence are the same as the grouping of data words, then the computing entity has the correct symbol for the grouping of data words. Note that the computing entity may need to add color to the symbol to adjust the ordering of the data word groups of the bit sequence.

As another example of requesting the symbol, the computing entity sends the grouping of data words (e.g., as bits, as an image, etc.) to the network and requests a symbol therefor. Alternatively, the computing entity performs a deterministic function on the grouping of data words to produce a reference value and sends the reference value to the network requesting a corresponding symbol. If the network has a corresponding symbol to the reference value or to the grouping of data words, it sends the symbol to the computing entity.

The method continues at step 302 where the computing entity determines whether it received a symbol for the current grouping of the data words. If yes, the method continues at step 303 where the computing entity adds the symbol to the index table its building for the file. If not, the method continues at step 304 where the computing entity determines whether it has another grouping of data words having the current grouping parameter to process. If yes, the method continues at step 301.

If there are no more groupings with the current grouping parameters to process, the method continues at step 305 where the computing entity determines whether it has all of the symbols for the file. If yes, the method continues at step 306 where the computing entity stores the index table.

If not, the method continues at step 307 where the computing entity changes the grouping parameter. The method continues at step 308 where the computing entity re-groups remaining data words based on the new grouping parameter. The method then continues at step 301.

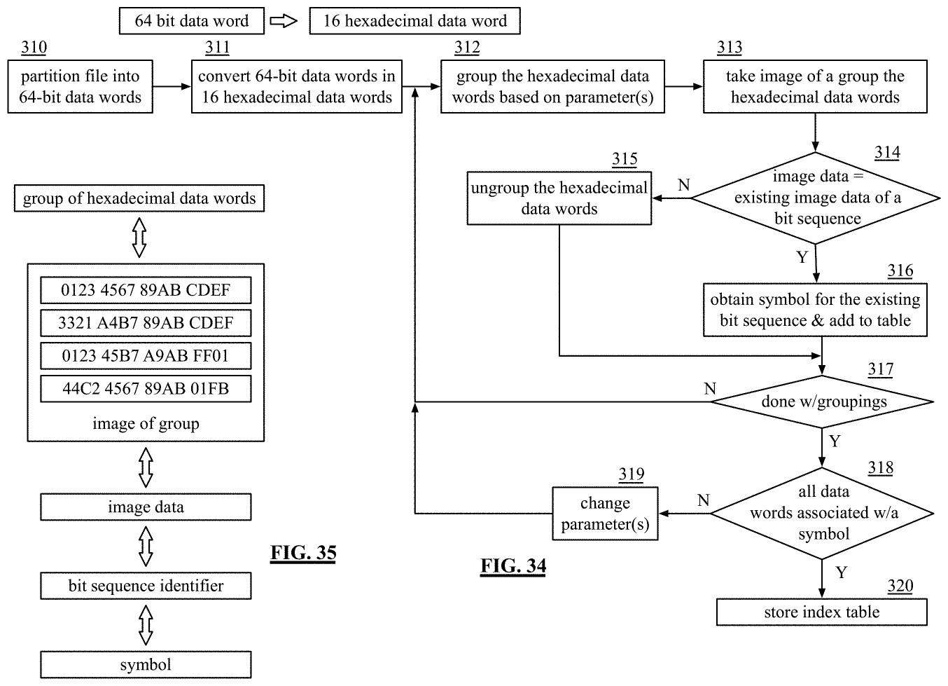

FIG. 34 is a logic diagram of another example of a method for a computing entity to convert a file into bit sequences and create an index table therefrom. The method begins at step 310 where the computing entity partitions a file into 64-bit data words. The method continues at step 311 where the computing entity converts the 64-bit data words into 16 hexadecimal value data words.

The method continues at step 312 where the computing entity groups the 16 hexadecimal value data words based on a grouping parameter, or parameters. The method continues at step 313 where the computing entity takes an image of a group of data words to produce a plurality of images for a plurality of groups of data words.

The method continues at step 314 where the computing entity and/or an infrastructure device determines whether the image data (e.g., the image and/or its digital representation in binary values) of the grouping of data words is the same as an existing image of a bit sequence, or portion thereof. If yes, the method continues at step 316 where the computing entity obtains a symbol for the existing bit sequence and adds it to an index table. If not, the method continues at step 315 where the computing entity ungroups the hexadecimal data words.

In either case, the method continues at step 317 where the computing entity determines when it's done with analyzing groupings of data words using the current grouping parameter(s). If not, the method continues at step 312. If yes, the method continues at step 318 where the computing entity determines whether all data words are associated with a symbol. If yes, the method continues at step 320 where the computing entity stores the index table. If not, the method continues at step 319 where the computing entity changes one or more of the grouping parameters. The method then continues at step 312 for remaining ungrouped data words.

FIG. 35 is a schematic block diagram of an example of identifying a symbol for a group of hexadecimal words corresponding to the method of FIG. 34. As shown, an image is taken of a group of hexadecimal data words to produce image data (e.g., the image and/or the digital representation thereof). The image data is used to determine a bit sequence identifier (e.g., an image of the bit sequence, a digital representation of the image, etc.) if a bit sequence exists. if a bit sequence identifier exists, it is used to determine a corresponding symbol for the bit sequence.

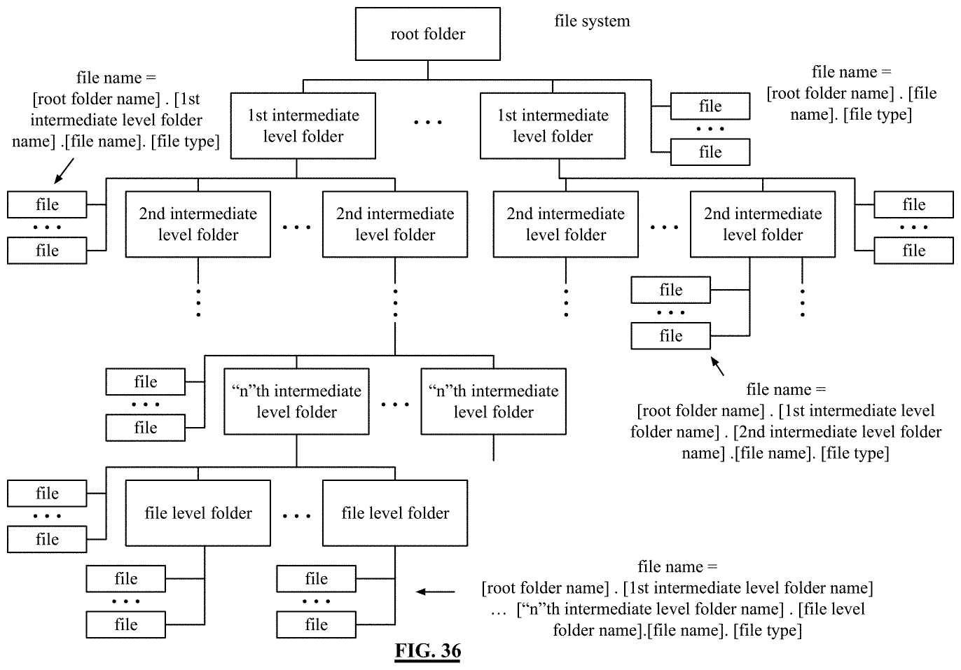

FIG. 36 is a schematic block diagram of an example of a file system for use by a computing entity for files associated with circulating and/or non-circulating bit sequence systems. The file system includes a root folder, a plurality of intermediate levels of folders, a plurality of file level folders, and a plurality of files. The intermediate levels of folders include one or more levels. In this example, there are n levels.

At each level of folders, files may be stored. For example, at the root level files stored therein would have a file system name of [root folder name].[file name].[file type]. As another example, a file stored in a folder of the first intermediate level would have a system file name of [root folder name].[1^{st} intermediate folder name]. [file name]. [file type]. As yet another example, a file stored in a folder of the second intermediate level would have a system file name of [root folder name].[1^{st} intermediate folder name]. [2^{nd} intermediate folder name].[file name].[file type]. As a further example, a file stored in the a file level folder would have a system file name of [root folder name]. [1^{st} intermediate folder name] . . . [n-th intermediate folder name]. [file folder name]. [file name]. [file type].

In an embodiment, the file system is stored as a separate file comprising a series of bit sequences. In another embodiment, the file system name for a file is included in the metadata of the file.

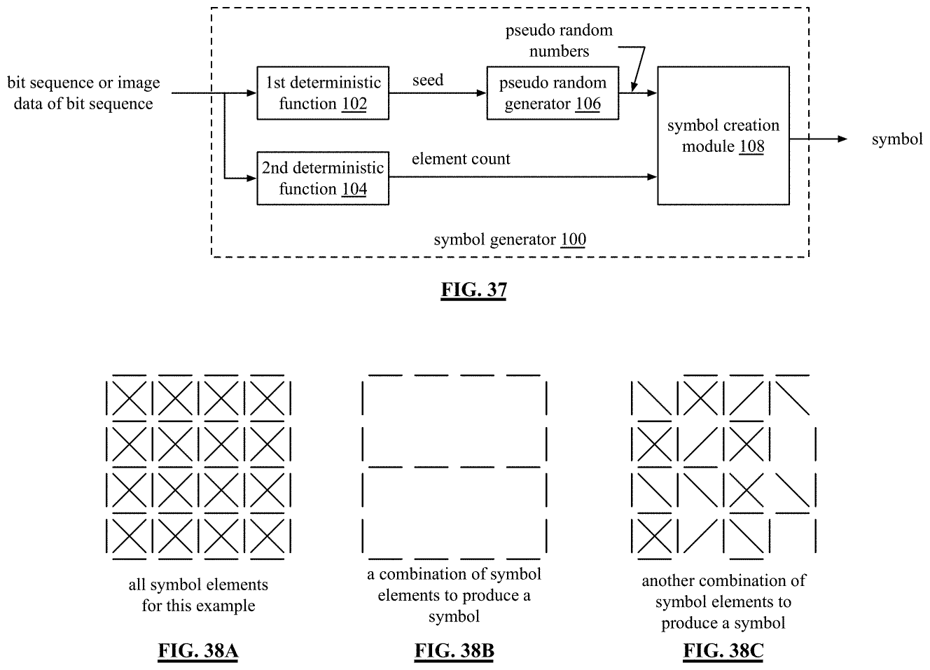

FIG. 37 is a schematic block diagram of an example of an embodiment of a symbol generator 100 that includes a first deterministic function module 102, a second deterministic function module 104, a pseudo random generator 106, and a symbol creating module 108. The deterministic function modules 102 and 104 may be implemented in a variety of ways. For example, the deterministic function is a hash function. As another example, the deterministic function is a CRC. As yet another example, the deterministic function is a checksum function. As a further another example, the deterministic function is encryption. Note that the first and second deterministic function modules may implement the same deterministic function or different ones. Further note that one or more of the first and second deterministic function modules may be replaced with a different module that performs a different mathematic function.

The first deterministic function module performs a deterministic function on the bit sequence and//or image data of an image of the bit sequence to produce a seed value. The pseudo random generator uses the seed value as an input to generate a set of pseudo random numbers. Note that the pseudo random generator may be implemented in a conventional manner.

The second deterministic function module performs a deterministic function on the bit sequence and//or image data of an image of the bit sequence to produce an element count value. The element count value corresponds to the number of symbol elements the symbol creation module uses to produce a symbol based on the set of pseudo random numbers.

The symbol creation module receives the element count and the pseudo random numbers. The pseudo random numbers correspond to symbol element positions of a plurality of symbol elements used to create symbols. The element count corresponds to the number of elements to include in a symbol.

FIGS. 38A-38C provide examples of a plurality of symbol elements and corresponding symbols produced by the symbol generator. FIG. 38A is a schematic block diagram of an example of a plurality of symbol elements available to the symbol creation module of the symbol generator. In this example, the plurality of symbol elements includes a total of 72 symbol elements, 20 vertical elements, 20 horizontal elements, and 32 diagonal elements. This provides 2⁷² options (4.7×10²¹) with binary representation of the symbol elements.

For this example, the pseudo random numbers range from 1-72 and the seed indicates a starting value for the set of pseudo random numbers and how the pseudo random number generator generates the remaining numbers in the set. The element count for this example ranges from 0-72.

As an example of mapping element numbers to the pattern of FIG. 38A, the horizontal elements are numbered first from top left to bottom right so they are numbered 1-20. The vertical elements are numbered next from top left to bottom right and include numbers 21-40. The diagonal elements are number last from top left to bottom right and includes numbers 41-72.

FIG. 38B is a schematic block diagram of an example of another symbol created by a symbol generator. In this example, the element count is 20 and the set of pseudo random numbers includes 1, 2, 3, 4, 9, 10, 11, 12, 17, 18, 19, 20, 21, 22, 23, 24, 37, 38, 39, and 40.

FIG. 38C is a schematic block diagram of an example of another symbol created by a symbol generator. In this example, the element count is 48 and the set of pseudo random numbers includes 2, 3, 4, 5, 7, 9, 10, 13, 14, 15, 16, 17, 19, 21, 22, 23, 24, 25, 26, 27, 28, 29, 30, 31, 32, 33, 34, 36, 38, 39, 40, 41, 43, 44, 45, 48, 49, 50, 51, 53, 54, 58, 60, 61, 62, 64, 65, 66, 68, and 69. Note that non-angled lines (zero or ninety degrees) in a symbol requires less data to represent in an image than a symbol that includes angled lines.

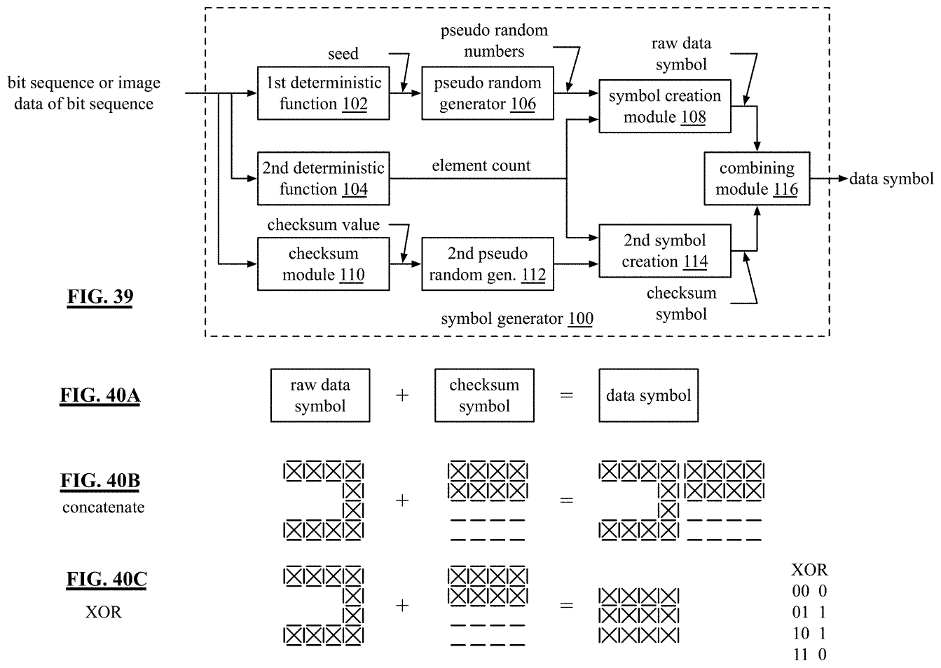

FIG. 39 is a schematic block diagram of another example of an embodiment of a symbol generator 100 that includes a first deterministic function module 102, a second deterministic function module 104, a pseudo random generator 106, a symbol creating module 108, a checksum module 110, a second pseudo random generator 112, and a second symbol creation module 114, and a combining module 116. The checksum modules may be implemented in a variety of ways. For example, the checksum module is configured to perform a CRC function on the bit sequence and/or image data of the bit sequence. The first deterministic function module, the second deterministic function module, the pseudo random generator, and the symbol creating module operate as previously discussed to produce a raw data symbol.

The checksum module generates a checksum value from the bit sequence and/or image data of the bit sequence. The second pseudo random generator generates a set of pseudo random numbers using the checksum value as the seed. The second symbol creation module creates a checksum symbol based on the second set of pseudo random numbers and the element count. The combining module combines the raw data symbol and the checksum symbol to produce the data symbol. In this manner, a checksum of the bit sequence is embedded into the symbol making it more difficult for a bad actor to alter a bit sequence and/or the symbol representing the bit sequence.

FIG. 40A is a schematic block diagram of an example of the combining module combining the raw data symbol with the checksum data symbol to produce the final data symbol. The combining can be done in a variety of ways. For example, FIG. 40B illustrates the checksum symbol being concatenated to the raw data symbol to produce the final data symbol.

As another example, FIG. 40C illustrates the checksum symbol being XORed with the raw data symbol to produce the final data symbol. Other ways of combining the raw data symbol with the checksum symbol include interlacing the symbols and alternating symbol elements of the symbols.

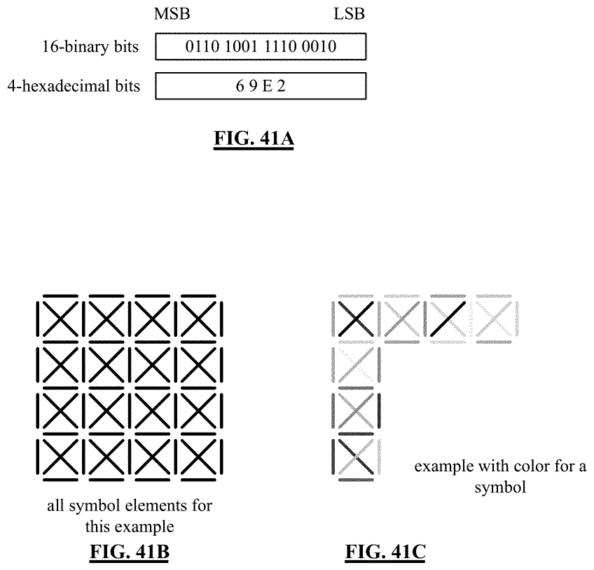

FIG. 41A is a schematic block diagram of an example of a 16-bit data word and it's corresponding 4-hexadecimal data word. The most significant bit (MSB) of the data word can be used by a symbol creation module to indicate the presence or absence of a symbol element in a resulting symbol. The remaining bits can be used to indicate color. As such, one symbol element has 2¹⁶ options (65,536). With 72 symbol elements as shown in FIG. 41B, there are 65,536⁷² options for symbols.

FIG. 41C is a schematic block diagram of an example of another symbol created by a symbol generator. In this example, the element count is 20 and the set of pseudo random numbers includes 1, 2, 3, 4, 5, 6, 7, 8, 21, 22, 23, 24, 25, 26, 27, 31, 32, 36, 37, 41, 42, 43, 44, 45, 46, 47, 48, 49, 50, 57, 58, 65, and 66. Each symbol element is shown to have a different color, which adds to the number of symbols that can be created.

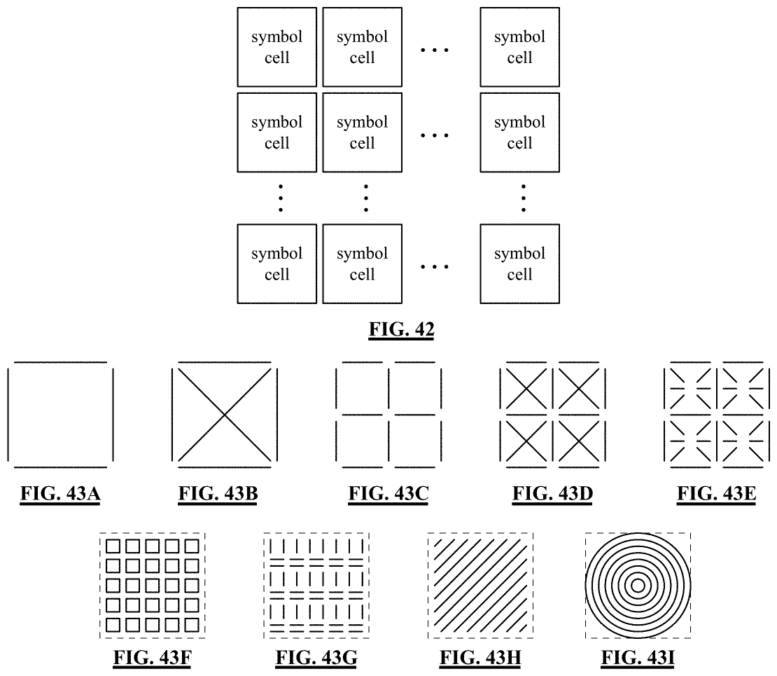

FIG. 42 is a schematic block diagram of an example of a symbol cell array of a symbol creation module. The symbol cell array includes one or more symbol cells. Each symbol cell includes a plurality of symbol elements. The arrangement of symbol elements of a symbol cell may be the same for each symbol cell or different. FIGS. 43A through 43I illustrates a few examples of symbol element arranges for symbol cells. Note that there is an almost endless number of symbol element shapes and arrangements for symbol cells.

The symbol creation module receives the set of pseudo random numbers and the element count and selects one or more of the symbol cells to produce the symbol. For example, the symbol creation module interprets the element count to determine how many symbol cells to use. For a low element count (e.g., less than 25, or some other number), the symbol creation module would select one cell. In addition, the symbol creation module selects which type of symbol cell pattern to use. For example, for an element count of 10, the symbol creating module may chose the pattern of one of FIG. 43C, 43D, or 43H.

Once the number of symbol cells is determined and the pattern for each is selected, the symbol creation module uses the set of pseudo random numbers and the element count to create a symbol. The symbol creation module assigns symbol element numbers to the symbol elements of the symbol cells to which the pseudo random numbers are mapped.

FIG. 43A is a schematic block diagram of an example of a symbol cell having 4 symbol elements in the pattern shown.

FIG. 43B is a schematic block diagram of an example of another symbol cell having 8 symbol elements in the pattern shown.

FIG. 43C is a schematic block diagram of an example of another symbol cell having 12 symbol elements in the pattern shown.

FIG. 43D is a schematic block diagram of an example of another symbol cell having 20 symbol elements in the pattern shown.

FIG. 43E is a schematic block diagram of an example of another symbol cell having 36 symbol elements in the pattern shown.

FIG. 43F is a schematic block diagram of an example of another symbol cell having 25 symbol elements in the pattern shown.

FIG. 43G is a schematic block diagram of an example of another symbol cell having 54 symbol elements in the pattern shown.

FIG. 43H is a schematic block diagram of an example of another symbol cell having 14 symbol elements in the pattern shown.

FIG. 43I is a schematic block diagram of an example of another symbol cell having 7 symbol elements in the pattern shown.

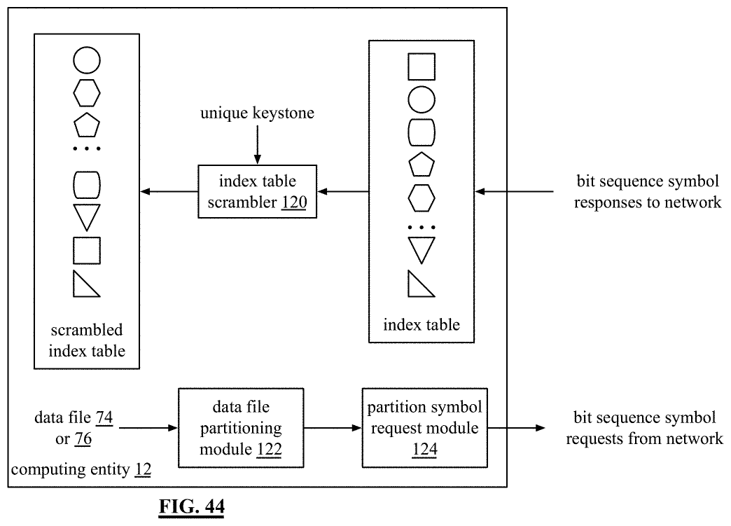

FIG. 44 is a schematic block diagram of an example of a computing entity 12 that includes an index table scrambler 120, a data file partitioning module 122, and a partition symbol request module 124. The data file partitioning module and the partition symbol request module perform one or more of the methods of FIGS. 33 and 34 to convert a data file into an index table.

The resulting index table includes an ordered arrangement of symbols. The index table scrambler scrambles the symbols of the index table to produce a scrambled index table. The index table scramble scrambles the index table in accordance with a unique keystone. The unique keystone may be created in a variety of ways. For example, if the index table represents an application file, then the unique keystone would be provided by the manufacturer of distributor of the application file. In this instance, the unique keystone would include a serial number of the application file, a username, a user password, a file key, and/or other pieces of data. As another example, the index table represents a data file of a user. In this instance the computing entity would create the unique keystone with or without input from a registered user of the computing entity.

The unique keystone may be represented by a symbol. In this instance, a user would display an image of the unique keystone on one device (e.g., a cell phone) so that image recognition programming of the computing entity can interpret the symbol. In an embodiment, the computing entity converts the image of the keystone into a bit pattern that is used by the index table scrambler.

The resulting scrambled index table is store in memory (local and/or cloud) of the computing entity. The index table is deleted once the scrambled index table has been successfully stored. This enhances security of the file that is represented by the index table.

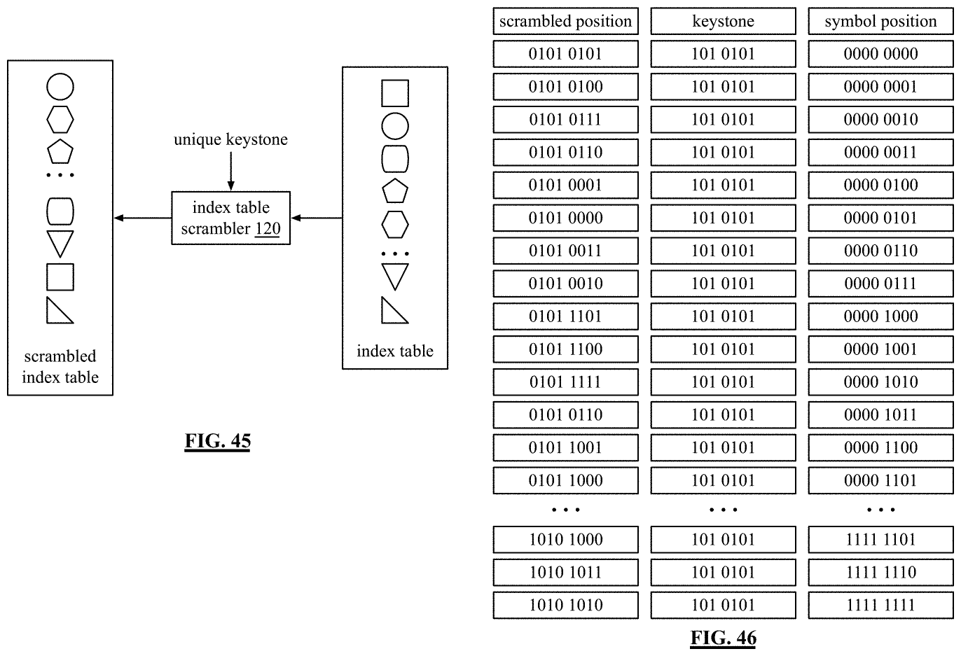

FIG. 45 is a schematic block diagram of another example of an index scrambler 120 scrambling an index table into a scrambled index table. In this embodiment, the scrambling is done using a CRC function, a Bose-Chaudhuri-Hocquenghem (BCH) coding, and/or Reed-Solomon coding. Note that other encoding schemes may be used by the index table scrambler.

In an embodiment, an XOR encoding scheme is used where the unique keystone is exclusively ORed with a symbol position as shown in FIG. 46. In this instance, a list of scrambled index positions is produced based on the XORing of the symbol position with the keystone. Once the scrambled positions have been determined, the computing entity reorders the symbols of the index table accordingly.

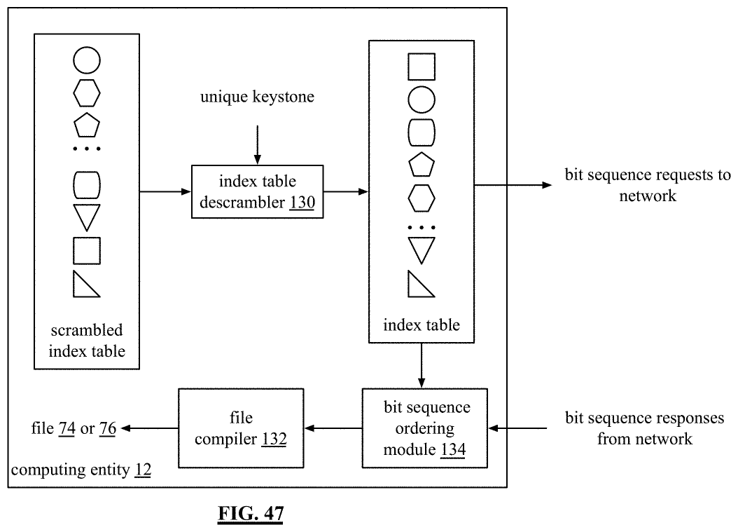

FIG. 47 is a schematic block diagram of another example of a computing entity 12 that includes an index descrambler 130, a bit sequence ordering module 134, and a file compiler 132. To retrieve a file, the computing entity engages the index table descrambler to convert, in accordance with the unique keystone, the scrambled index table into an index table. The index table descrambler performs the inverse function of the index table scrambler.

The computing entity uses the index table to retrieve bit sequences for each symbol in the table. The bit sequence ordering module orders the bit sequences received in accordance with the index table. The file compiler converts the ordered bit sequences into the requested file 74 or 76.

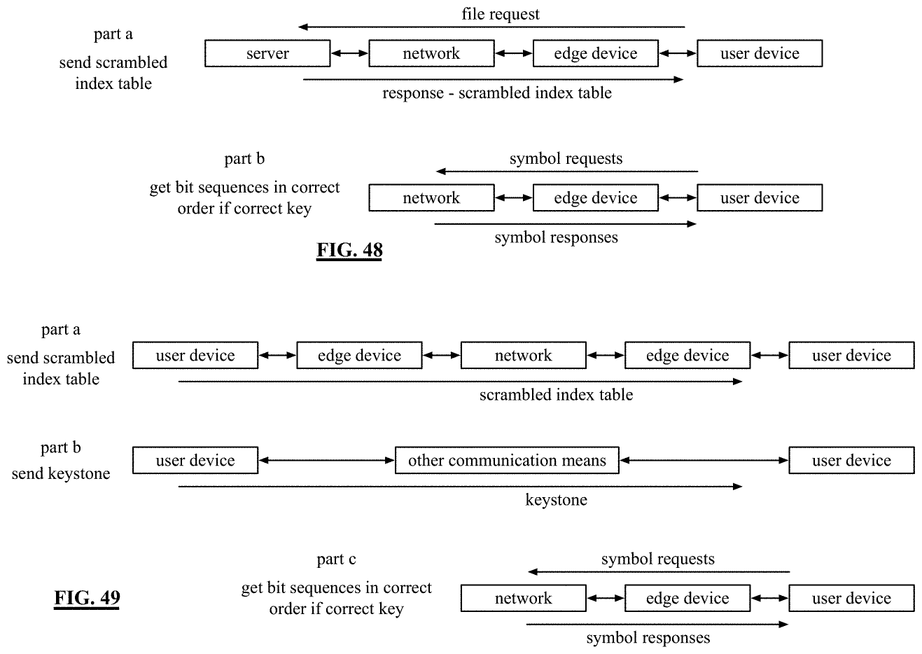

FIG. 48 is a schematic block diagram of an example of on-demand access to files using a scrambled index table. On demand access includes video on demand, downloading software updates, downloading applications, streaming audio, etc. To access an on-demand file, a user device (e.g., a computing entity) sends a file request to a server via an edge device and/or other devices of the network.

In response to the request, the server identifies the file, accesses the corresponding index table, creates (or retrieves) a unique keystone for the requestor (if the request and the requestor are authenticated), and creates a scrambled version of the index table in accordance with the unique keystone. The server sends the scrambled index table to the user device via the network and/or an edge device. If the user device is not already in possession of the unique keystone, the server sends it to the user of the user device via another communication path (e.g., via a text, via an email, etc.).

When the user device is prompted to access the file, the user device descrambles the scrambled index table in accordance with the unique keystone to produce the index table. The user device sends symbol requests to the network and/or edge device. The network responds to the symbol request with a bit sequence. The user device compiles the file from the bit sequence. If the unique keystone was the correct keystone, then the file will have been accurately compiled.

As an example, a 2-hour UHD movie is about 1.7 Gigabytes in size. This requires a data rate of (1.7 G*8)/(120*60), which is 1.87 Mbps. With a 64 to 1 data size to symbol size, a 2-hour UHD movies can be stored as an index table that is about 26 Megabytes in size and requires a data rate of 29 Kbps to download.

FIG. 49 is a schematic block diagram of an example of data communication using a scrambled index table. In this example, a first user device (e.g., computing entity) desires to send a file to a second user device (e.g., another computing entity) via one or more networks. Accordingly, the first user device creates a scrambled index table and sends to an edge device, which routes the scrambled index table to an edge device affiliated with the second user device.

Using a different communication means (e.g., cell phone call, a text, an email, a written document sent through conventional mail, etc.), the first user device sends the keystone for the scrambled index table to the second user device. The second user device descrambles the scrambled index table in accordance with the keystone to recover the index table.

Using the index table, the second user device retrieves bit sequences in the form of symbol responses. The second user device reconstructs the file based on the retrieved bit sequences. In this manner files can be communicated between computing entities in a secure manner and with substantially less data being transmitted from one computing entity to another (e.g., 4× to 64× or more).

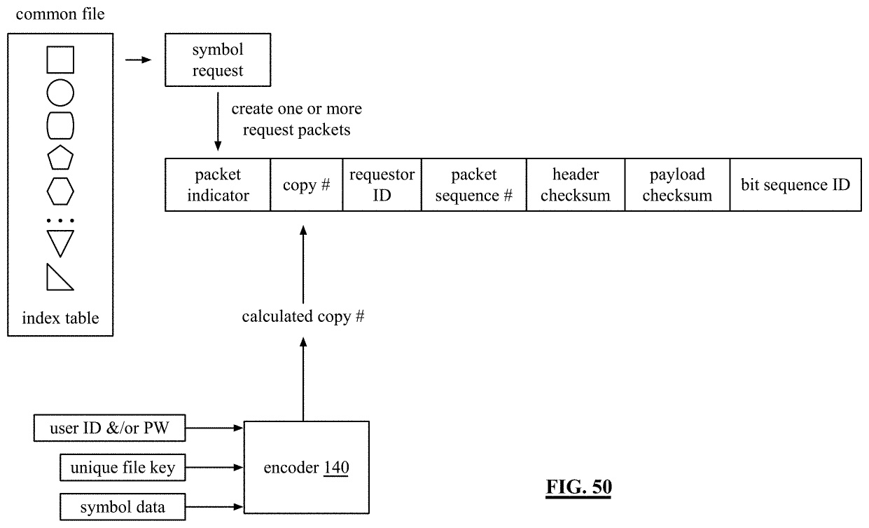

FIG. 50 is a schematic block diagram of an example of secure bit sequence retrieval based on unique file key. In a circulating or non-circulating bit sequence storage system, security of index tables, security of bit sequences, and authorized access of bit sequences are notable factors in reliable use of such systems. Security issues come in the form of fake accounts, intentional data corruption, breach of data secrecy, account takeover, copyright law violations, and/or other forms.

To ensure a user device (e.g., a computing entity affiliated with a user ID) is authorized to use an index table to retrieve a file, the user device is required to obtain a unique file key from an entity providing access to the file. The unique file key is an alphanumeric code that is unique to the specific user device (via the user ID or other identification process) and the file. Thus, only this computing entity can use the unique file key and retrieve a meaningful copy of the file (i.e., the correct bit sequences in the correct order to reconstruct the file).

An encoder 140 receives the unique file key and symbol data (e.g., the image data of the symbol, a numerical representation of the symbol, etc.). The encoder 140 may also receive a user ID and/or a user password (PW). The encoder may be implemented in a variety of ways. For example, the encoder is a modulo pseudo random number generator (e.g., generates a random number within a set of numbers) where the input(s) provide the seed. As another example, the encoding is an encryption module and modulo module. The encryption module encrypts the symbol data based on the unique file key to produce encryption data. The modulo module converts the encryption data into a modulo value that is within a range of numbers that corresponds to the number of copies of the bit sequence and/or of the segments thereof).

The encoder 140 generates an individual copy number for the symbol requests. For example, an individual copy number is calculated for each symbol request (note that the individual calculations of copy numbers for some symbol requests may yield the same copy number. As another example, an individual copy number is calculated for a symbol request and then is used for one or more other symbol requests.

The calculated copy number is used in the bit sequence request packet(s) of the symbol request. If the symbol corresponds to a bit sequence that is divided into a plurality of segments, then a plurality of request packets is generated; one for each segment. The copy number for such a plurality of request packets could the same or different. If different, the encoder creates the other copy numbers for the copy number it created based on the symbol data.

The resulting request packet includes the packet indication field, which is set to indicate that the packet is a request packet; the copy number field, which is set to the calculated copy value produced by the encoder; and the remaining fields of the packet as set as previously discussed. By creating a unique sequence of copy numbers using a unique file key for a set of symbol request provides a unique copy of a file to the requesting device. This helps with copyright law compliance, reducing unauthorized access to files, reducing intentional acts to corrupt data, and/or in reducing breaches of data secrecy.

With the use of the encoder, the same index table of a file can be provided to a plurality of user devices along with a plurality of unique file keys. Thus, even though a device may obtain a copy of the index table, without the unique file key, the device cannot accurately recover the file.

FIG. 51 is a schematic block diagram of an example of a user device (e.g., a computing entity 12) sending packets of symbol requests to the network 14. The packets are sent to an edge device 33. As discussed with reference to FIG. 50, a packet includes the requestor ID and a copy number that was generated by the encoder.

As the edge device receives request packets from the user device, it verifies the packets includes the correct copy number. Accordingly, the edge device performs a similar function as the encoder of FIG. 50 to produce a sequence of copy numbers for the various packets. If, as packets are received, they include the correct copy number, then the edge device passes the request packet to the network, which provides a symbol response (e.g., one or more response packets that include the copy number and the bit sequence or segments thereof).

If the edge device determines that the request packets do not include the correct copy number sequence, the edge device does not forward the request packets to the network. The edge device may send an error message to the requesting user device. In an alternate embodiment, one or more another infrastructure devices perform the functions described with reference to the present figure. As another alterative embodiment, the system includes one or more security devices that perform the function described with reference to the present figure.

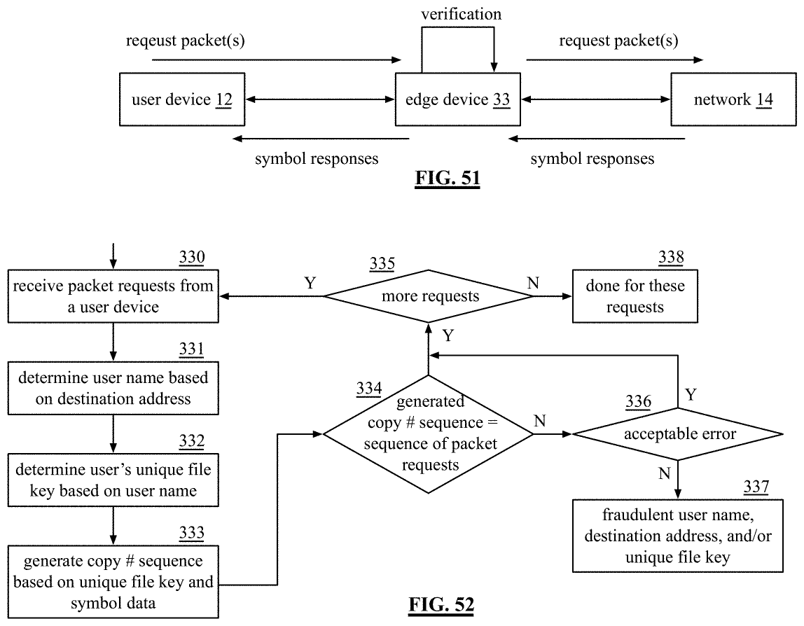

FIG. 52 is a logic diagram of an example of a method for execution by an infrastructure edge device, an infrastructure core device, and/or other network device (hereinafter for this figure referred to as device) to verify username, destination address, and/or unique file key for a file. The method begins at step 330 where the device receives one or more request packets from a user device in accordance with the example(s) of FIGS. 50 and 51. The method continues at step 331 where the device determines the username based on the destination address (e.g., the requestor ID). The method continues at step 332 where the device determines the user's unique file key in accordance with the username. For example, the device performs a lookup to obtain the unique file key. As another example, the device calculates the unique file key based on the username in the same manner as the entity that initially created the unique file key. As yet another example, the device obtains the unique file key from the entity that initially create it.

The method continues at step 333 where the device generates a copy number for a packet based on the unique file key and the symbol data. Note that the device obtains a copy of the index table of the file and creates the symbol data therefrom. The method continues at step 334 where the device determines whether the copy number it generated matches the copy number of the packet. If yes, the method continues at step 335 where the device determines whether there are more request packets for index table of the file to be processed. If yes, the method repeats at step 330. If there are no more request packets to process, then the method continues at step 338 where the device is done for this index table.

If, at step 334, the copy numbers didn't match, the method continues at step 336 where the device determines whether it is an acceptable error. An acceptable error is rate of mismatches that is below a threshold (e.g., less than 1 mismatch per 100 packets, per 1,000 packets, etc.). If it was an acceptable error, the method repeats at step 335. In addition, the device may request the user device to resend the request packet.

If it is not an acceptable error, then the method continues at step 337 where the device determines that the user is not authorized to access the file and terminates the process. In this instance, the user may not be authorized because of a fraudulent or incorrect username, a fraudulent or incorrect destination address, and/or a fraudulent or incorrect unique file key. This data can be used to identify potential bad actors and/or bad actions within the system and enable measures to be established to mitigate the adverse effects of bad actors and/or bad actions.

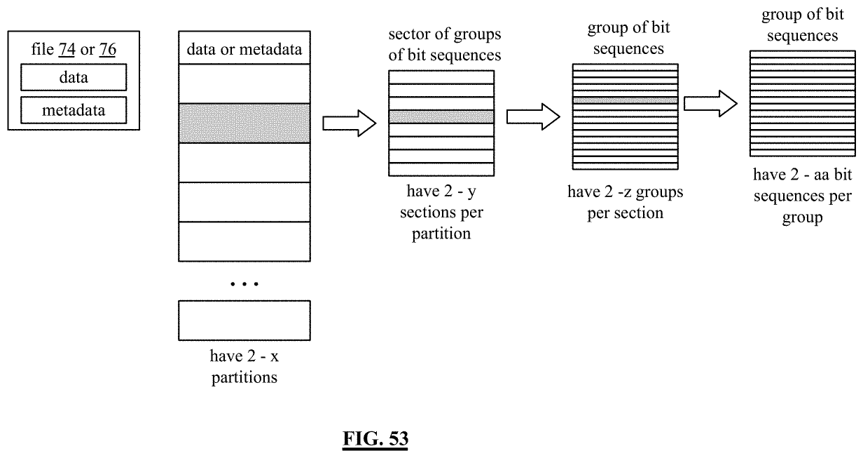

FIG. 53 is a schematic block diagram of an example of layers of symbols and/or bit sequence groups of a file 74 or 76. The file, which may be a data file, an application file, an operating system, a driver, and/or other software program, includes a data section and a metadata section. The data section includes data words of the file, and the metadata section includes metadata regarding the data words and/or metadata regarding the file.

The data section and/or the metadata section is divided into two or more partitions. Each partition is represented by one or more symbols. One or more of the partitions may be further divided into two or more sections. Each section is represented by a one or more symbols. One or more of the sections may be further divided into two or more groups. Each group is represented by one or more symbols. One or more of the groups may be further divided into two or more bit sequences. Each bit sequence is represented by a symbol as previously discussed.

The metadata would further include information regarding how the particular section (e.g., data or metadata) is divided. Such information includes the number of layers (e.g., 4 in this example) and the number of divisions for each layer (e.g., 2 partitions; for partition 1 its divided into 2 sections and for partition 2 it is not divided; for section 1 of partition 1 it is not divided; etc.). and indicate the level of an index table of symbols.

Note that the data section and metadata section could be divided differently. For example, the data section is divided into three levels and the metadata section is not divided; it just includes symbols for bit sequences.

Also note that the division of level does not have to be uniform from level to level and that the size of divisions does not have to be the same. For example, if a data section is divided into two partitions; one partition may be further divided while the other partition is not. Continuing with the example, the partition that is being further divided may be larger than the other partition (e.g., has more bit sequences). In furtherance of this example, the non-divided section would include symbols for bit sequences.

For the partition that is further divided, assume that it is divided into two sections. One of the sections is not further divided and the other section is. For the non-divided section, it includes symbols for bit sequences. For the divided section, it is divided into groups of bit sequences. Each group is represented by one or more symbols. A group includes a plurality of symbols for a corresponding plurality of bit sequences. The number of bit sequences from group to group may vary or may be the same.

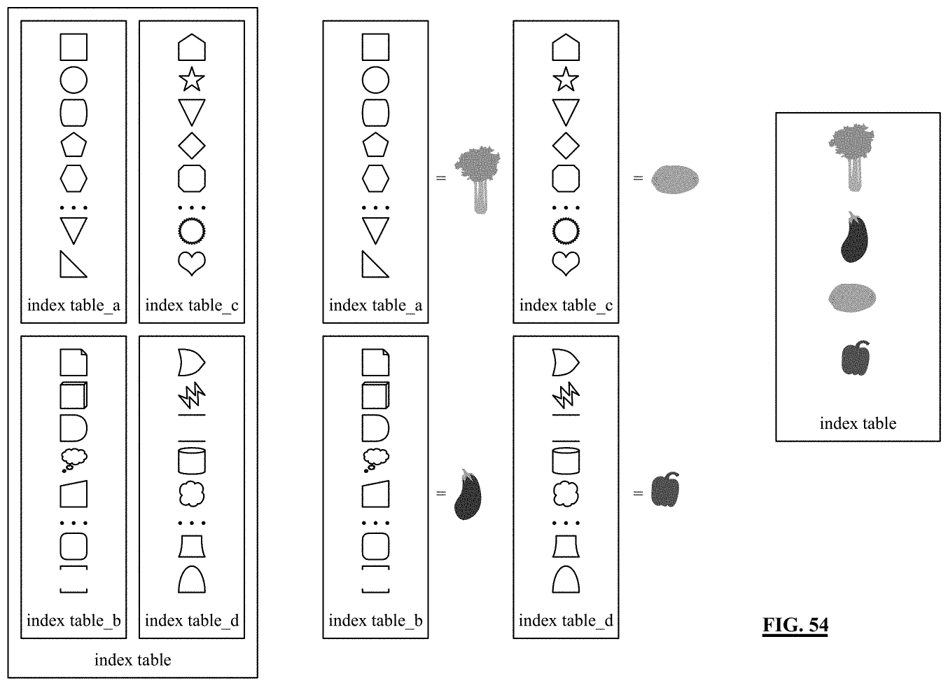

FIG. 54 is a schematic block diagram of an example of layers of symbols groups for a file. The file includes four partitions. Each is expressed via a sub-index table (index table_a, index table b, index table_c, and index table_d). Without partitioning, the file would be represented by an index table that includes all of the symbols of the sub-index tables.

With partitioning, each partition is represented by a unique symbol. In this example, index table_a is represented by a green color image of celery; index table b is represented by a dark purple color image of an eggplant; index table_c is represented by a light brown color image of a potato; and index table_d is represented by a red color image of a cherry.

As such, the index table for the file includes the symbols for each sub-index table. When the file is to be retrieve, the image of the celery is used to retrieve index table_a, the image of the eggplant is used to retrieve index table b, the image of the potato is used to retrieve index table_c, and the image of the cherry is used to retrieve the index table_d.

The symbols of index table_a are used to retrieve a first set of bit sequences; the symbols of index table b are used to retrieve a second set of bit sequences; the symbols of index table_c are used to retrieve a third set of bit sequences; and the symbols of index table_d are used to retrieve a fourth set of bit sequences. The first-fourth sets of bit sequences are arranged to provide the data words of the file.

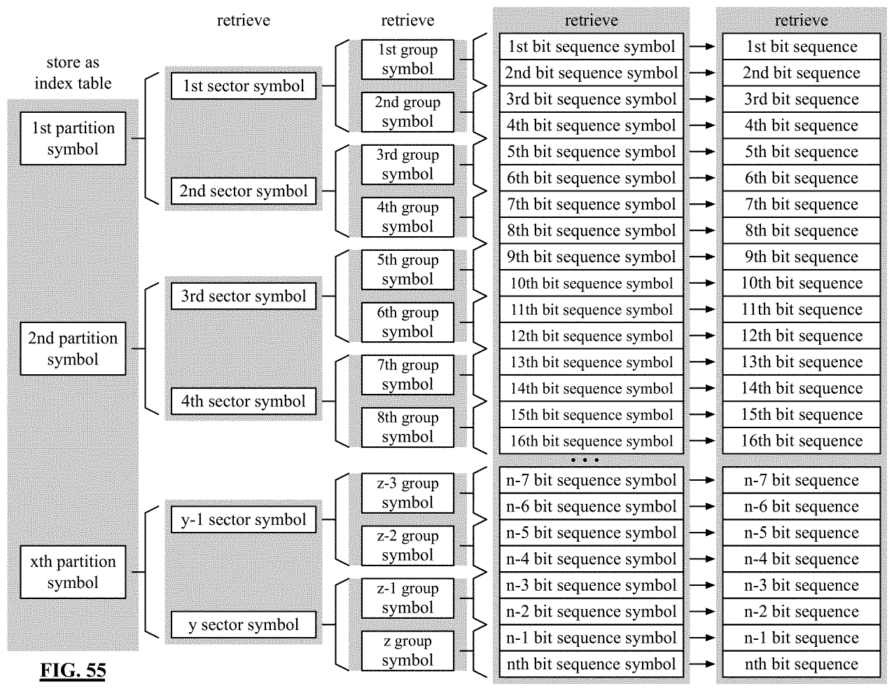

FIG. 55 is a schematic block diagram of another example of layers of symbols and/or bit sequence groups of a file. The file is divided into “x” partitions. In this example, “x” is an integer that is equal to or greater than 3. Each partition is represented by a unique symbol (or combination of symbols). The unique symbols of the partitions are stored by a computing entity as an index table for the file.

The symbols of the first partition are used to retrieve an index table of sector level. For example, the symbol of the first partition is used to retrieve a first sector index table that includes symbols for a first sector and a second sector. The symbol of the second partition is used to retrieve a second sector index table that includes symbols for a third sector and a fourth sector. The symbol of the x^{th} partition is used to retrieve an index table that includes symbols of a y−1 sector and a y sector.

The symbol of the first sector is used to retrieve a first group index table that includes symbols for a first group and a second group. The symbol of the second sector is used to retrieve a second group index table that includes symbols for a third group and a fourth group. The symbol of the third sector is used to retrieve a third group index table that includes symbols for a fifth group and a sixth group. The symbol of the fourth sector is used to retrieve a fourth group index table that includes symbols for a seventh group and an eighth group. The symbol of the y−1 sector is used to retrieve a y−1 group index table that includes symbols for a z−3 group and a z−2 group. The symbol of the y sector is used to retrieve a y group index table that includes symbols for a z−1 group and a z group.

The symbol of the first group is used to retrieve a first bit sequence symbol and a second bit sequence symbol. The symbol of the second group is used to retrieve a third bit sequence symbol and a fourth bit sequence symbol. The symbol of the third group is used to retrieve a fifth bit sequence symbol and a sixth bit sequence symbol. The symbol of the fourth group is used to retrieve a seventh bit sequence symbol and an eighth bit sequence symbol. The symbol of the fifth group is used to retrieve a ninth bit sequence symbol and a tenth bit sequence symbol. The symbol of the sixth group is used to retrieve an eleventh bit sequence symbol and a twelfth bit sequence symbol. The symbol of the seventh group is used to retrieve a thirteenth bit sequence symbol and a fourteenth bit sequence symbol. The symbol of the eighth group is used to retrieve a fifteenth bit sequence symbol and a sixteen bit sequence symbol.

The symbol of the z−3 group is used to retrieve an n−7 bit sequence symbol and an n−6 bit sequence symbol. The symbol of the z−2 group is used to retrieve an n−5 bit sequence symbol and an n−4 bit sequence symbol. The symbol of the z−1 group is used to retrieve an n−3 bit sequence symbol and an n−2 bit sequence symbol. The symbol of the z group is used to retrieve an n−1 bit sequence symbol and an n^{th} bit sequence symbol.

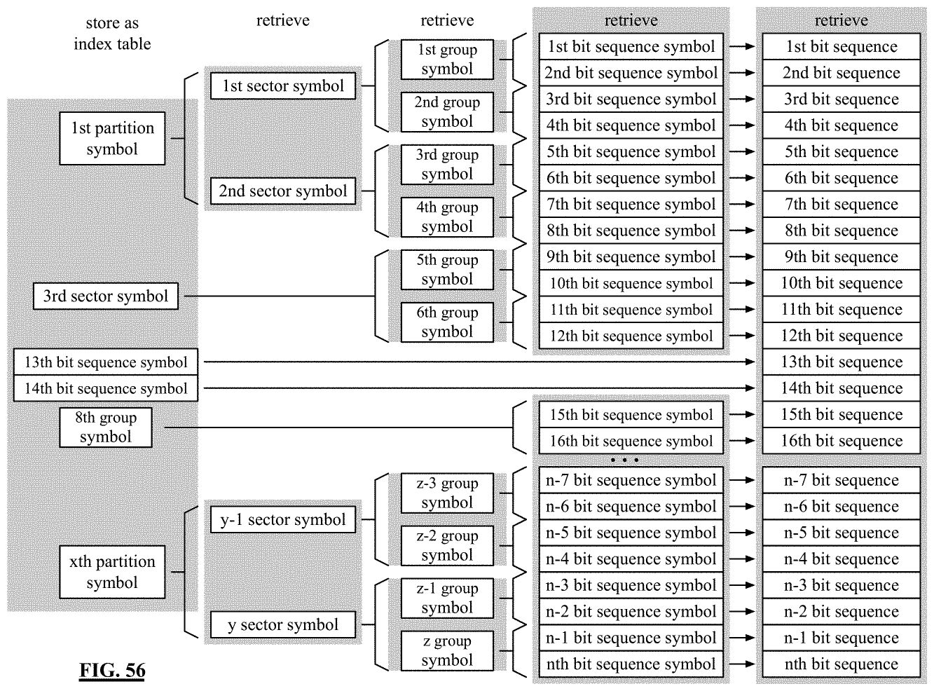

The first through n^{th} bit sequence symbol is used to retrieve the first through n^{th} bit sequence. By having symbols also representing groups of symbols, a large amount of data (i.e., a file that includes a plurality of bit sequences) can be represented with a much-much smaller amount of data. In the example, the levels fanned out equally. In the example of FIG. 56, the levels do not fan out equally.

FIG. 56 is a schematic block diagram of another example of layers of symbols and/or bit sequence groups of a file. The file includes the same bit sequences as the file of FIG. 55, but the file is divided differently. In this example, the index table for the file includes the 1^{st} partition symbol, the 3^{rd} sector symbol, the 13^{th} bit sequence symbol, the 14^{th} bit sequence symbol, the 8^{th} group symbol, and the x^{th} partition symbol. The 1^{st} and the x^{th} partitions are divided and represented by symbols as discussed with reference to FIG. 55.

The 3^{rd} sector and the 8^{th} sector of the file are each further divided as discussed with reference to FIG. 55. In this example, the 13^{th} and 14^{th} bit sequences were not in any groups, thus they are only represented by their respective symbols. As such, the symbols of the 13th and 14^{th} bit sequences are included in the index table for the file.

The level associated with symbols of the index table are distinguishable in a variety of ways. For example, the meta data of the file indicates the levels of the symbols and the symbols of the sub-index tables. As another example, each level has a unique set of symbols. Thus, the level of the file is based on the particular features of the symbol.

In an embodiment, a symbol is stored as image data, which is a series of data words. Some of the series of data words corresponds to data words of bit sequences. Thus, for some index tables and/or sub-index tables they can be expressed as one or more bit sequences.

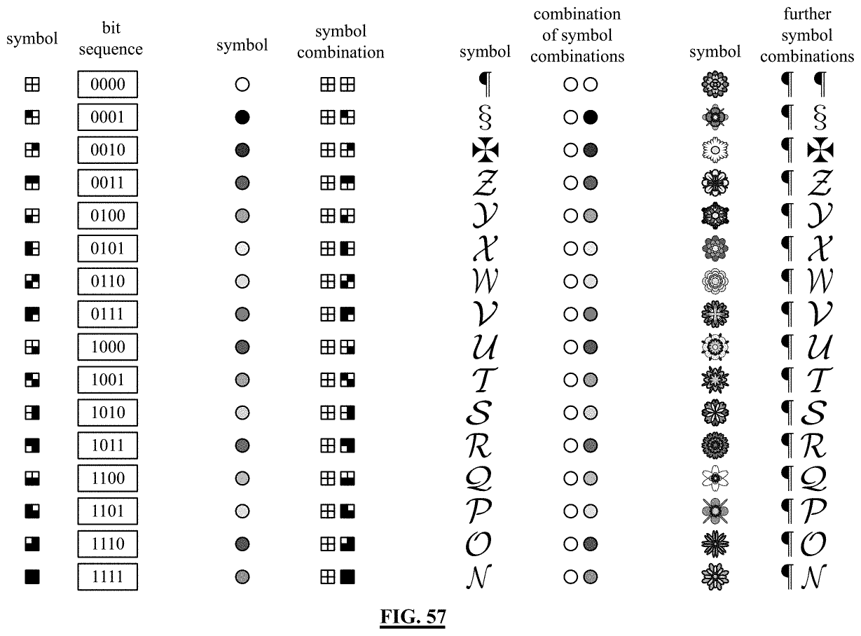

FIG. 57 is a schematic block diagram of another example of layers of symbols. In this example, a first type of symbols (e.g., black & white square pattern) is used to express bit sequences. A second type of symbols (e.g., color circles) is used to express a collection of first type of symbols. A third type of symbols (e.g., a set of characters) is used to express a collection of second type of symbols. A fourth type of symbols (e.g., color flowers) is used to express a collection of third type of symbols.

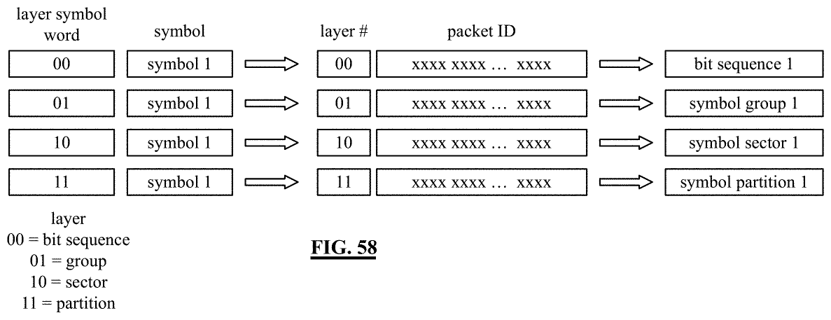

FIG. 58 is a schematic block diagram of another example of a symbol being used for multiple layers. In this example, one symbol is used to represent different layers (e.g., the layers shown in FIGS. 53-56). The symbol is coupled with a n-bit layer symbol word (e.g., n=2 or more). An image of the bits and the symbol for the symbol for a specific layer. For example, if a symbol is a square and the layer symbol word is 00, then the symbol is a bit sequence symbol. If the layer symbol word is a 01, then the symbol is a group layer symbol. If the layer symbol word is a 10, then the symbol is a sector layer symbol. If the layer symbol word is a 11, then the symbol is a partition layer symbol.

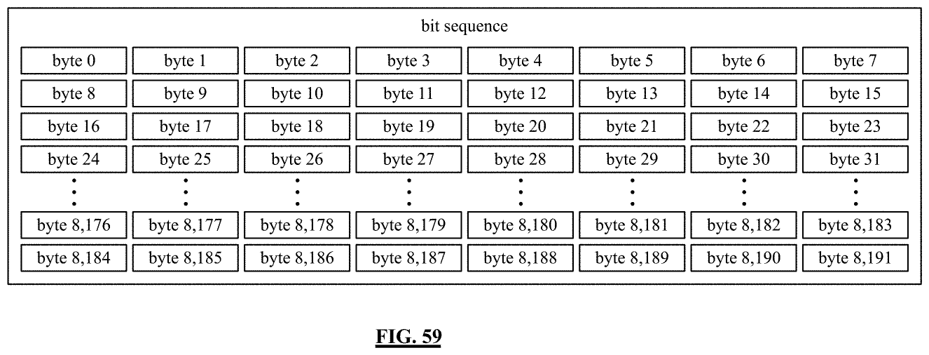

FIG. 59 is a schematic block diagram of another example of a bit sequence arranged in data words. In this example, a data word is 1 byte in size and the bit sequence includes 8,191(8 Kbytes) of data words. The symbol for the bit sequence may be any of the symbols discussed herein or another type of symbol. When an image is taken of the symbol, the image data will be of a size. Depending on the image capture protocol (e.g., JPG, TIFF, GIF, etc.), the size of the image data will be significantly less than the 8 Kbytes of data it represents. When one symbol represents the grouping of two bit sequence symbols, then the ratio of symbol data size to actual data size will be even greater.

With 8 Kbytes of data in a bit sequence, not every combination of bits will be represented in bit sequences. To do so would require 2^{(8*8,191)} bit sequences. Even with 6.8 zettabytes of data being stored annually and doubling every two to four years, only a very-very small percentage of bit combinations of the 2^{(8*8,191)} bit combinations for an 8 Kbyte bit sequence are used. Thus, only those bit sequences need to be created and represented by symbols.

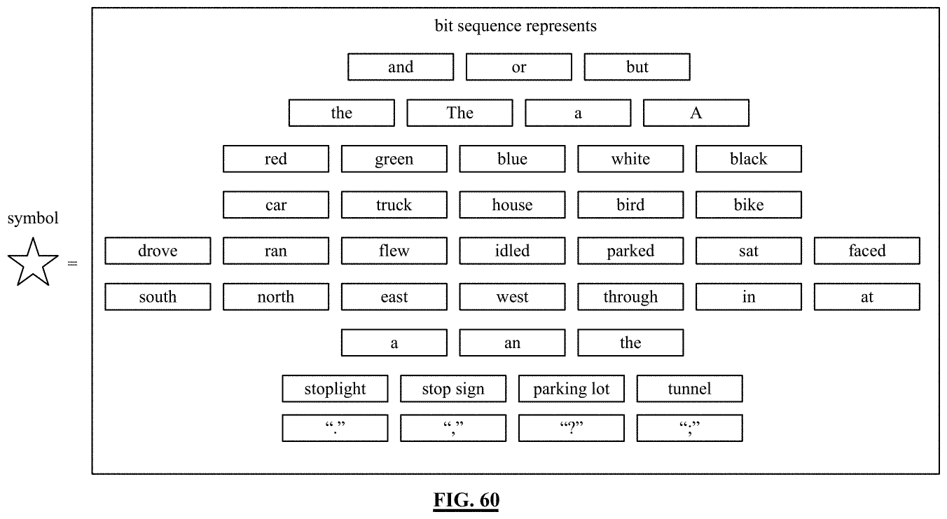

In addition, different files may use the same data words of a bit sequence, may use a substantial majority of the data words of a bit sequence, and/or may use the same data words of a bit sequence in a different order. FIGS. 60-68 illustrate various examples that allow different files to access the same bit sequences but use the data words thereof in different ways.

FIG. 60 is a schematic block diagram of an example of symbol representing a word-based bit sequence. In this example, binary or hexadecimal data words are expressed as ASCII characters to form words. As shown, the bit sequence includes a plurality of words that are often used together in various combinations to form sentences and/or express a meaning.

The symbol for the bit sequence is a black & white star. The black & white color indicates that all of the bit sequence is to be used in the order of the data words contained therein. Note that spacing between words is includes the in words of the bit sequence.

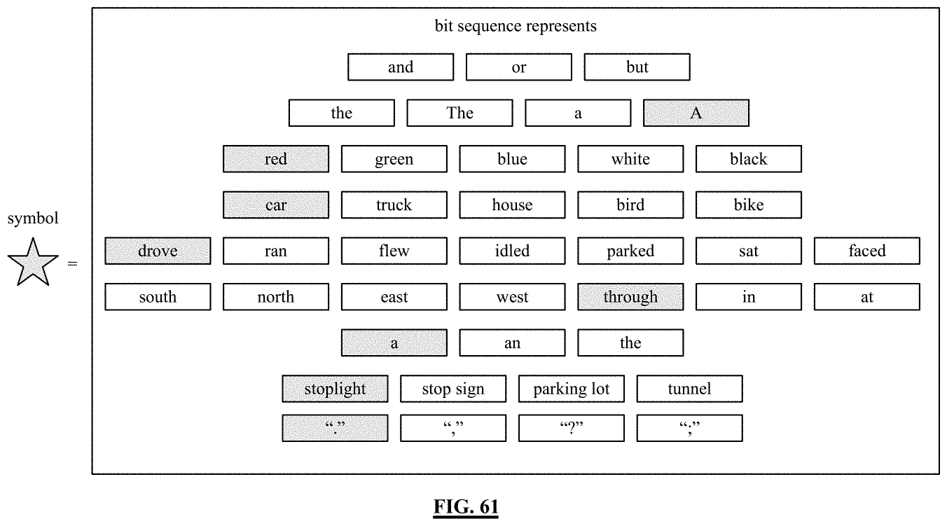

FIG. 61 is a schematic block diagram of an example of color information of a symbol being used to identified selected data of a word-based bit sequence. In this example, the star is colored green. The color green is used to indicate that the words “A red car drove through a stoplight.” are to be used from this bit sequence.

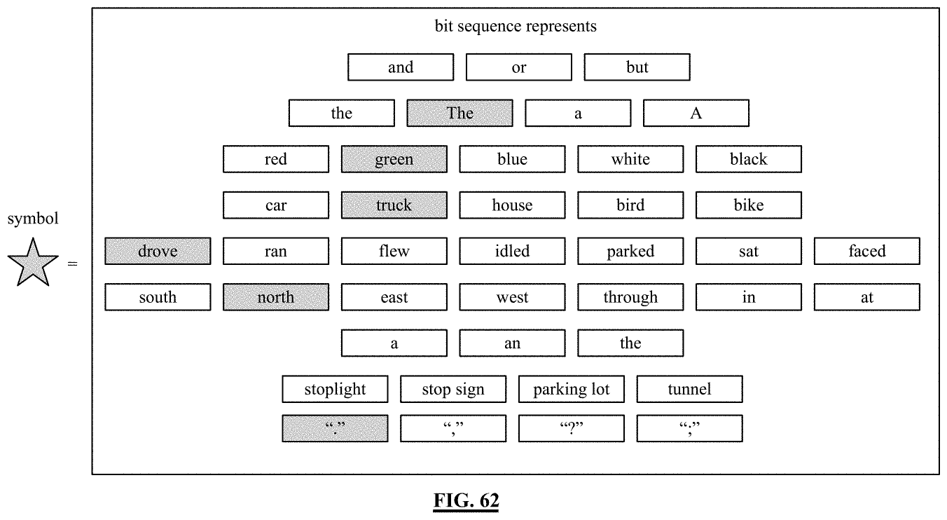

FIG. 62 is a schematic block diagram of another example of color information of a symbol being used to identified selected data of a word-based bit sequence. In this example, the star is colored red. The color red is used to indicate that the words “The green truck drove north.” are to be used from this bit sequence.

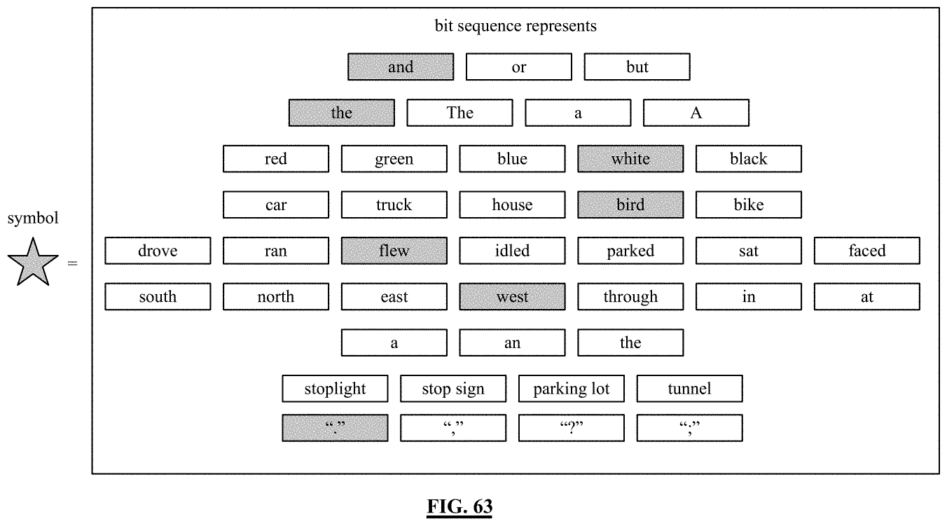

FIG. 63 is a schematic block diagram of another example of color information of a symbol being used to identify selected data of a word-based bit sequence. In this example, the star is colored blue. The color blue is used to indicate that the words “and the white bird flew west.” are to be used from this bit sequence.

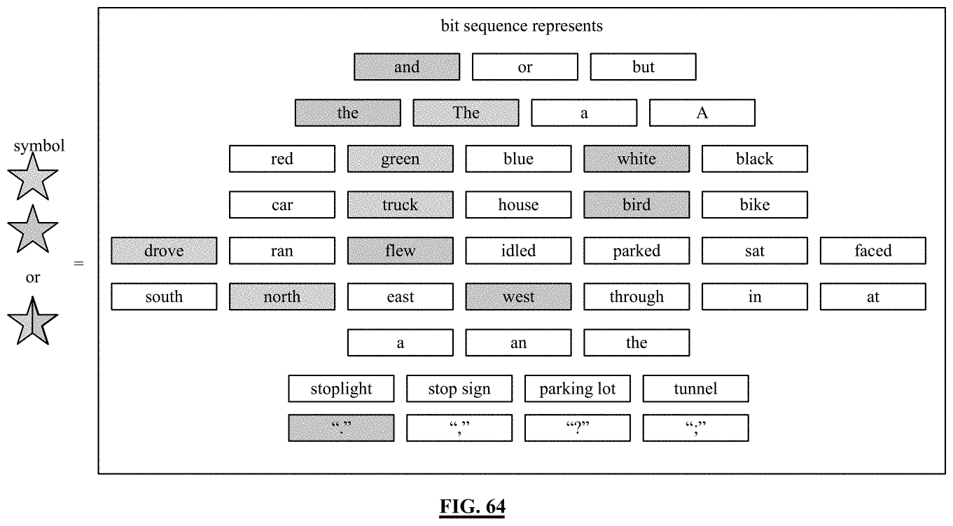

FIG. 64 is a schematic block diagram of another example of color information of a symbol being used to identify selected data of a word-based bit sequence. In an example, there are two stars in an order. The first is red and the second is blue. The color red is used to indicate that the words “The green truck drove north.” are to be used from this bit sequence. The color blue is used to indicate that the words “and the white bird flew west.” are to be used from this bit sequence. With the red star being first, it indicates that the collective words to be used are “The green truck drove north and the white bird flew west.”

Alternatively, only one star could be used. In this alternative, half of the star is colored red and the other half is colored blue. The color of the left indicates which set of words comes first.

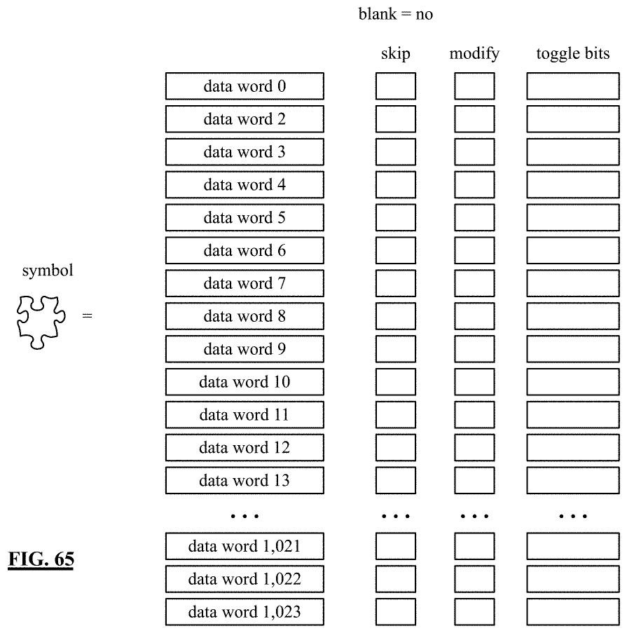

FIG. 65 is a schematic block diagram of an example of a symbol representing a bit sequence that includes a plurality of data words. In this example, the bit sequence includes 1,023 data words and the symbol representing the bit sequence is a puzzle piece. The data words are ordered from 0 through 1,023.

Associated with the bit sequence is a table that includes columns for skip, modify, and toggle bits. The rows of the table correspond to the data words. The skip column indicates whether a data word should be skipped when using the bit sequence to reconstruct a file. The modify column indicates how the data is to be modified. For example, a data word is modified by shifting 1 or more bits to the left. As another example, a data word is modified by shifting 1 or more bits to the right. As another example, bits of a data word are toggled (e.g., a 1 is toggled to a 0 or a 0 is toggled to a 1).

The white color of the puzzle piece indicates that the data words of the bit sequence are used to reconstruct a file in the order they appear and without modification. Color indicates modification to one or more data words and the nature of the modification.

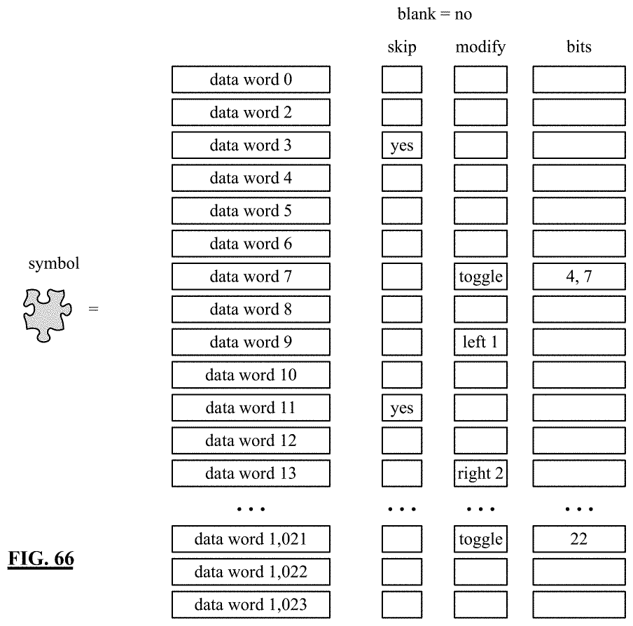

FIG. 66 is a schematic block diagram of another example of color information of a symbol being used to identify selected data words of a bit sequence for changes. In this example, the puzzle piece is colored purple. The color purple indicates that data words 3 and 11 are to be skipped (e.g., effectively removed from the bit sequence for reconstructing the bit sequence). The color purple also indicates that data word 7 is to be modified by toggling bits 4 and 7; data word 9 is to be shifted left by 1 bit; data word 13 is to be shifted right by 2 bits; and data word 1,021 is to be modified by toggling bit 22.

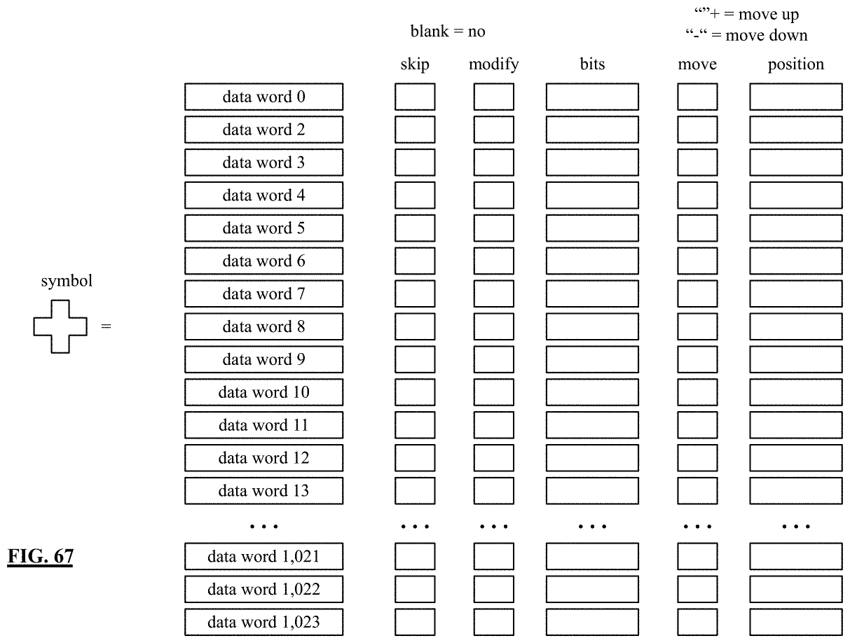

FIG. 67 is a schematic block diagram of an example of a symbol representing a bit sequence that includes a plurality of data words. Associated with the bit sequence is a table regarding how the data words are to be modified. The table includes columns for skip, modify, bits, move, and position. The rows of the table correspond to the data words. The skip, modify, and bits columns are as previously discussed. The move column includes whether a data word is to be moved in the order of data words and the position is by how much and in what direction.

The symbol representing the bit sequence is a plus sign. The white color indicates that no changes to the data words are to be made. When the plus sign has a color, the color indicates the changes to the data words.

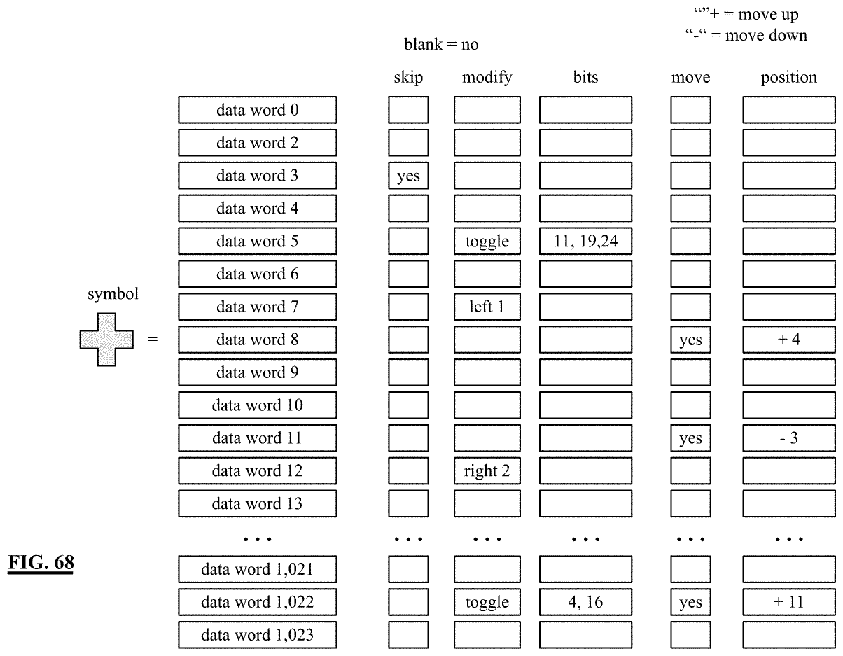

FIG. 68 is a schematic block diagram of another example of color information of a symbol being used to identify selected data words of a bit sequence for changes. In this example, the plus sign is colored light blue. The color light blue indicates that data word 3 is to be skipped when reconstructing a file. The color light blue also indicates that data word 5 is to have bits 11, 19, and 24 toggled; data word 7 is to be shifted left by 1 bit; data word 8 is to be moved up 4 spots (e.g., between data words 3 and 4); data word 11 is to be moved down by 3 spots (e.g., between data words 114 and 15); and data word 1,022 is to have bits 4 and 16 toggled and to be moved up 11 positions.

In this manner one bit sequence can be used to reconstruct files that have slightly altered versions of the data words of the bit sequence. The table associated with the bit sequence may be included with the bit sequence, stored by computing entities, and/or stored within the network.

It is noted that terminologies as may be used herein such as bit stream, stream, signal sequence, etc. (or their equivalents) have been used interchangeably to describe digital information whose content corresponds to any of a number of desired types (e.g., data, video, speech, text, graphics, audio, etc. any of which may generally be referred to as ‘data’).

As may be used herein, the terms “substantially” and “approximately” provide an industry-accepted tolerance for its corresponding term and/or relativity between items. For some industries, an industry-accepted tolerance is less than one percent and, for other industries, the industry-accepted tolerance is 10 percent or more. Other examples of industry-accepted tolerance range from less than one percent to fifty percent. Industry-accepted tolerances correspond to, but are not limited to, component values, integrated circuit process variations, temperature variations, rise and fall times, thermal noise, dimensions, signaling errors, dropped packets, temperatures, pressures, material compositions, and/or performance metrics. Within an industry, tolerance variances of accepted tolerances may be more or less than a percentage level (e.g., dimension tolerance of less than +/−1%). Some relativity between items may range from a difference of less than a percentage level to a few percent. Other relativity between items may range from a difference of a few percent to magnitude of differences.

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processing module”, “processing circuit”, “processor”, “processing circuitry”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, processing circuitry, and/or processing unit may be, or further include, memory and/or an integrated memory element, which may be a single memory device, a plurality of memory devices, and/or embedded circuitry of another processing module, module, processing circuit, processing circuitry, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, processing circuitry, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, processing circuitry and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, processing circuitry and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

One or more functions associated with the methods and/or processes described herein can be implemented via a processing module that operates via the non-human “artificial” intelligence (AI) of a machine. Examples of such AI include machines that operate via anomaly detection techniques, decision trees, association rules, expert systems and other knowledge-based systems, computer vision models, artificial neural networks, convolutional neural networks, support vector machines (SVMs), Bayesian networks, genetic algorithms, feature learning, sparse dictionary learning, preference learning, deep learning and other machine learning techniques that are trained using training data via unsupervised, semi-supervised, supervised and/or reinforcement learning, and/or other AI. The human mind is not equipped to perform such AI techniques, not only due to the complexity of these techniques, but also due to the fact that artificial intelligence, by its very definition—requires “artificial” intelligence—i.e., machine/non-human intelligence.

One or more functions associated with the methods and/or processes described herein can be implemented as a large-scale system that is operable to receive, transmit and/or process data on a large-scale. As used herein, a large-scale refers to a large number of data, such as one or more kilobytes, megabytes, gigabytes, terabytes or more of data that are received, transmitted and/or processed. Such receiving, transmitting and/or processing of data cannot practically be performed by the human mind on a large-scale within a reasonable period of time, such as within a second, a millisecond, microsecond, a real-time basis or other high speed required by the machines that generate the data, receive the data, convey the data, store the data and/or use the data.

One or more functions associated with the methods and/or processes described herein can require data to be manipulated in different ways within overlapping time spans. The human mind is not equipped to perform such different data manipulations independently, contemporaneously, in parallel, and/or on a coordinated basis within a reasonable period of time, such as within a second, a millisecond, microsecond, a real-time basis or other high speed required by the machines that generate the data, receive the data, convey the data, store the data and/or use the data.

One or more functions associated with the methods and/or processes described herein can be implemented in a system that is operable to electronically receive digital data via a wired or wireless communication network and/or to electronically transmit digital data via a wired or wireless communication network. Such receiving and transmitting cannot practically be performed by the human mind because the human mind is not equipped to electronically transmit or receive digital data, let alone to transmit and receive digital data via a wired or wireless communication network.

One or more functions associated with the methods and/or processes described herein can be implemented in a system that is operable to electronically store digital data in a memory device. Such storage cannot practically be performed by the human mind because the human mind is not equipped to electronically store digital data.

One or more functions associated with the methods and/or processes described herein may operate to cause an action by a processing module directly in response to a triggering event—without any intervening human interaction between the triggering event and the action. Any such actions may be identified as being performed “automatically”, “automatically based on” and/or “automatically in response to” such a triggering event. Furthermore, any such actions identified in such a fashion specifically preclude the operation of human activity with respect to these actions—even if the triggering event itself may be causally connected to a human activity of some kind.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with one or more other routines. In addition, a flow diagram may include an “end” and/or “continue” indication. The “end” and/or “continue” indications reflect that the steps presented can end as described and shown or optionally be incorporated in or otherwise used in conjunction with one or more other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid-state memory, a hard drive memory, cloud memory, thumb drive, server memory, computing device memory, and/or other physical medium for storing digital information.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A method comprises:
receiving, by a computing entity, a file retrieval request for a file;
accessing, by the computing entity, an index table regarding the file, wherein the index table includes a plurality of symbols, wherein a symbol of the plurality of symbols is representative of a bit sequence of the plurality of bit sequences;
interpreting, by the computing entity, the index table to identify a plurality of bit sequences;
sending, by the computing entity, one or more requests to a network device regarding at least some of the plurality of bit sequences;
receiving, by the computing entity, a requested bit sequence in response to the one or more requests; and
reconstructing, by the computing entity, a portion of the file based on the requested bit sequence and the index table.

2. The method of claim 1, wherein the file comprises one of:
a data file;
an application file;
an operating system; and
a driver.

3. The method of claim 1, wherein the symbol comprises one or more of:
a glyph;
an alpha-numeric; and
an image.

4. The method of claim 3, wherein the interpreting the index table to identify a plurality of bit sequences further comprises:
interpreting the symbol to identify the bit sequence, wherein a data size of the symbol is less than a data size of the bit sequence.

5. The method of claim 1, wherein the plurality of bit sequences comprises:
an ordered sub-set of bit sequences of one or more collections of bit sequences.

6. The method of claim 5 further comprises:
the one or more collections of bit sequences residing in a network that includes the network device.

7. The method of claim 1, wherein the receiving a requested bit sequence further comprises one or more of:
receiving one or more packets regarding the bit sequence; and
receiving one or more frames regarding the bit sequence.

8. The method of claim 1, wherein the reconstructing a portion of the file further comprises:
decompressing the bit sequence to recover the portion of the file.

9. The method of claim 1, wherein the reconstructing a portion of the file further comprises:
decrypting the bit sequence to recover the portion of the file.

10. A computer readable memory comprises:
a first memory section that stores operational instructions that, when executed by a computing entity, causes the computing entity to:
receive a file retrieval request for a file;
access an index table regarding the file, wherein the index table includes a plurality of symbols, wherein a symbol of the plurality of symbols is representative of a bit sequence of the plurality of bit sequences;
interpret the index table to identify a plurality of bit sequences; and
a second memory section that stores operational instructions that, when executed by the computing entity, causes the computing entity to:
send one or more requests to a network device regarding at least some of the plurality of bit sequences;
receive a requested bit sequence in response to the one or more requests; and
reconstructing a portion of the file based on the requested bit sequence and the index table.

11. The computer readable memory of claim 10, wherein the file comprises one of:
a data file;
an application file;
an operating system; and
a driver.

12. The computer readable memory of claim 10, wherein the symbol comprises one or more of:
a glyph;
an alpha-numeric; and
an image.

13. The computer readable memory of claim 12, wherein the first memory section further stores operational instructions that, when executed by the computing entity, causes the computing entity to interpret the index table to identify a plurality of bit sequences further by:
interpreting the symbol to identify the bit sequence, wherein a data size of the symbol is less than a data size of the bit sequence.

14. The computer readable memory of claim 10, wherein the plurality of bit sequences comprises:
an ordered sub-set of bit sequences of one or more collections of bit sequences.

15. The computer readable memory of claim 14 further comprises:
the one or more collections of bit sequences residing in a network that includes the network device.

16. The computer readable memory of claim 10, wherein the second memory section further stores operational instructions that, when executed by the computing entity, causes the computing entity to the receive the requested bit sequence by one or more of:
receiving one or more packets regarding the bit sequence; and
receiving one or more frames regarding the bit sequence.

17. The computer readable memory of claim 10, wherein the second memory section further stores operational instructions that, when executed by the computing entity, causes the computing entity to reconstruct the portion of the file further by:
decompressing the bit sequence to recover the portion of the file.

18. The computer readable memory of claim 10, wherein the second memory section further stores operational instructions that, when executed by the computing entity, causes the computing entity to reconstruct the portion of the file further by:
decrypting the bit sequence to recover the portion of the file.
